(19) United States
(12) Patent Application Publication
(10) Pub. No.: US 2016/0329510 A1
(43) Pub. Date: Nov. 10, 2016

(54) PHOTOVOLTAIC CELLS

(71) Applicant: MERCK PATENT GMBH, Darmstadt (DE)

(72) Inventors: Jeffrey Hamilton PEET, Southborough, MA (US); Christoph LUNGENSCHMIED, Santa Barbara, CA (US)

(73) Assignee: Merck Patent GmbH, Darmstadt (DE)

(21) Appl. No.: 15/108,086

(22) PCT Filed: Dec. 5, 2014
(86) PCT No.: PCT/EP2014/003266

§ 371 Date: Jun. 24, 2016

Related U.S. Application Data
(60) Provisional application No. 61/920,930, filed on Dec. 26, 2013.

(51) Int. Cl. H01L 51/00; C08G 61/12

(52) U.S. Cl. CPC H01L 51/0094; H01L 51/0047; C08G 61/126; H01L 51/4273

(57) ABSTRACT

The invention relates to a photovoltaic cell that comprises a first electrode, a second electrode, and a photoactive layer between the first electrode and the second electrode, and to a preparation thereof. The invention further relates to the use of at least two specific donor materials in photovoltaic cells.

### FIELD OF THE INVENTION

The invention relates to a photovoltaic cell that comprises a first electrode, a second electrode, and a photoactive layer between the first electrode and the second electrode, and to a preparation thereof. The invention further relates to the use of at least two specific donor materials in photovoltaic cells.

### BACKGROUND AND PRIOR ARTS

Photovoltaic cells are commonly used to transfer energy in form of light into electricity. A typical photoactive cell comprises a first electrode, a second electrode, a photoactive layer between the first electrode and the second electrode. Generally, one of the electrodes allows light passing through to the photoactive layer. This transparent electrode may for example be made of a film of semi conductive material (such as for example, indium tin oxide).

Photovoltaic cells configurations are already described, for example, in U.S. Pat. No. 7,781,673B, U.S. Pat. No. 8,058,550B, U.S. Pat. No. 8,455,606B, U.S. Pat. No. 8,008,424B, US2007/0020526A, U.S. Pat. No. 77,724,285B, U.S. Pat. No. 8,008,421 B, US2010/0224252A, WO2011/085004A, and WO2012/030942A.

However, there is still one or more of the following problems for which improvement is desired, as listed below.
1. Photoelectric conversion efficiency is still not high enough and should be improved.
2. The fill factor of a photovoltaic cell still needs improvement.
3. An increase in thickness of the photoactive layer generally leads to a decreasing fill factor. It is desirably to reduce the corresponding loss in fill factor when the thickness of the photoactive layer is increased so as to improve performance of the photovoltaic cell.
4. There is still a need for improvement in the thermal stability.

### DETAILED DESCRIPTION OF THE INVENTION

The inventors aimed to solve one or more of the aforementioned problems. Surprisingly, the inventors have found an inventive photovoltaic cell (100) which comprises
a first electrode (120);
a second electrode (160); and
a photoactive layer (140) between the first electrode (120) and the second electrode (160),

wherein the photoactive layer (140) comprises a first donor material, second donor material and acceptor material; the first donor material and the second donor material being different from each other and each of the donor materials comprising a common building block of the same chemical structure, said common building block comprising a conjugated fused ring moiety.

Preferably, it solves one or more of the problems 1 to 4. Further advantages of the present invention will become evident from the following detailed description.

In a preferred embodiment of the present invention, the common building block constitutes an electron donating unit of the donor materials.

Preferably, the photovoltaic cell according to the present invention, the common conjugated fused ring moiety of donor materials is at each occurrence, selected from the group consisting of the following formulae (A1) to (A106),

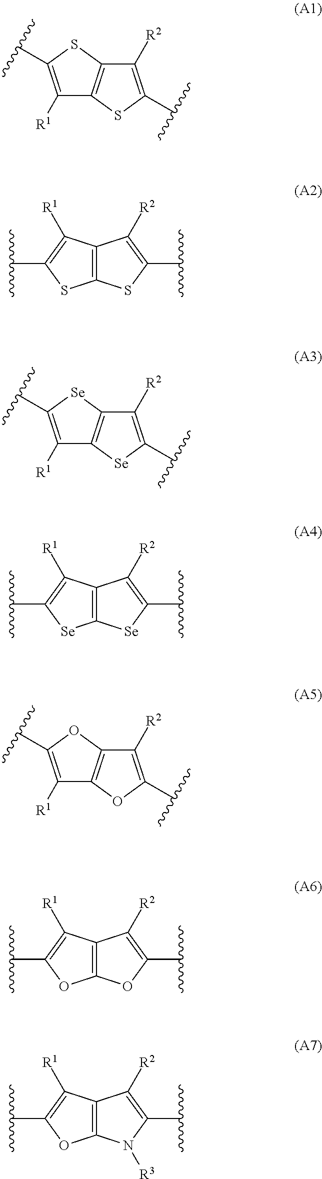

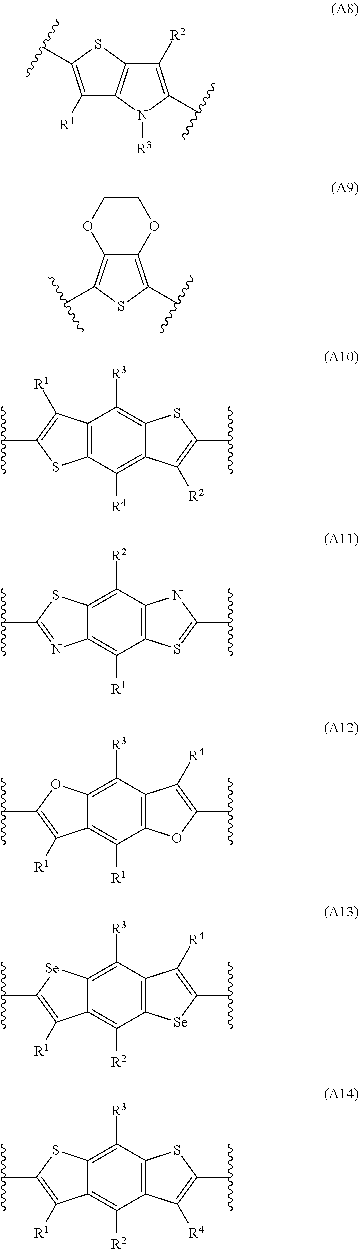

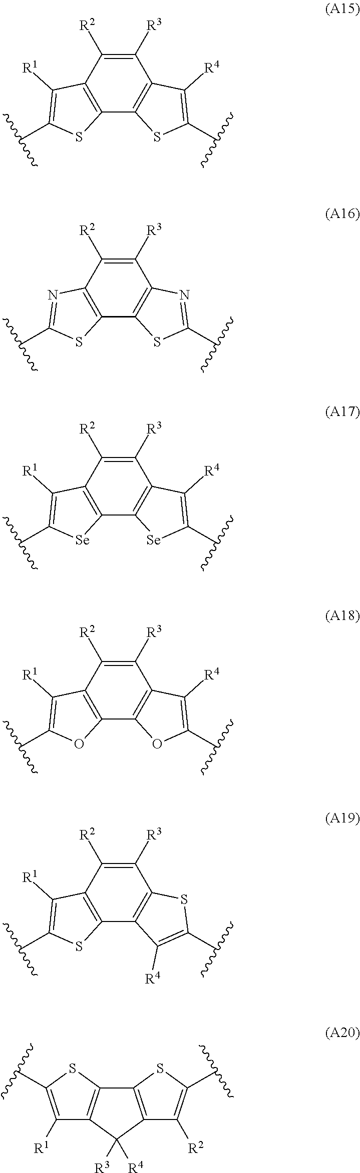

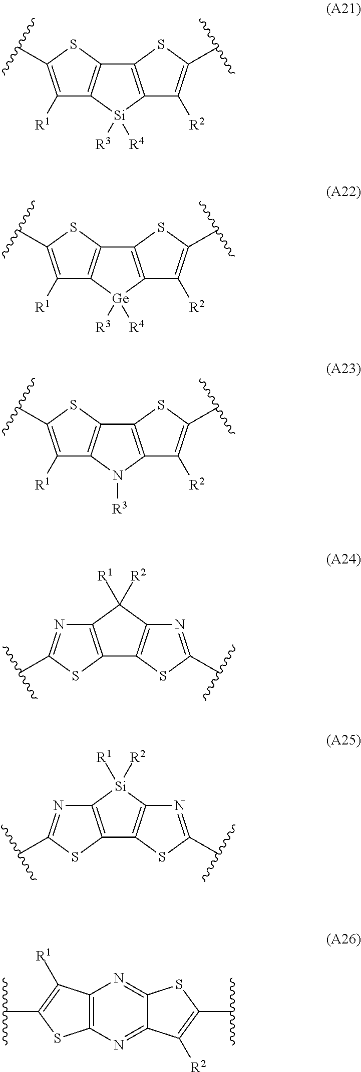

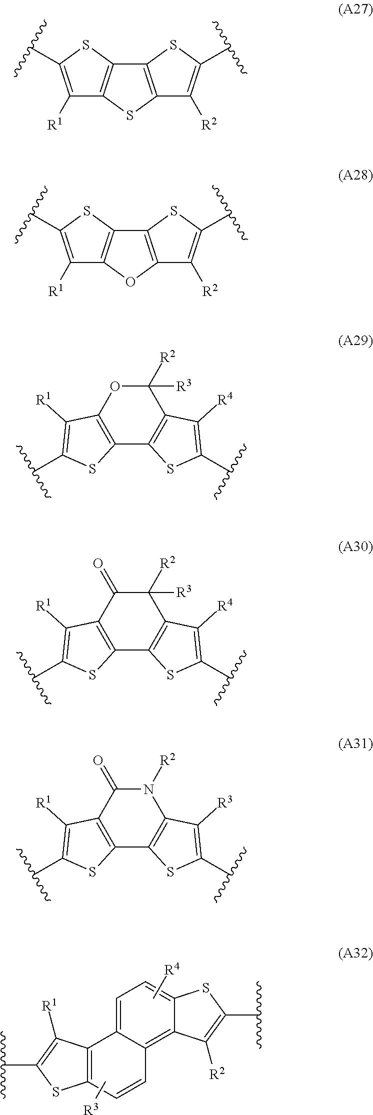

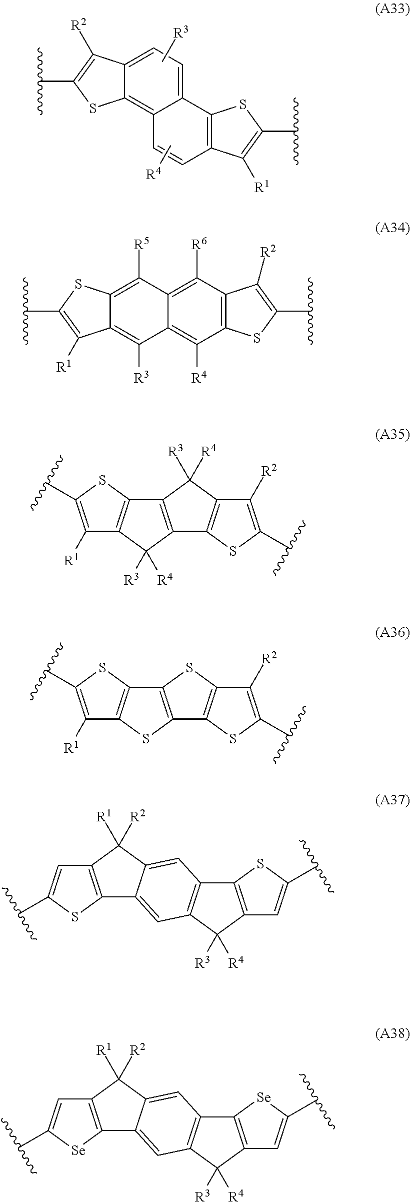

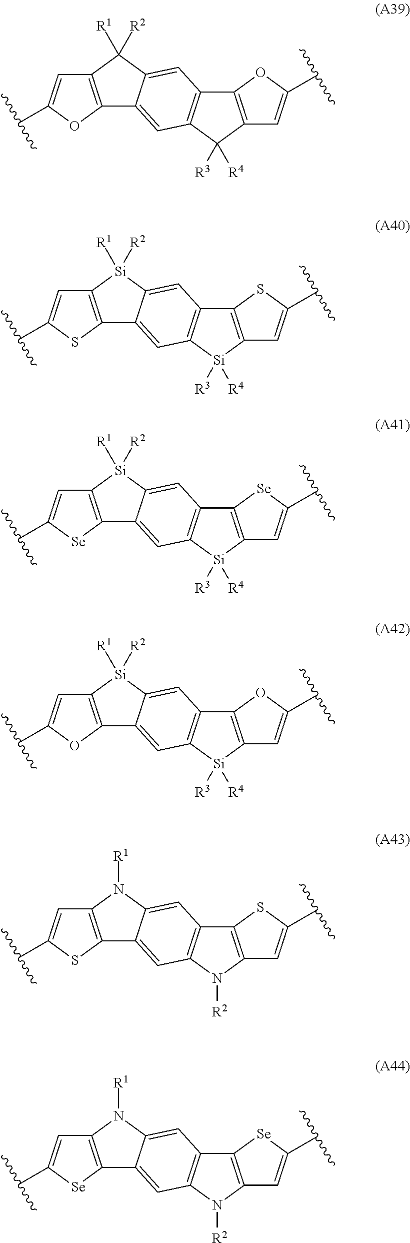

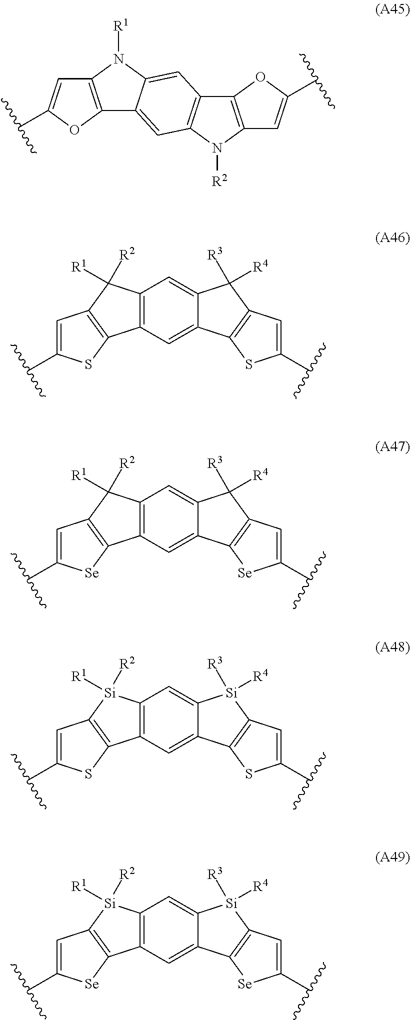

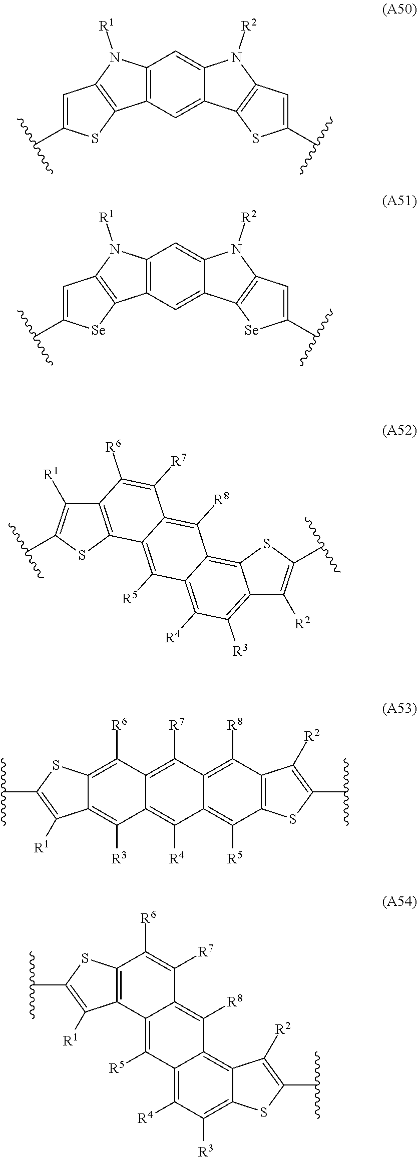

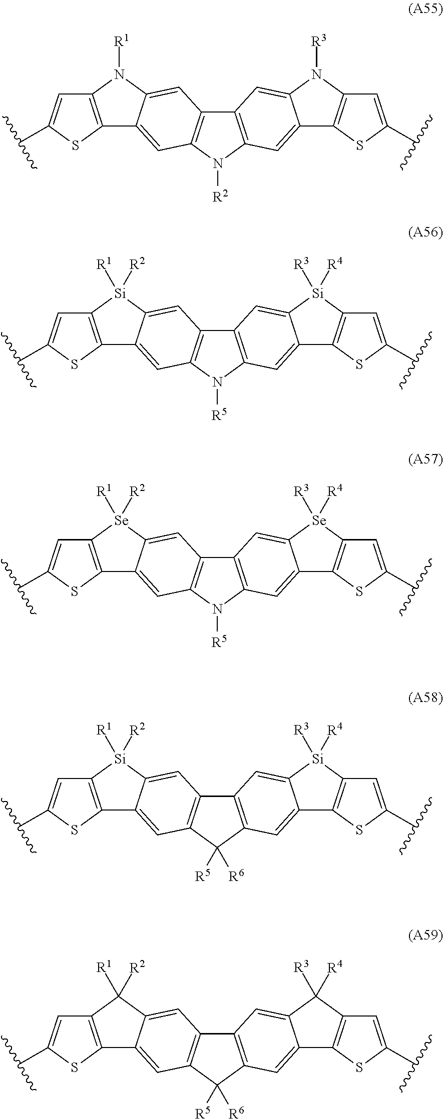

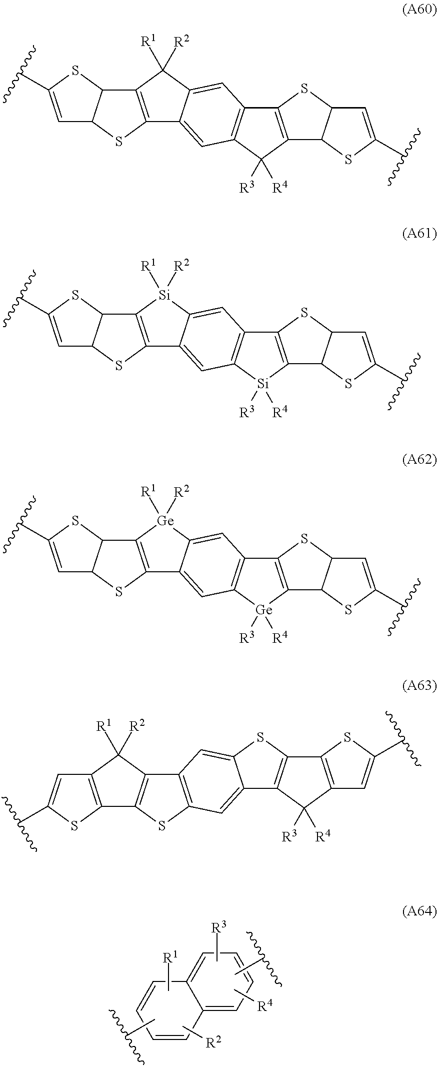

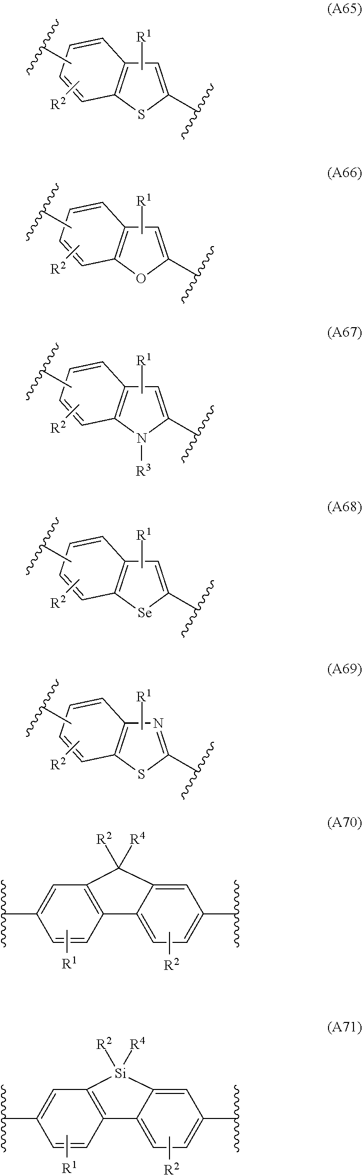

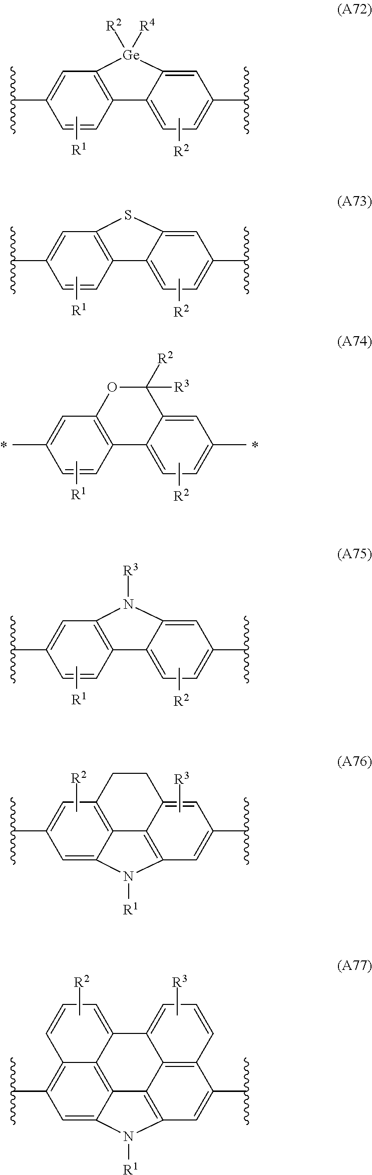

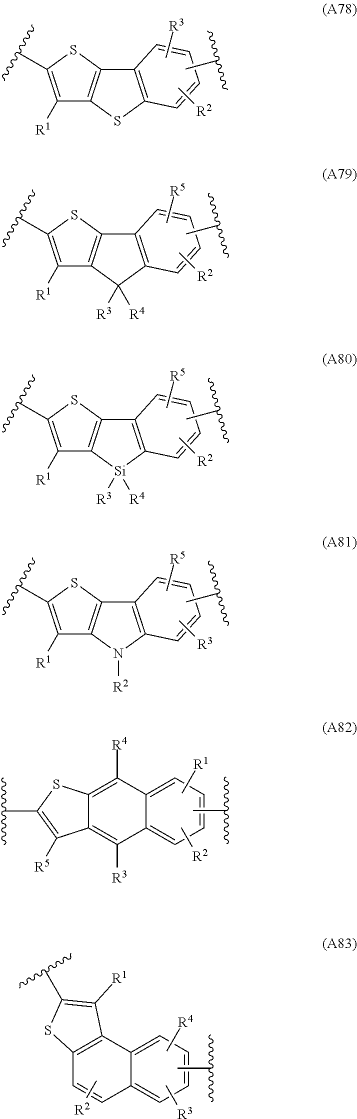

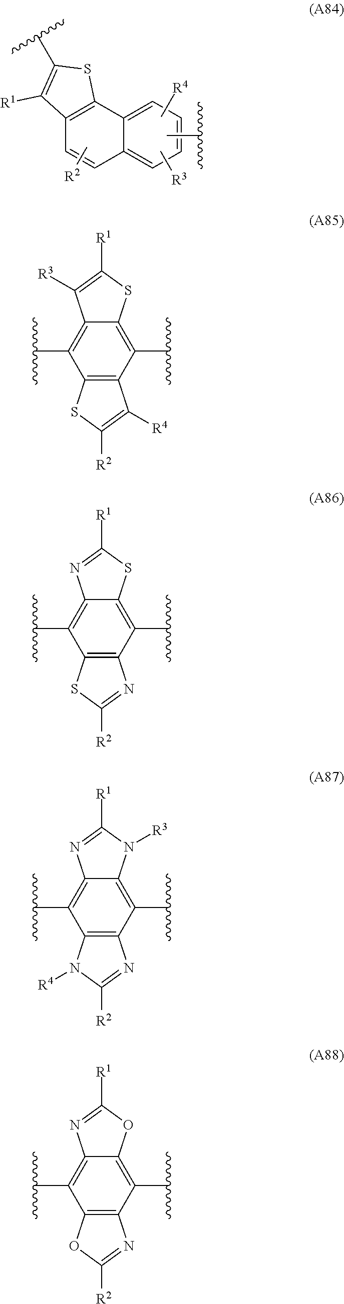

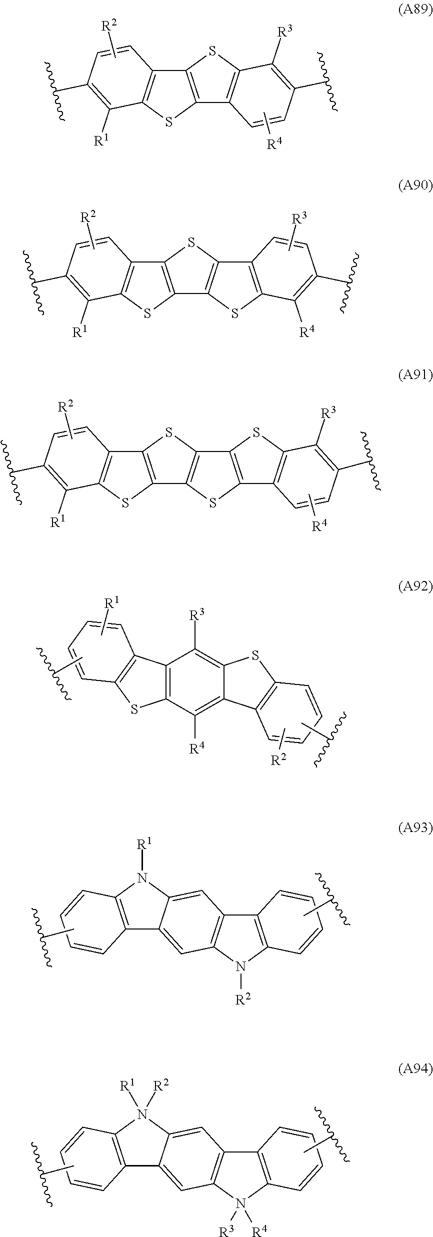

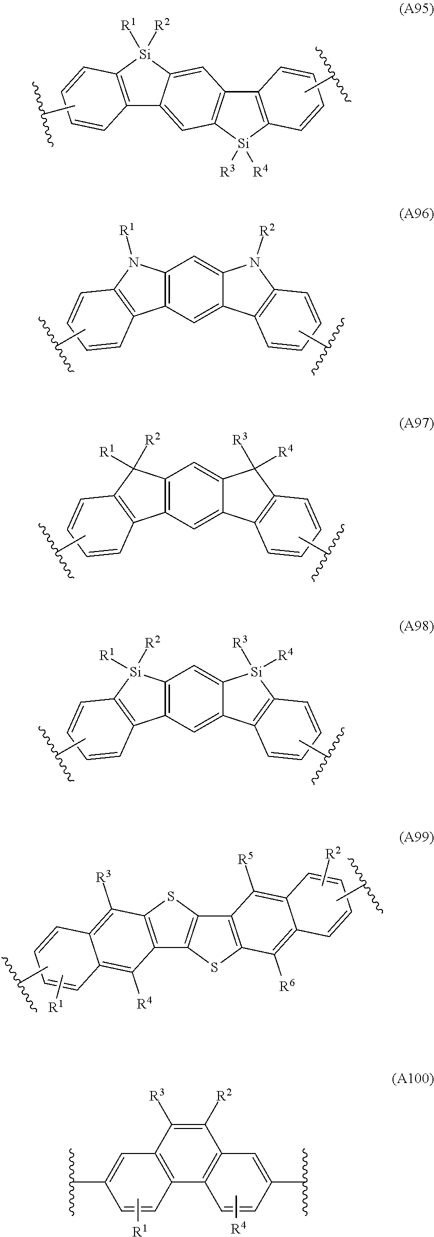

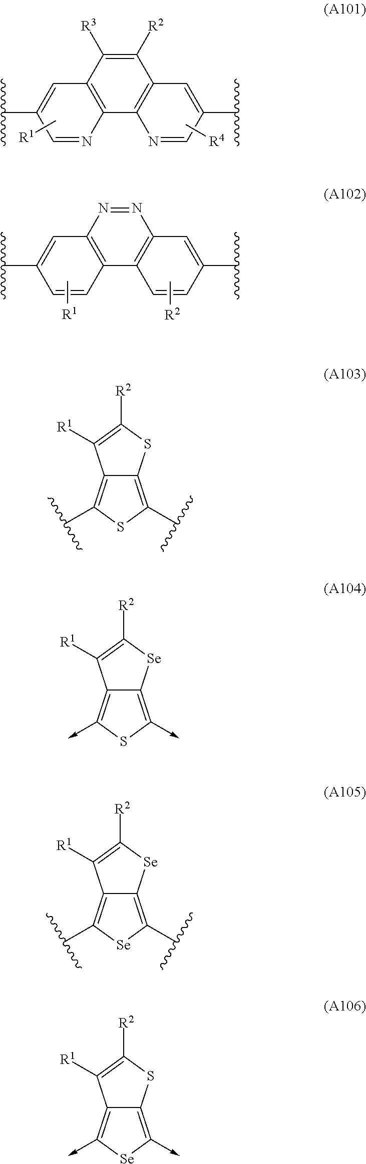

wherein the following applies to the symbols used:

R¹ is at each occurrence, identically or differently, selected from the group consisting of hydrogen, halogen, C₁-C₄₀ alkyl, C₁-C₄₀ alkoxy, aryl, heteroaryl, C₃-C₄₀ cycloalkyl, C₃-C₄₀ heterocycloalkyl, CN, OR⁹, COR⁹, COOR⁹, and CON(R⁹R¹⁰), with R¹ preferably being H, C₁-C₄₀ alkyl, or COOR⁹;

R² is at each occurrence, identically or differently, selected from the group consisting of hydrogen, halogen, C₁-C₄₀ alkyl, C₁-C₄₀ alkoxy, aryl, heteroaryl, C₃-C₄₀ cycloalkyl. C₃-C₄₀ heterocycloalkyl, CN, OR⁹, COR⁹, COOR⁹, and CON(R⁹R¹⁰), with R² preferably being H, C₁-C₄₀ alkyl, or COOR⁹;

R³ is at each occurrence, identically or differently, selected from the group consisting of hydrogen, halogen, C₁-C₄₀ alkyl, C₁-C₄₀ alkoxy, aryl, heteroaryl, C₃-C₄₀ cycloalkyl, C₃-C₄₀ heterocycloalkyl, CN, OR⁹, COR⁹, COOR⁹, and CON(R⁹R¹⁰), with R³ preferably being H, C₁-C₄₀ alkyl, or COOR⁹;

R⁴ is at each occurrence, identically or differently, selected from the group consisting of hydrogen, halogen, C₁-C₄₀ alkyl, C₁-C₄₀ alkoxy, aryl, heteroaryl, C₃-C₄₀ cycloalkyl, C₃-C₄₀ heterocycloalkyl, CN, OR⁹, COR⁹, COOR⁹, and CON(R⁹R¹⁰), with R⁴ preferably being H, C₁-C₄₀ alkyl, or COOR⁹;

R⁵ is at each occurrence, identically or differently, selected from the group consisting of hydrogen, halogen, C₁-C₄₀ alkyl, C₁-C₄₀ alkoxy, aryl, heteroaryl, C₃-C₄₀ cycloalkyl. C₃-C₄₀ heterocycloalkyl, CN, OR⁹, COR⁹, COOR⁹, and CON(R⁹R¹⁰), with R⁵ preferably being H, C₁-C₄₀ alkyl, or COOR⁹;

R⁶ is at each occurrence, identically or differently, selected from the group consisting of hydrogen, halogen, C₁-C₄₀ alkyl, C₁-C₄₀ alkoxy, aryl, heteroaryl, C₃-C₄₀ cycloalkyl. C₃-C₄₀ heterocycloalkyl, CN, OR⁹, COR⁹, COOR⁹, and CON(R⁹R¹⁰), with R⁶ preferably being H, C₁-C₄₀ alkyl, or COOR⁹;

R⁷ is at each occurrence, identically or differently, selected from the group consisting of hydrogen, halogen, C₁-C₄₀ alkyl, C₁-C₄₀ alkoxy, aryl, heteroaryl, C₃-C₄₀ cycloalkyl. C₃-C₄₀ heterocycloalkyl, CN, OR⁹, COR⁹, COOR⁹, and CON(R⁹R¹⁰), with R⁷ preferably being H, C₁-C₄₀ alkyl, or COOR⁹;

R⁸ is at each occurrence, identically or differently, selected from the group consisting of hydrogen, halogen, C₁-C₄₀ alkyl, C₁-C₄₀ alkoxy, aryl, heteroaryl, C₃-C₄₀ cycloalkyl. C₃-C₄₀ heterocycloalkyl, CN, OR⁹, COR⁹, COOR⁹, and CON(R⁹R¹⁰), with R⁹ preferably being H, C₁-C₄₀ alkyl, or COOR⁹;

R⁹ is at each occurrence, identically or differently, H, C₁-C₄₀ alkyl, aryl, heteroaryl, C₃-C₄₀ cycloalkyl, or C₃-C₄₀ heterocycloalkyl.

R¹⁰ is at each occurrence, identically or differently, H, C₁-C₄₀ alkyl, aryl, heteroaryl, C₃-C₄₀ cycloalkyl, or C₃-C₄₀ heterocycloalkyl.

More preferably, the photovoltaic cell according to the present invention, the common conjugated fused ring moiety of the donor materials is at each occurrence selected from the group consisting of formulae (A10), (A12), (A13), (A19), (A20), (A21), (A22), and (A23).

Even more preferably, the common conjugated fused ring moieties of the donor materials is at each occurrence, represented by formula (A10) or (A21).

Preferably the photovoltaic cell according to the present invention, is one wherein at least one of the donor materials comprises an electron withdrawing building block.

More preferably the photovoltaic cell according to the present invention, is one wherein at least two of the donor materials comprises the electron withdrawing building block, and the electron withdrawing building block of one of the donor materials has more electron withdrawing capability than the electron withdrawing building block of the rest of the donor materials.

Preferably the photovoltaic cell according to the present invention, is one wherein the electron withdrawing building block of the first donor material is selected from the group consisting of the following formulae (B1) to (B93)

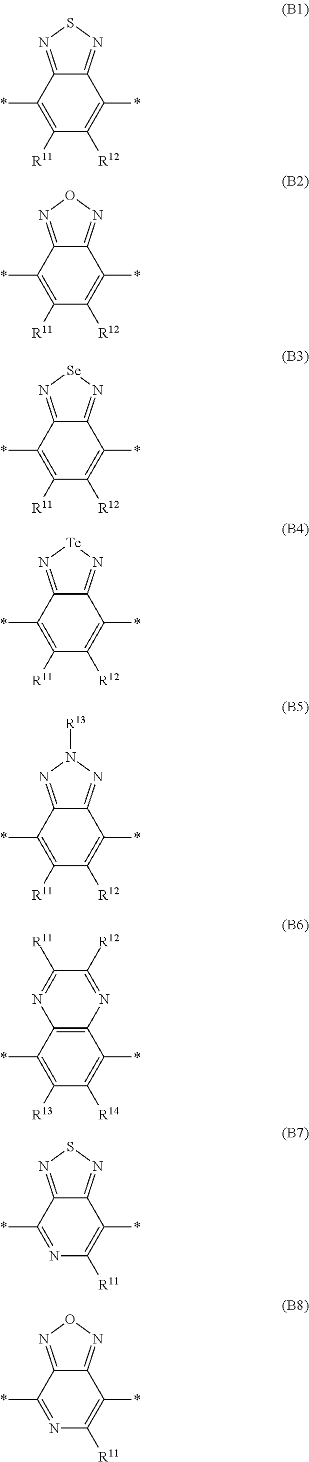

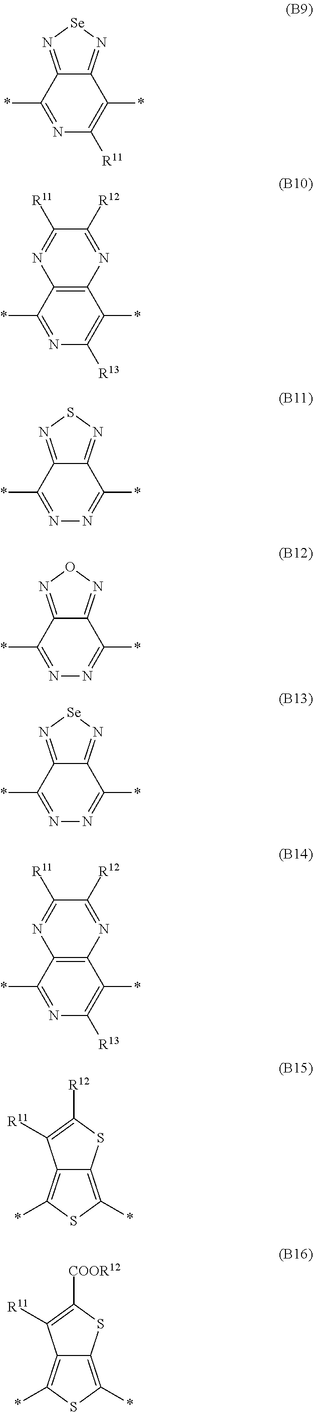

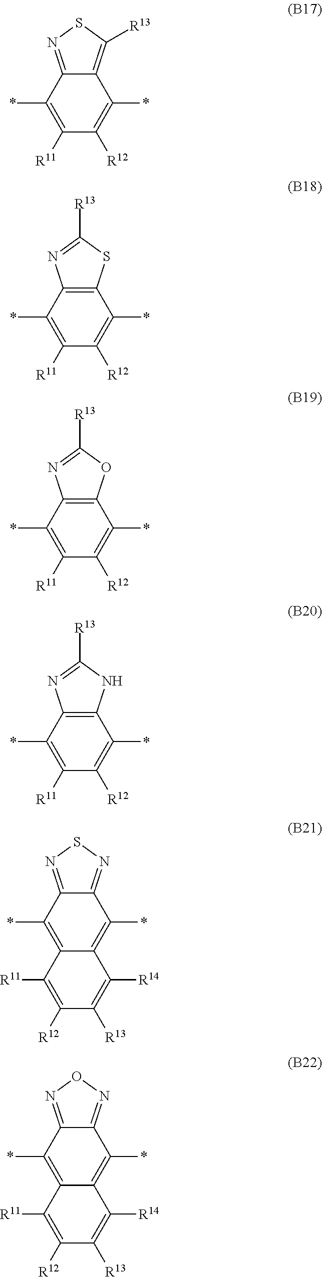

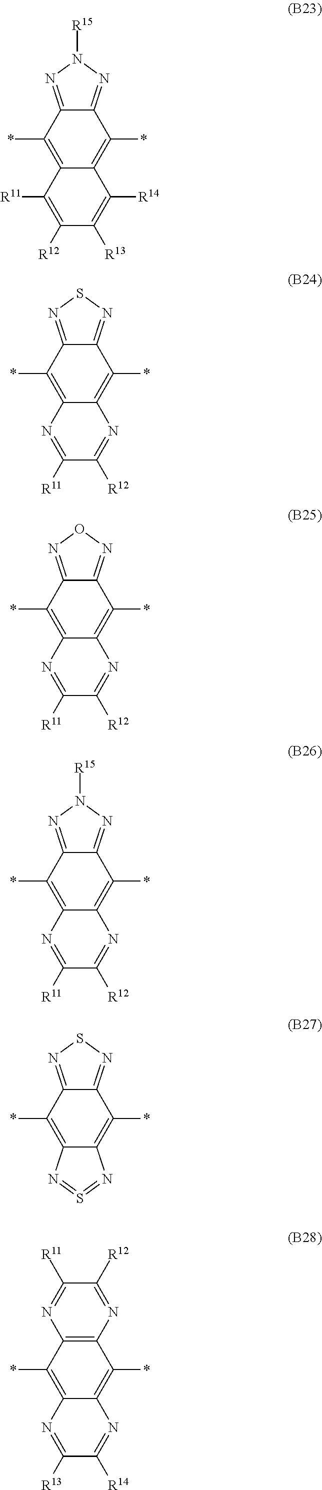

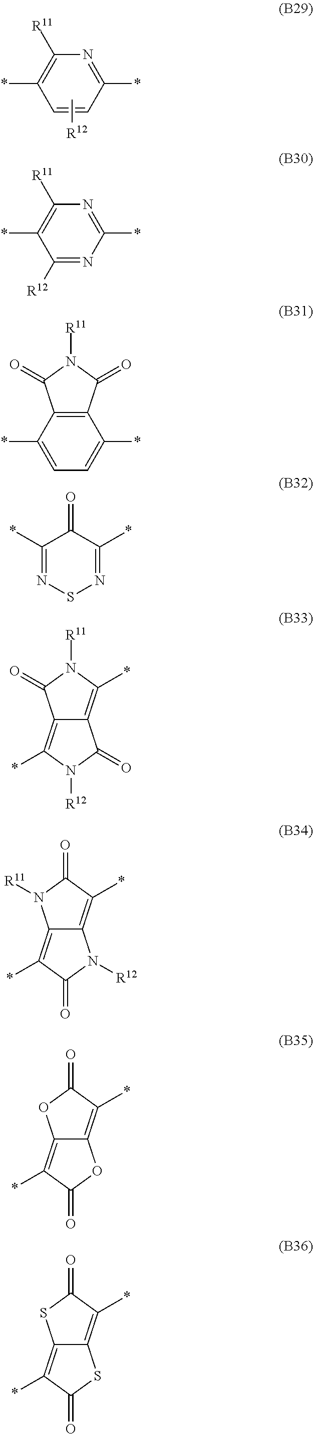

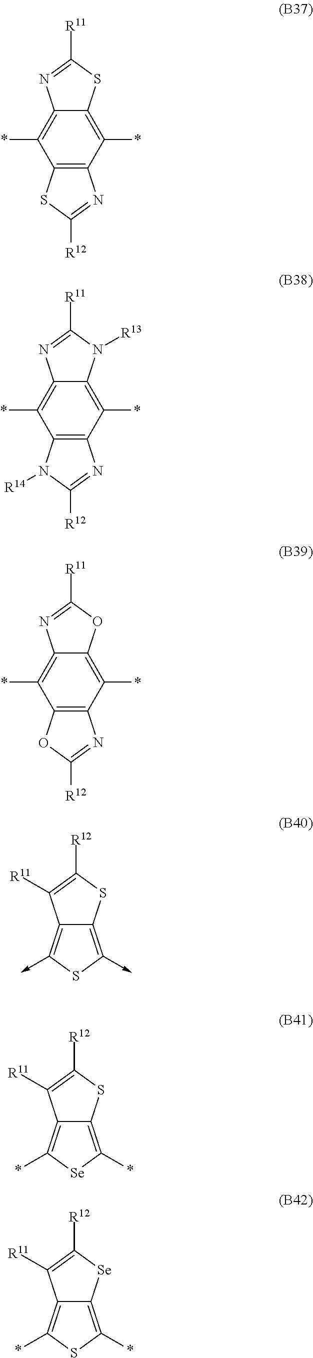

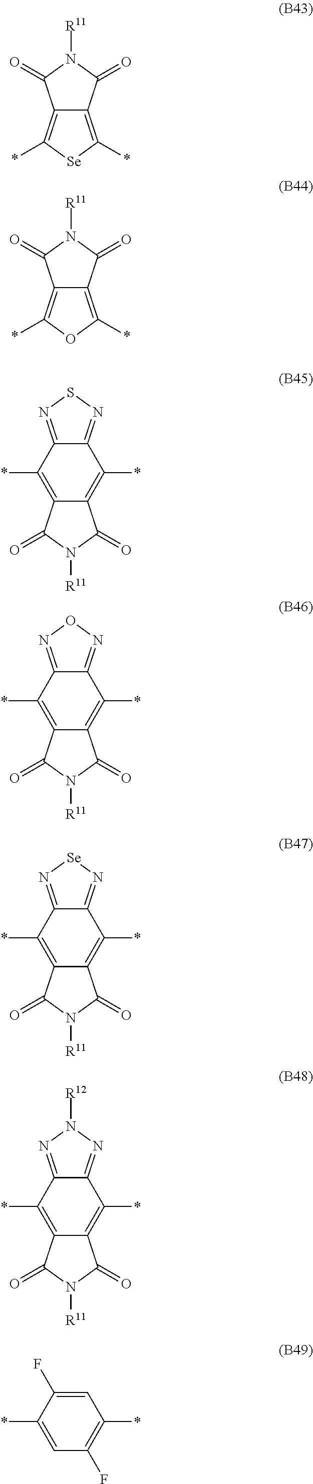

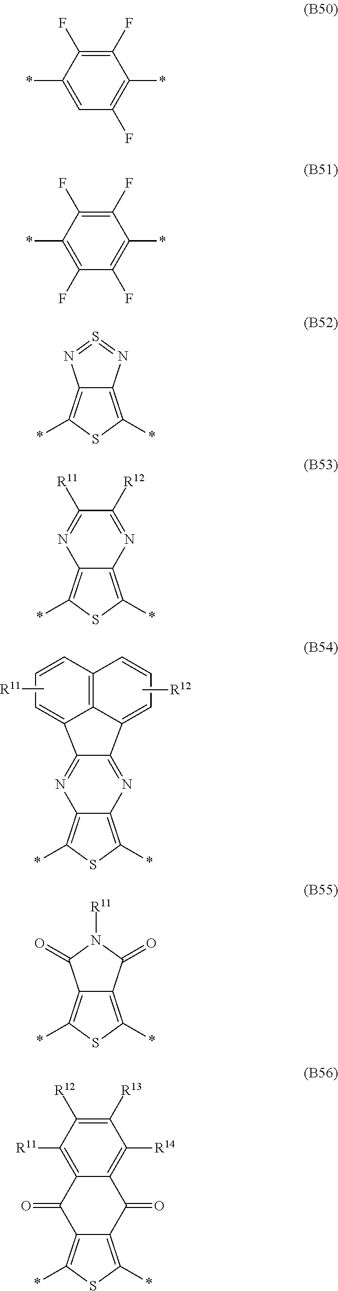

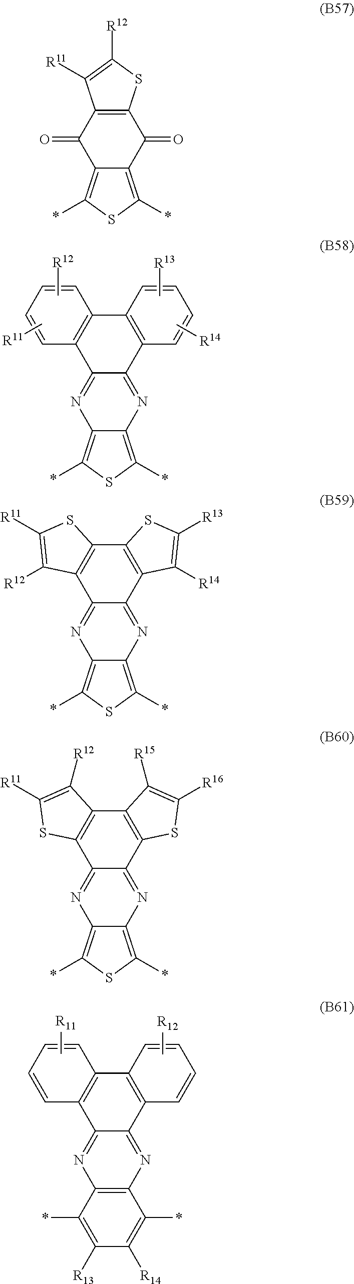

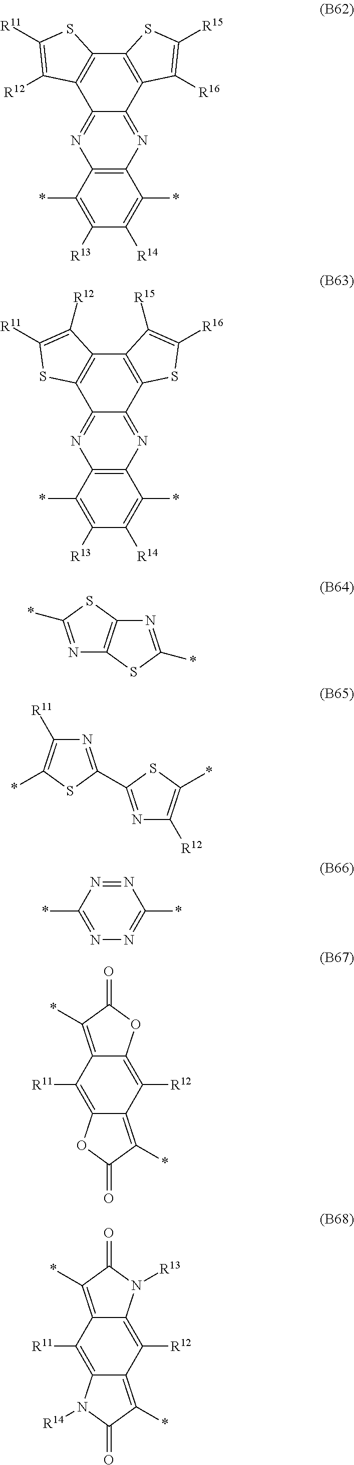

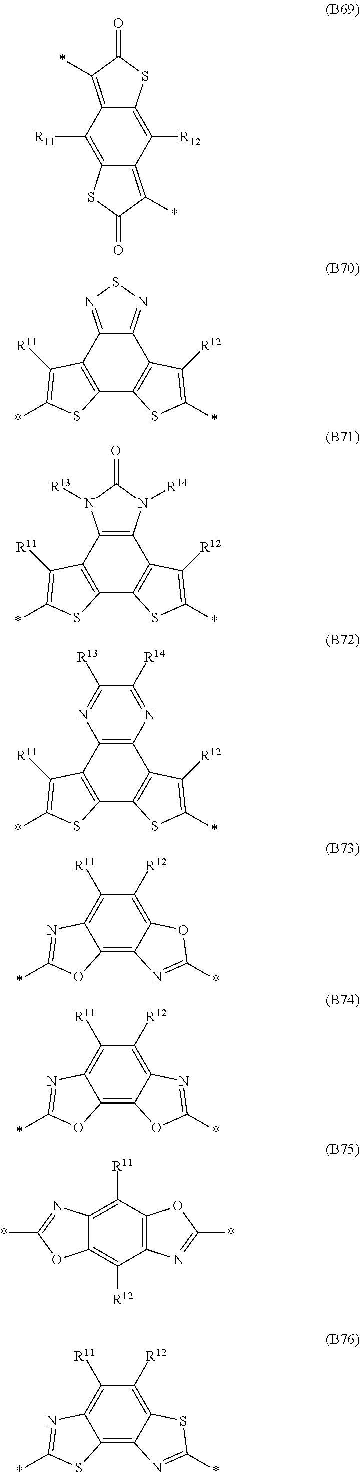

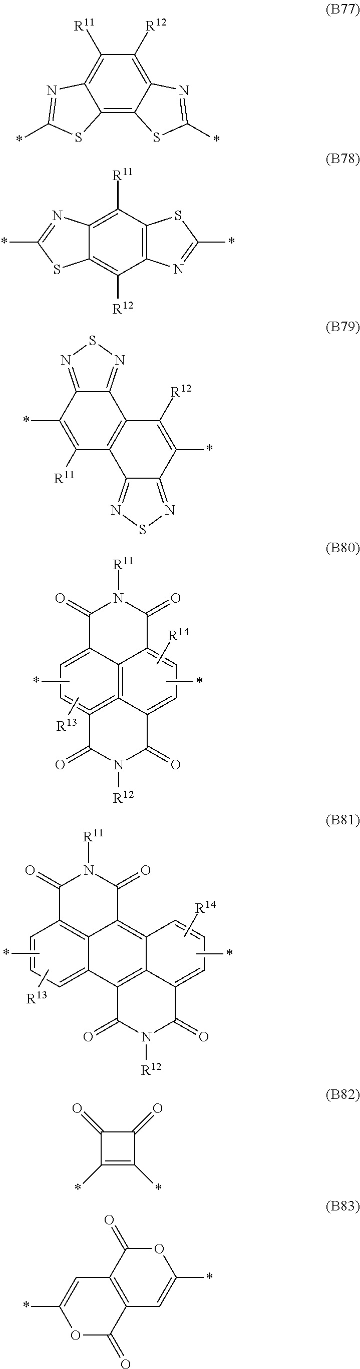

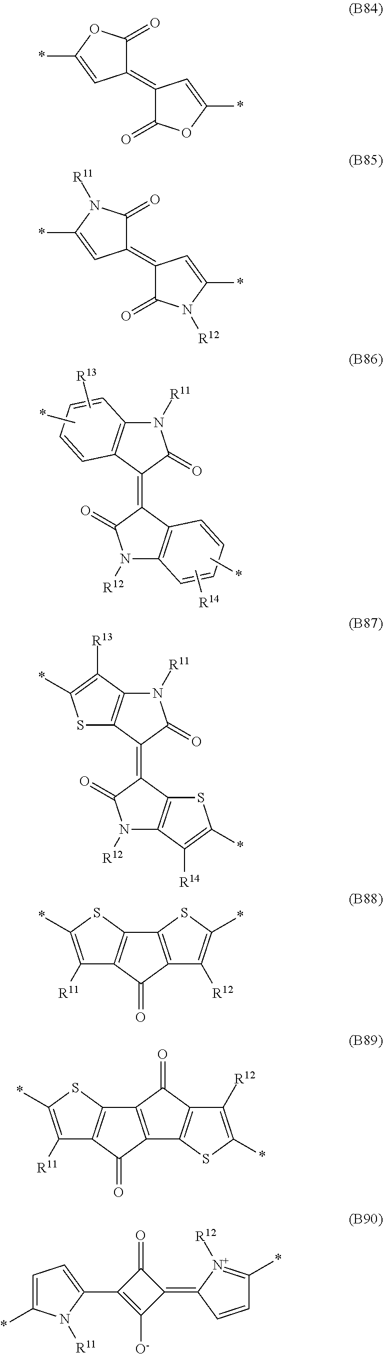

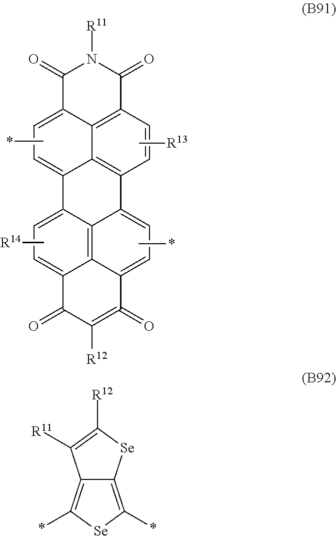

wherein the following applies to the symbols used:

R¹¹ is at each occurrence, identically or differently, selected from the group consisting of hydrogen, halogen, C₁-C₄₀ alkyl, C₁-C₄₀ alkoxy, aryl, heteroaryl, C₃-C₄₀ cycloalkyl, C₃-C₄₀ heterocycloalkyl, CN, OR¹⁷, COR¹⁷, COOR¹⁷, and CON(R¹⁷R¹⁸);

R¹² is at each occurrence, identically or differently, selected from the group consisting of hydrogen, halogen, C₁-C₄₀ alkyl, C₁-C₄₀ alkoxy, aryl, heteroaryl, C₃-C₄₀ cycloalkyl, C₃-C₄₀ heterocycloalkyl, CN, OR¹⁷, COR¹⁷, COOR¹⁷, and CON(R¹⁷R¹⁸);

R¹³ is at each occurrence, identically or differently, selected from the group consisting of hydrogen, halogen, C₁-C₄₀ alkyl, C₁-C₄₀ alkoxy, aryl, heteroaryl, C₃-C₄₀ cycloalkyl, C₃-C₄₀ heterocycloalkyl, CN, OR¹⁷, COR¹⁷, COOR¹⁷, and CON(R¹⁷R¹⁸);

R¹⁴ is at each occurrence, identically or differently, selected from the group consisting of hydrogen, halogen, C₁-C₄₀ alkyl, C₁-C₄₀ alkoxy, aryl, heteroaryl, C₃-C₄₀ cycloalkyl, C₃-C₄₀ heterocycloalkyl, CN, OR¹⁷, COR¹⁷, COOR¹⁷, and CON(R¹⁷R¹⁸);

R¹⁵ is at each occurrence, identically or differently, selected from the group consisting of hydrogen, halogen, C₁-C₄₀ alkyl, C₁-C₄₀ alkoxy, aryl, heteroaryl, C₃-C₄₀ cycloalkyl, C₃-C₄₀ heterocycloalkyl, CN, OR¹⁷, COR¹⁷, COOR¹⁷, and CON(R¹⁷R¹⁸);

R¹⁶ is at each occurrence, identically or differently, selected from the group consisting of hydrogen, halogen, C₁-C₄₀ alkyl, C₁-C₄₀ alkoxy, aryl, heteroaryl, C₃-C₄₀ cycloalkyl, C₃-C₄₀ heterocycloalkyl, CN, OR¹⁷, COR¹⁷, COOR¹⁷, and CON(R¹⁷R¹⁸);

R¹⁷ is at each occurrence, identically or differently, H, C₁-C₄₀ alkyl, aryl, heteroaryl, C₃-C₄₀ cycloalkyl, or C₃-C₄₀ heterocycloalkyl.

R¹⁸ is at each occurrence, identically or differently, H, C₁-C₄₀ alkyl, aryl, heteroaryl, C₃-C₄₀ cycloalkyl, or C₃-C₄₀ heterocycloalkyl.

and the electron withdrawing building block of the second donor material is selected from the group consisting of the following formulae (C1) to (C91),

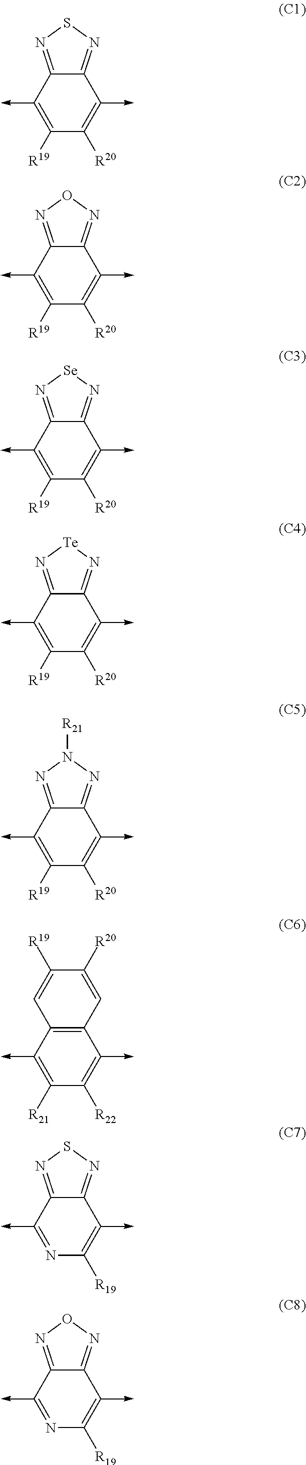

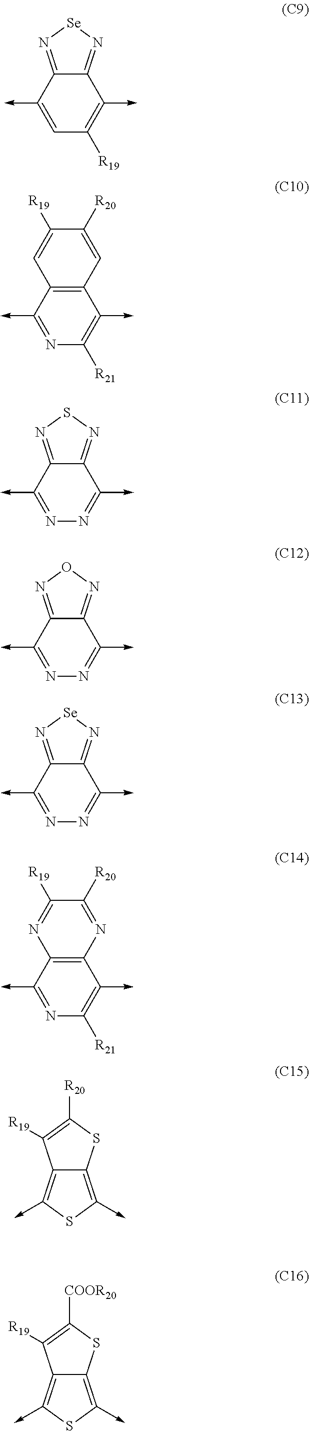

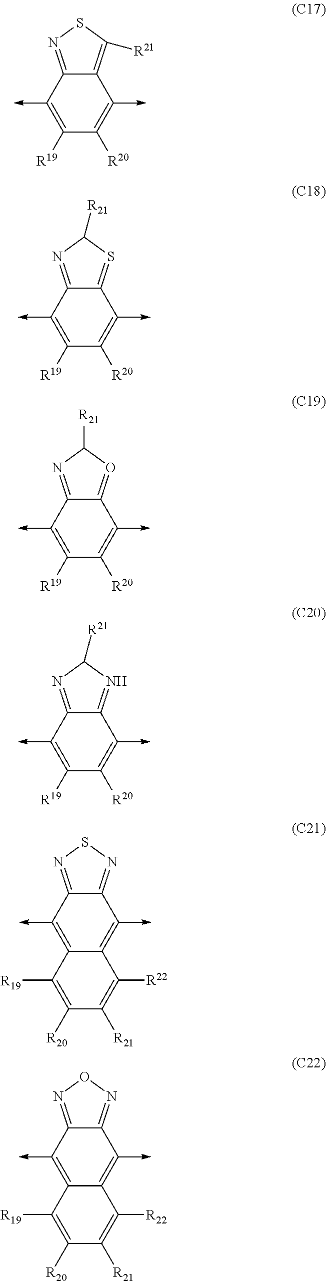

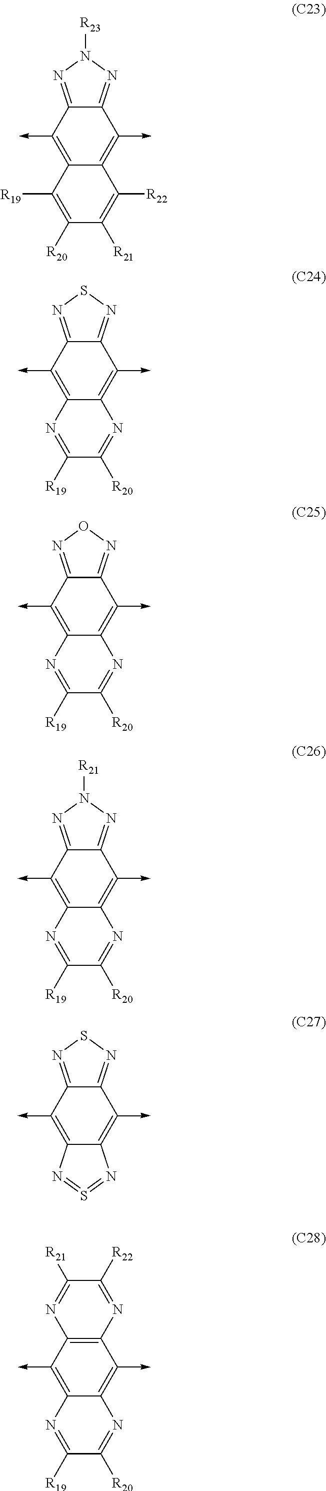

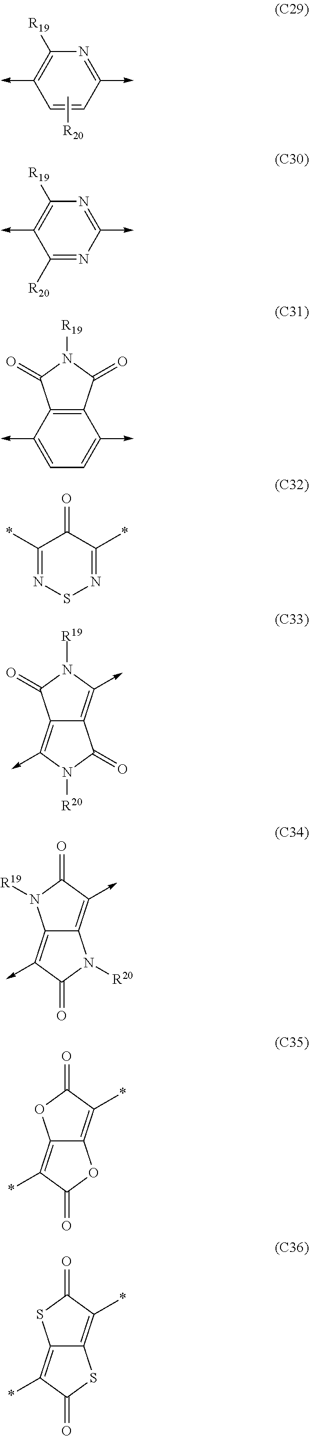

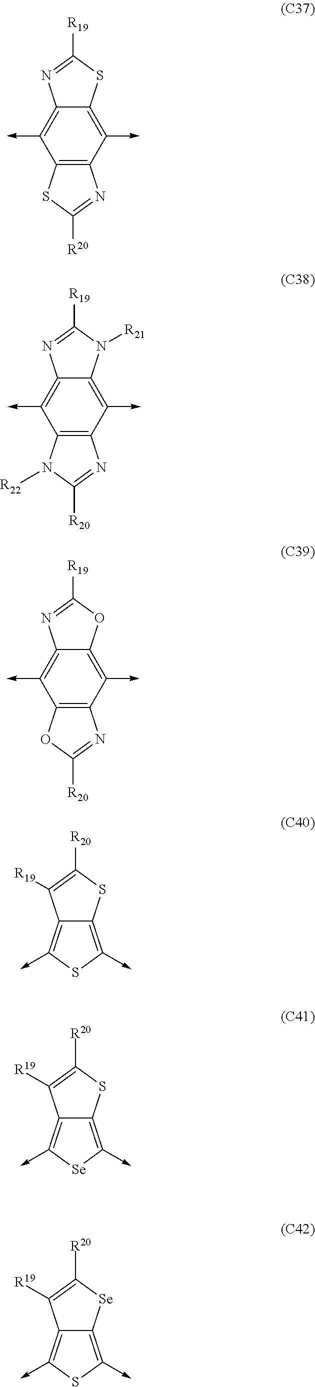

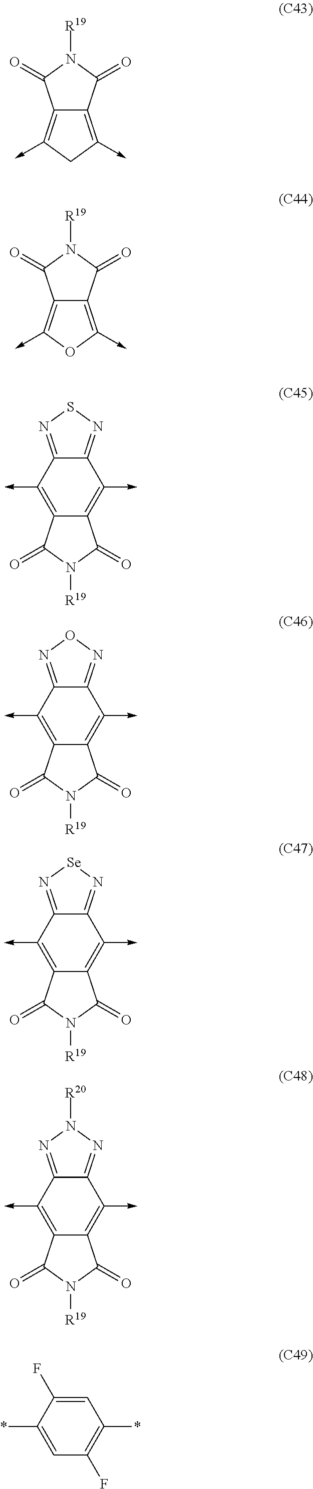

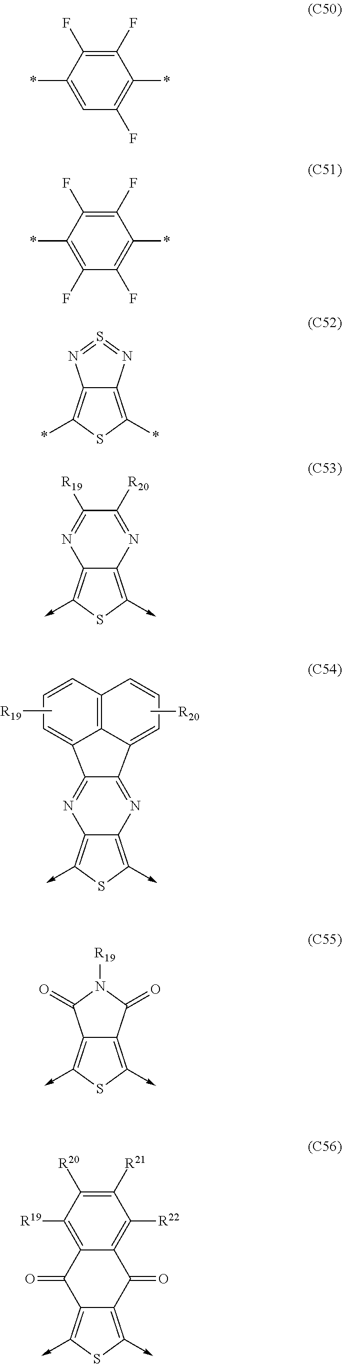

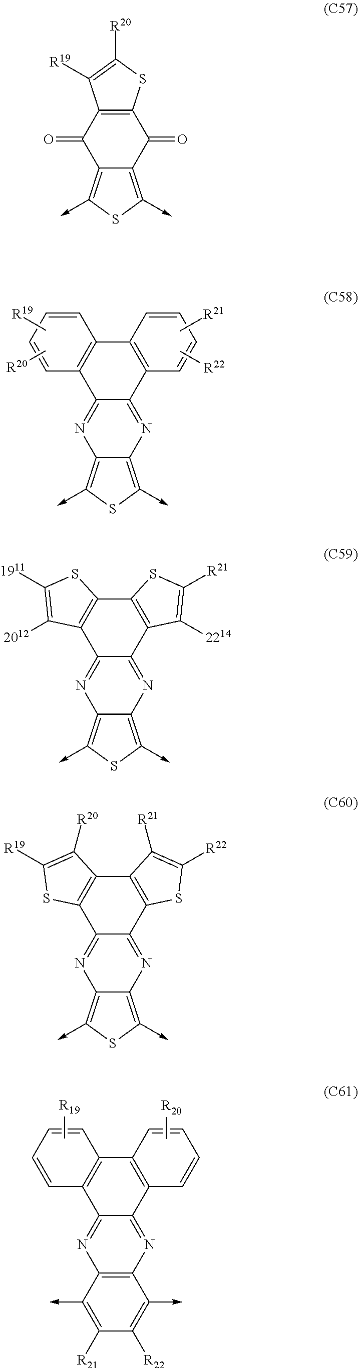

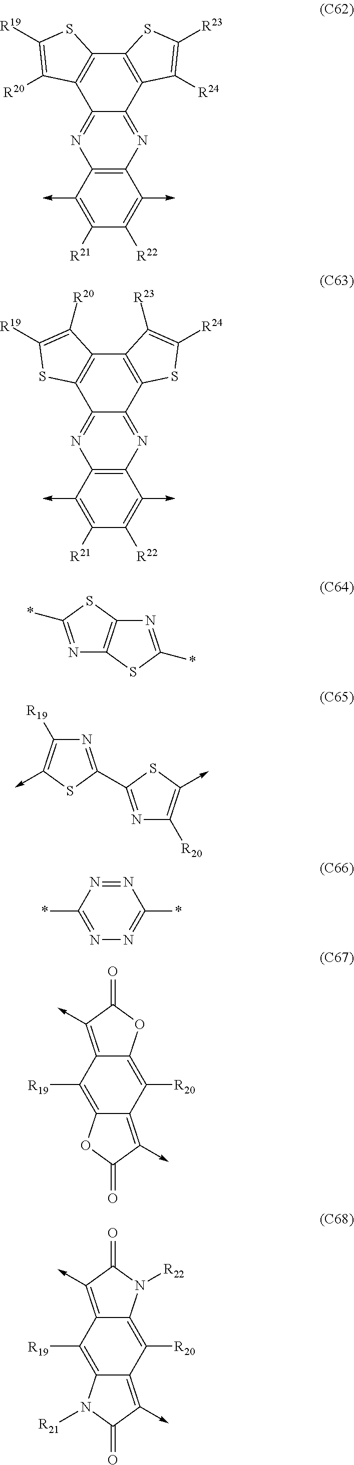

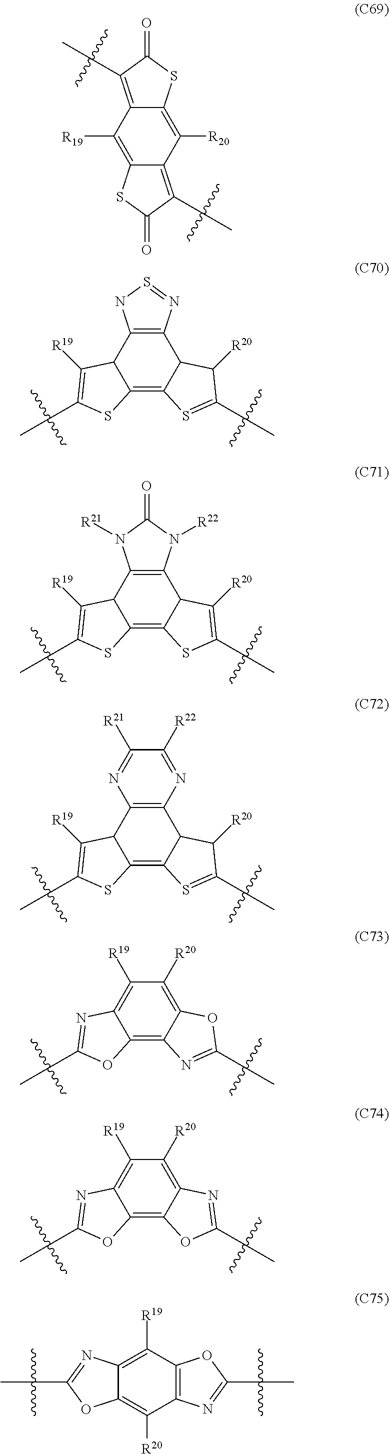

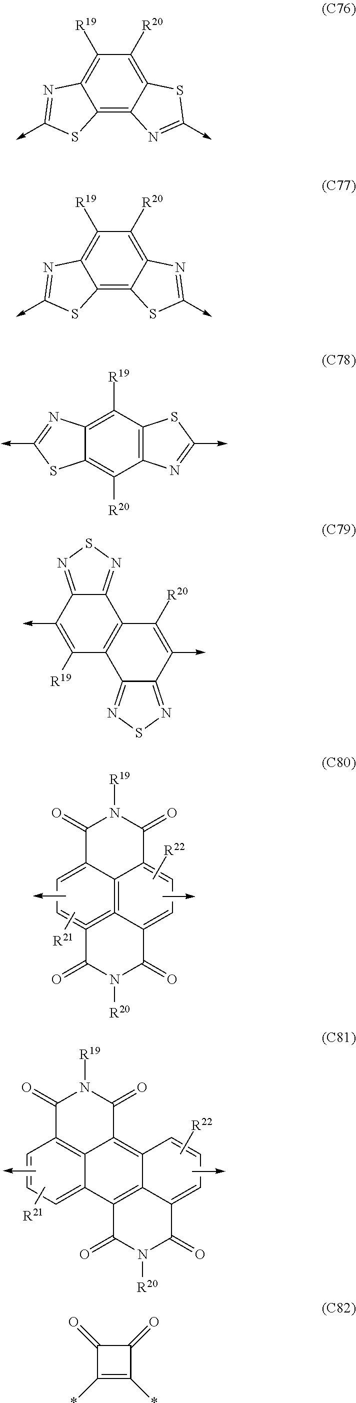

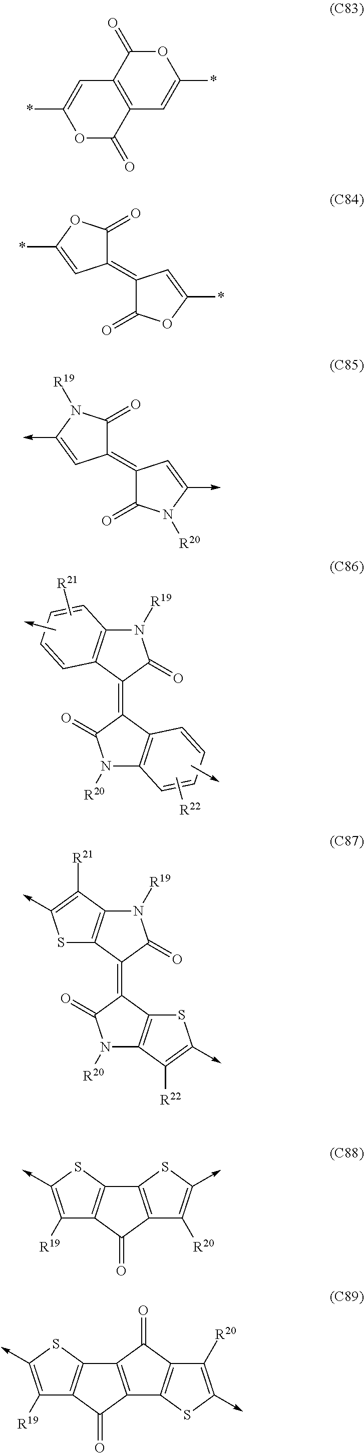

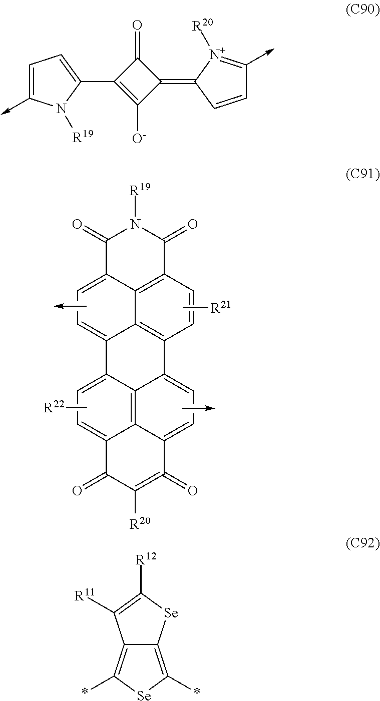

wherein the following applies to the symbols used:

R¹⁹ is at each occurrence, identically or differently, selected from the group consisting of hydrogen, halogen, C₁-C₄₀ alkyl, C₁-C₄₀ alkoxy, aryl, heteroaryl, C₃-C₄₀ cycloalkyl, C₃-C₄₀ heterocycloalkyl, CN, OR²⁵, COR²⁵, COOR²⁵, and CON(R²⁵R²⁶);

R²⁰ is at each occurrence, identically or differently, selected from the group consisting of hydrogen, halogen, C₁-C₄₀ alkyl, C₁-C₄₀ alkoxy, aryl, heteroaryl, C₃-C₄₀ cycloalkyl, C₃-C₄₀ heterocycloalkyl, CN, OR²⁵, COR²⁵, COOR²⁵, and CON(R²⁵R²⁶);

R²¹ is at each occurrence, identically or differently, selected from the group consisting of hydrogen, halogen, C₁-C₄₀ alkyl, C₁-C₄₀ alkoxy, aryl, heteroaryl, C₃-C₄₀ cycloalkyl, C₃-C₄₀ heterocycloalkyl, CN, OR²⁵, COR²⁵, COOR²⁵, and CON(R²⁵R²⁶);

R²² is at each occurrence, identically or differently, selected from the group consisting of hydrogen, halogen, C₁-C₄₀ alkyl, C₁-C₄₀ alkoxy, aryl, heteroaryl, C₃-C₄₀ cycloalkyl, C₃-C₄₀ heterocycloalkyl, CN, OR²⁵, COR²⁵, COOR²⁵, and CON(R²⁵R²⁶);

R²³ is at each occurrence, identically or differently, selected from the group consisting of hydrogen, halogen, C₁-C₄₀ alkyl, C₁-C₄₀ alkoxy, aryl, heteroaryl, C₃-C₄₀ cycloalkyl, C₃-C₄₀ heterocycloalkyl, CN, OR²⁵, COR²⁵, COOR²⁵, and CON(R²⁵R²⁶);

R²⁴ is at each occurrence, identically or differently, selected from the group consisting of hydrogen, halogen, C₁-C₄₀ alkyl, C₁-C₄₀ alkoxy, aryl, heteroaryl, C₃-C₄₀ cycloalkyl, C₃-C₄₀ heterocycloalkyl, CN, OR²⁵, COR²⁵, COOR²⁵, and CON(R²⁵R²⁶);

R²⁵ is at each occurrence, identically or differently, H, C₁-C₄₀ alkyl, aryl, heteroaryl, C₃-C₄₀ cycloalkyl, or C₃-C₄₀ heterocycloalkyl.

R²⁶ is at each occurrence, identically or differently, H, C₁-C₄₀ alkyl, aryl, heteroaryl, C₃-C₄₀ cycloalkyl, or C₃-C₄₀ heterocycloalkyl.

In a particularly preferred embodiment of the invention, the electron withdrawing building block of the first donor material is represented by any one of formulae (B15), (B16), (B45), (B46), (B47), and (B48); the electron withdrawing building block of the second donor material is represented by the formula (C64).

More particularly preferably, the electron withdrawing building block of first donor material is represented by any one of formulae (B15), (B16), and (B45); the electron withdrawing building block of the second donor material is represented by the formula (C64).

In a preferred embodiment of the present invention, at least one of the donor materials is a polymer or an oligomer.

More preferably, at least one of the donor materials comprises a phenyl moiety represented by following formula (1),

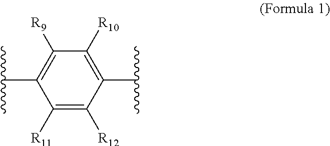

in which R₉, R₁₀, R₁₁ and R₁₂, are at each occurrence, identically or differently, is H, halogen (e.g., fluorine, chlorine, or bromine), or C1-C4 trihaloalkyl (e.g., trifluoromethyl), provided that at least two of R₉, R₁₀, R₁₁ and R₁₂ are halogen or C₁-C₄ trihaloalkyl. Preferably, R₉, R₁₀, R₁₁ and R₁₂ are halogen. Most preferably, R₉, R₁₀, R₁₁ and R₁₂ are fluorine.

Even more preferably, at least two of the donor materials are, at each occurrence, independently of each other selected from the group consisting of KP179, KP252 and KP184, or KP143, and KP155.

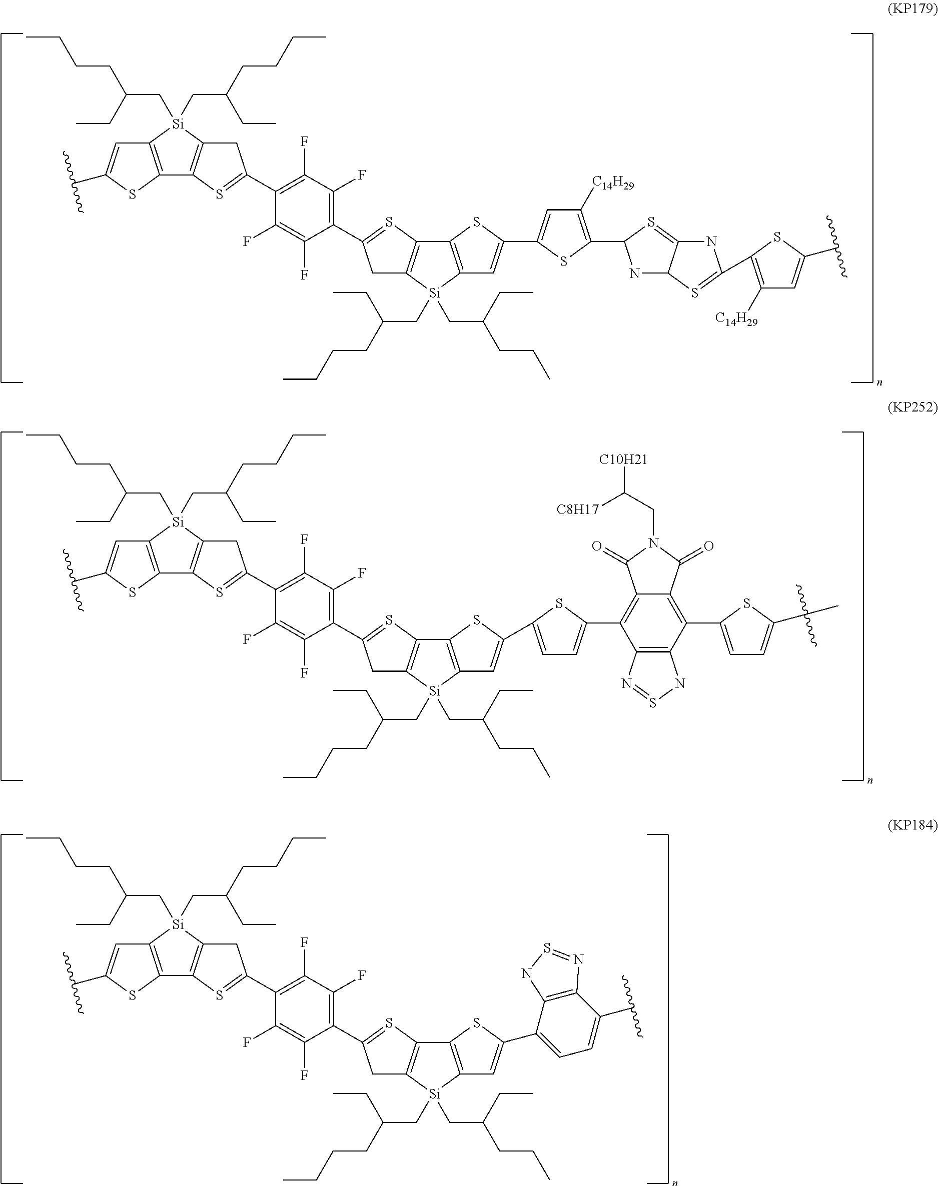

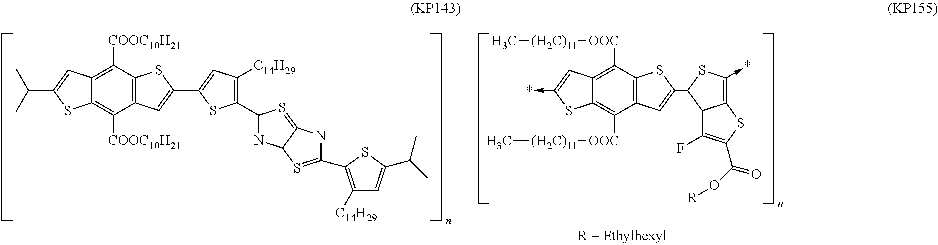

where in the chemical structures mentioned above, the index “n” means a number average degree of polymerization.

The donor materials described above can be obtained as described, for example, in U.S. Pat. No. 7,781,673B, U.S. Pat. No. 8,058,550B, U.S. Pat. No. 8,455,606B, U.S. Pat. No. 8,008,424B, US2007/0020526A, U.S. Pat. No. 77,724,285B, U.S. Pat. No. 8,008,421 B, US2010/0224252A, WO2011/085004A, and WO2012/030942A. Or the donor materials can be prepared by methods known in the arts. For example, a copolymer can be prepared by a cross-coupling reaction between one or more monomers containing two organometallic groups (e.g., alkylstanyl groups, Grignard groups, or alkylzinc groups) and one or more monomers containing two halo groups (e.g., Cl, Br, or I) in the presence of a transition metal catalyst. Other methods that can be used to prepare the copolymers described above include Suzuki coupling reactions, Negishi coupling reactions, Kumada coupling reactions, and Stille coupling reactions.

Examples 1-4 below provide descriptions of how donor materials used in the other examples and comparative examples were prepared.

The monomers suitable for preparing the donor materials described above can be prepared by the methods described herein or by the methods known in the arts, such as those described in Macromolecules 2003, 36, 2705-2711, Kurt et al., J. Heterocycl. Chem. 1970, 6, 629, Chen et al., J. Am. Chem. Soc., (2006) 128(34), 10992-10993, Hou et al., Macromolecules (2004), 37, 6299-6305, and Bijleveld et al., Adv. Funct. Mater., (2009), 19, 3262-3270.

Preferably the acceptor material comprises a compound selected from the group consisting of fullerene, fullerene derivatives, perylene diimide derivatives, benzo thiazole derivatives, diketo-pyrrolo-pyrrole derivatives, bi-fluorenylidene derivatives, pentacene derivatives, quinacridone derivatives, fluoranthene imide derivatives, boron-dipyrromethene derivatives, oxadiazoles, metal phthalocyanine and sub-phthalocyanine, inorganic nanoparticles, discotic liquid crystals, cabon nanorods, inorganic nanorods, polymers containing CN groups, polymers containing CF₃ groups, or a combination of any of these.

More preferably, the acceptor material comprises a substituted fullerene.

Even more preferably, the substituted fullerene is selected from the group consisting of PC60BM, PC61BM, PC70BM and a combination of any of these.

In a preferred embodiment of the present invention, the photoactive layer further comprises a dopant.

More preferably, the dopant is selected from the group consisting of diiodo octane, octadecanethiol, phenylnaphthalene and a combination of any of these.

The invention further relates to the use of donor materials in a photovoltaic cell;

wherein the photovoltaic cell (100) comprises:
a first electrode (120);
a second electrode (160); and
a photoactive layer (140) between the first electrode (120) and the second electrode (160),

wherein the photoactive layer (140) comprises a first donor material, second donor material and acceptor material; the first donor material and the second donor material being different from each other and each of the donor materials comprising a common building block of the same chemical structure, said common building block comprising a conjugated fused ring moiety.

In general, the method of preparing the photoactive layer (140) can vary as desired.

In some embodiments, photoactive layer (140) can preferably be prepared by using a liquid-based coating process.

The term “liquid-based coating process” means a process that uses a liquid-based coating composition.

Here, the term “liquid-based coating composition” embraces solutions, dispersions, and suspensions.

More specifically, the liquid-based coating process can be carried out by using at least one of the following processes: solution coating, ink jet printing, spin coating, dip coating, knife coating, bar coating, spray coating, roller coating, slot coating, gravure coating flexographic printing, offset printing, relief printing, intaglio printing, or screen printing.

In general, the donor materials and the acceptor material may together be dissolved in a solvent, in which situation the donor materials and the acceptor material may first be mixed together and then dissolved in the solvent. Or they may be dissolved separately in the same solvent or in different solvents to obtain separate solutions, which are then mixed. After mixing, the resulting solution is coated over the layer underneath by a liquid coating process as defined herein.

In one aspect, the invention therefore further relates to a method for preparing the photovoltaic cell of the present invention, said method for preparing the photovoltaic cell of the present invention comprising the steps of
(a) dissolving at least the first donor material, the second donor material and the acceptor material together in a solvent,
(b) subsequently coating the resulting solution from step (a) over a layer underneath,

wherein the first donor material and the second donor material are different from each other and each of the donor materials comprises a common building block of the same chemical structure, said common building block comprising a conjugated fused ring moiety.

In another aspect, the present invention also relates to a method for preparing the photovoltaic cell of the present invention, said method comprising the steps of
(a′) dissolving at least the first donor material, the second donor material and the acceptor material each separately in a same type or different type of solvent to obtain different solutions;
(b′) mixing the resulting solutions from step (a′) to obtain a solution which contains the first donor material, the second donor material and the acceptor material;
(c′) subsequently coating the resulting solution from step (b′) over a layer underneath,

wherein the first donor material and the second donor material are different from each other and each of the donor materials comprises a common building block of a same chemical structure, said common building block comprising a conjugated fused ring moiety.

Preferably the solvent is selected from organic solvents.

More preferably, said solvent is selected from the group consisting of aliphatic hydrocarbons, chlorinated hydrocarbons, aromatic hydrocarbons, ketones, ethers and mixtures thereof. Additional solvents which can be used include 1,2,4-trimethylbenzene, 1,2,3,4-tetra-methyl benzene, pentylbenzene, mesitylene, cumene, cymene, cyclohexylbenzene, diethylbenzene, tetralin, decalin, 2,6-lutidine, 2-fluoro-m-xylene, 3-fluoro-o-xylene, 2-chlorobenzotrifluoride, N,N-dimethylformamide, 2-chloro-6-fluorotoluene, 2-fluoroanisole, anisole, 2,3-dimethylpyrazine, 4-fluoroanisole, 3-fluoroanisole, 3-trifluoro-methylanisole, 2-methylanisole, phenetol, 4-methylanisole, 3-methylanisole, 4-fluoro-3-methylanisole, 2-fluorobenzonitrile, 4-fluoroveratrol, 2,6-dimethylanisole, 3-fluorobenzo-nitrile, 2,5-dimethylanisole, 2,4-dimethylanisole, benzonitrile, 3,5-dimethyl-anisole, N,N-dimethylaniline, ethyl benzoate, 1-fluoro-3,5-dimethoxy-benzene, 1-methylnaphthalene, N-methylpyrrolidinone, 3-fluorobenzo-trifluoride, benzotrifluoride, dioxane, trifluoromethoxy-benzene, 4-fluorobenzotrifluoride, 3-fluoropyridine, toluene, 2-fluoro-toluene, 2-fluorobenzotrifluoride, 3-fluorotoluene, 4-isopropylbiphenyl, phenyl ether, pyridine, 4-fluorotoluene, 2,5-difluorotoluene, 1-chloro-2,4-difluorobenzene, 2-fluoropyridine, 3-chlorofluoro-benzene, 1-chloro-2,5-difluorobenzene, 4-chlorofluorobenzene, chloro-benzene, o-dichlorobenzene, 2-chlorofluorobenzene, p-xylene, m-xylene, o-xylene or mixture of o-, m-, and p-isomers or a combination of any of these.

Turning to other components of the photovoltaic cell of the present invention, electrode (120) is generally formed of an electrically conductive material. The type of the electrically conductive material is not particularly limited. For example, suitable electrically conductive materials include electrically conductive metals, electrically conductive alloys, electrically conductive polymers, or electrically conductive metal oxides or a combination of any of these.

Exemplary electrically conductive metals can include gold, silver, copper, aluminum, nickel, palladium, platinum, titanium or a combination of any of these. Exemplary electrically conductive alloys include stainless steel (e.g., 332 stainless steel, 316 stainless steel), alloys of gold, alloys of silver, alloys of copper, alloys of aluminum, alloys of nickel, alloys of palladium, alloys of platinum, alloys of titanium, carbon, graphene, carbon nano-tube or a combination of any of these.

Exemplary electrically conducting polymers can include polythiophenes (e.g., doped poly (3,4-ethylenedioxythiopphene) (doped PEDOT)), polyanilines (e.g., doped polyanilines), polypyrroles (e.g., doped polypyrroles), or a combination of any of these.

Exemplary electrically conductive metal oxides can include indium tin oxide (ITO), zinc oxide (ZnO), fluorine doped tin oxide (FTO), tin oxide.

The electrode (120) may consist of two or more stacked layers. Without wishing to be bound by theory it is believed that such an electrode may lead to an increased conductivity and/or environmental stability of the electrode (120).

In some embodiments, electrode (120) can be a mesh electrode to enhance flexibility and/or transparency of the photovoltaic cell (100). Examples of mesh electrodes are described in U.S. Patent Application Publication Nos. 2004-0187911 and 2006-0090791.

Preferably, the photovoltaic cell of the present invention can include a substrate (110).

The material for substrate (110) is not particularly limited. Transparent or non transparent materials can be used as desired.

In general, substrate (110) can be flexible, semi-rigid or rigid.

Suitable examples are metal substrate, carbon substrate, alloy substrate, glass substrate, thin glass substrate stacked on a polymer film, polymer substrate, ceramics or a combination of any of these.

Preferably, a transparent substrate, such as a transparent polymer substrate, glass substrate, thin glass substrate stacked on a transparent polymer film, transparent metal oxides (for example, silicone oxide, aluminum oxide, titanium oxide), can be used in the photovoltaic cell.

In another aspect, to increase its photoconversion efficiency, a reflective substrate can be used in this way. Such as metal substrate, substrate having reflective layer (e.g., Al, Ti or reflective multilayer) on the top of the surface of the substrate.

In another aspect, metal substrate can be used in this way preferably, to reduce its thermal damage for a photovoltaic cell.

A transparent polymer substrate can be made from polyethylene, ethylene-visyl acetate copolymer, ethylene-vinylalcohol copolymer, polypropylene, polystyrene, polymethyl methacrylate, polyvinylchloride, polyvinylalcohol, polyvinylvutyral, nylon, polyether ether ketone, polysulfone, polyether sulfone, tetrafluoroethylene-erfluoroalkylvinyl ether copolymer, polyvinylfluoride, tetraflyoroethylene ethylene copolymer, tetrafluoroethylene hexafluoro polymer copolymer, or a combination of any of these.

Optionally, the photovoltaic cell of the present invention can include a hole blocking layer (130) between the electrode (120) and the photoactive layer (140). The hole blocking layer (130) may consist of two or more stacked layers. Without wishing to be bound by theory it is believed that such a hole blocking layer may allow to control or adjust electron transport and/or hole blocking ability of the hole blocking layer (130).

Generally, the hole blocking layer (130) is formed of a material that, at the thickness used in photovoltaic cell (100), transports electrons to electrode (120) and substantially blocks the transport of holes to electrode (120).

For example, the hole blocking layer (130) can be formed by LiF, metal oxides (e.g., zinc oxide or titanium oxide), organic materials which have an ability of electron transport and hole blocking substantially.

As examples of organic materials, glycerol diglycidyl ether (DEG), polyethylenimine (PEI), disclosed in WO 2012/154557A, a polyethylenimine having amino group disclosed in U.S. Patent application Publication No. 2008-0264488 (now U.S. Pat. No. 8,242,356), especially mentioned below can be used as a single component or a combination of any of these preferably:

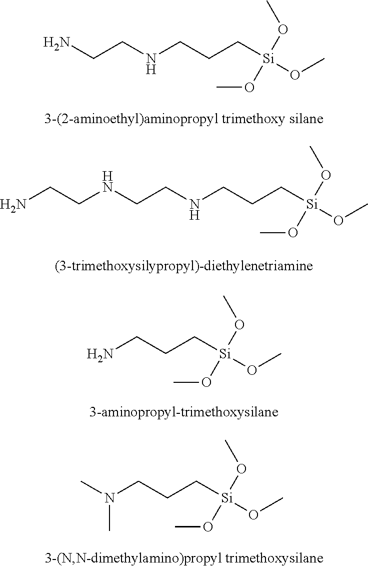

Without wishing to be bound by theory, it is believed that, when photovoltaic cell (100) includes a hole blocking layer (130) made of amines, the hole blocking layer can facilitate the formation of an ohmic contact between photoactive layer (140) and electrode (120) without being exposed to UV light, thereby reducing damage to photovoltaic cell (100) resulting from such UV exposure.

The thickness of the hole blocking layer (130) may be varied as desired. In some embodiments, hole blocking layer (130) can have a thickness of at least 1 nm and/or at the most 500 nm.

Preferably, the thickness of the hole blocking layer (130) is at least 2 nm and/or at the most 100 nm.

Optionally, the photovoltaic cell of the present invention can include a hole carrier layer (150) between the photoactive layer (140) and the electrode (160). The hole carrier layer (150) can be two or more of stacked layers to control and/or adjust hole transport/electron blocking ability of the hole carrier layer (150) preferably.

Generally, the hole carrier layer (150) is formed of a material that, at the thickness used in photovoltaic cell (100), transports holes to electrode (160) and substantially blocks the transport of holes to electrode (170).

The hole carrier layer (150) is generally formed of a hole transportable material. The type of the hole transport material is not particularly limited. For example, polythiophenes (e.g., PEDOT), polyanilines, polycarbazoles, polyvinylcarbazoles, polyphenylenes, polyphenylvinylenes, polysilanes, polythienylenevinylenes, polyisothianaphethanenes, copolymers thereof, and a combination of any of these.

In some embodiments, metal oxides such as MoO₃, or organic materials having hole transport ability, such as thiophenes, anilines, carbazoles, phenylenes, amino derivatives, can be used to form the hole carrier layer (150).

In some embodiments, hole carrier layer (150) can include a dopant used in combination with one or more of aforementioned hole transport materials.

For example of dopants, poly(styrene-sulfonate)s, polymeric sulfonic acides, fluorinated polymers (e.g., fluorinated ion exchange polymers), TCNQs (e.g., F4-TCNQ), and materials having electron acceptability disclosed in EP 1476881, EP1596445, PCT/US2013/035409 or a combination of any of these.

The thickness of the hole carrier layer (150) may be varied as desired. The thickness may for example depend upon the work functions of the neighboring layers in a photovoltaic cell (100).

In some embodiments, hole carrier layer (150) can have a thickness of at least 1 nm and/or at the most 500 nm.

Electrode (160) is generally formed of an electrically conductive material, such as one or more of the electrically conductive materials described above with respect to electrode (120). In some embodiments, electrode (160) can be formed of a mesh electrode as described above with respect to electrode (120).

Optionally, the photovoltaic cell (100) can have a passivation layer (170) to protect underlying layers (120), (130), (140), (150), and/or (160). Such passivation layers have been found useful for protecting the photoactive layer (140).

Transparent substrates described above with respect to substrate (110) can be used as the passivation layer (170).

In some embodiments, transparent metal oxides, such as alumina, silicone oxide, titanium oxide, water glass (sodium silicate aqueous solution), or transparent polymers, can be used to form the passivation layer (170).

In some embodiments, the photovoltaic cell according to the present invention can further include a wavelength conversion layer, and/or an antireflection layer on the top of electrode (160) or on the top of the passivation layer (170) to enhance photoconversion efficiency.

In come embodiments, the passivation layer (170) can be the wavelength conversion layer or antireflection layer.

In general, the methods of preparing each of layers (120), (130), (150), (160), and (170) in photovoltaic cell (100) can vary as desired and be selected from well known techniques.

In some embodiments, layers (120), (130), (150), (160) or (170) can be prepared by a gas phase based coating process (such as Chemical Vapor Deposition, vapor deposition, flash evaporation), or a liquid-based coating process.

In some embodiments, photovoltaic cell (100) can be prepared in a continuous manufacturing process, such as a roll-to-roll process, thereby significantly reducing the manufacturing cost. Examples of roll-to-roll processes have been described in, for example, U.S. Pat. Nos. 7,476,278 and 8,129,616.

In some embodiments, photovoltaic cell (100) can include the layer as shown in FIG. 1 in reverse order. In other words, photovoltaic cell (100) can include these layers from the bottom to the top in the following sequence: an optional substrate (110), an electrode (160), a photoactive layer (140), an electrode (120), and optionally a passivation layer (170). A reversed photovoltaic cell (100) can comprise an optional hole carrier layer (150) between the electrode (160) and the photoactive layer (140), and/or a hole blocking layer (130) between the photoactive layer (140) and the electrode (120).

In some embodiments, substrate (110) can be transparent.

In some embodiments, the above described photoactive layer (140) can be used in a system in which two photovoltaic cells share a common electrode. Such a system is also known as tandem photovoltaic cell.

Exemplary tandem photovoltaic cells have been described in, e.g., U.S. Application Publication Nos. 2009-02116333, 2007-0181179, 2007-0246094 and 2007-0272296.

FIG. 2 shows a schematic representation of a tandem photovoltaic cell (200) having two semi-cells (202) and (204). Semi-cell (202) includes an electrode (220), optionally a hole blocking layer (230), a first photoactive layer (240), a recombination layer (242). Semi-cell (204) includes recombination layer (242), a second photoactive layer (244), optionally a hole carrier layer (250), and an electrode (260). An external load can be connected to photovoltaic cell (200) via electrodes (220) and (260). Optionally, the tandem photovoltaic cell (200) can include substrate and/or passivation layer as described above with regard to photovoltaic cell (100).

Depending on the production process and the desired device architecture, the current flow in a semi-cell can be reversed by changing the electron/hole conductivity of a certain layer (e.g., changing hole blocking layer (230) to a hole carrier layer (250)).

A recombination layer (242) refers to a layer in a tandem cell wherein the electrons generated from a first semi-cell recombine with the holes generated from a second semi-cell.

Recombination layer (242) typically includes a p-type semiconductor material and an n-type semiconductor material. In general, n-type semiconductor materials selectively transport electrons and p-type semiconductor materials selectively transport holes.

As a result, electrons generated from the first semi-cell recombine with holes generated from the second semi-cell at the interface of the n-type and p-type semiconductor materials in the recombination layer (242).

In some embodiments, the p-type semiconductor material includes a polymer and/or a metal oxide. Examples of p-type semiconductor polymers include benzodithiophene-containing polymers, polythiophes (e.g., poly(3,4-ethylene dioxythiophene) (PEDOT)), polyanilines, polyvinylcarbazoles, polyphenylenes, polyphenylene vinylenes, polysilanes, polythienylenevinylenes, polyisothianaphthanenes, polycyclopentadithiophenes, polysilacyclopentadithiophenes, polycyclopentadithiazoles, polythiazoles, polybenzothiadiazoles, poly(thiophene oxide)s, poly(cyclopentadithiophene oxide)s, polythiadiazoloquinoxaline, polybenzoisothiazole, polybenzothiazole, polythienothiophene, poly(thienothiophene oxide), polydithienothiophene, poly(dithienothiophene oxide)s, polytetrahydroisoindoles, and copolymers thereof. The metal oxide can be an intrinsic p-type semiconductor (e.g., copper oxides, strontium copper oxides, or strontium titanium oxides) or a metal oxide that forms a p-type semiconductor after doping with a dopant (e.g., p-doped zinc oxides or p-doped titanium oxides). Examples of dopants include salts or acids of fluoride, chloride, bromide, and iodide. In some embodiments, the metal oxide can be used in the form of nanoparticles.

In some embodiments, the n-type semiconductor material (either an intrinsic or doped n-type semiconductor material) includes a metal oxide, such as titanium oxides, zinc oxides, tungsten oxides, molybdenum oxides, and a combination of any of these. The metal oxide can be used in the form of nanoparticles. In other embodiments, the n-type semiconductor material includes a material selected from the group consisting of fullerenes (such as those described above), inorganic nanoparticles, oxadiazoles, discotic liquid crystals, carbon nanorods, inorganic nanorods, polymers containing CN groups, polymers containing CF₃ groups, and a combination of any of these.

In some embodiments, the p-type and n-type semiconductor materials are blended into one layer. In certain embodiments, recombination layer (242) includes two layers, one layer including the p-type semiconductor material and the other layer including the n-type semiconductor material. In such embodiments, recombination layer (242) can further include an electrically conductive layer (e.g., a metal layer or mixed n-type and p-type semiconductor materials) at the interface of the two layers.

In some embodiments, recombination layer (242) includes at least 30 wt % (e.g., at least 40 wt % or at least 50 wt %) and/or at most 70 wt % (e.g., at most 60 wt % or at most 50 wt %) of the p-type semiconductor material. In some embodiments, recombination layer (242) includes at least 30 wt % (e.g., at least 40 wt % or at least 50 wt %) and/or at most 70 wt % (e.g., at most 60 wt % or at most 50 wt %) of the n-type semiconductor material.

Recombination layer (242) generally has a sufficient thickness so that the layers underneath are protected from any solvent applied onto recombination layer (242). In some embodiments, recombination layer (242) can have a thickness of at least 10 nm (e.g., at least 20 nm, at least 50 nm, or at least 100 nm preferably) and/or at most 500 nm (e.g., at most 200 nm, at most 150 nm, and preferably 100 nm).

In general, recombination layer (242) is substantially transparent. For example, at the thickness used in a tandem photovoltaic cell (200), recombination layer (242) can transmit at least 70% (e.g., at least 75%, at least 80%, at least 85%, or at least 90%) of incident light at a wavelength or a range of wavelengths (e.g., from 350 nm to 1,000 nm) used during operation of the photovoltaic cell.

Recombination layer (242) generally has a sufficiently low surface resistance. In some embodiments, recombination layer (242) has a surface resistance of at most aboutness 1×10⁶ ohm/square (e.g., at most 5×10⁵ ohm/square, at most 2×10⁵ ohm/square, or at most 1×10⁵ ohm/square).

Without wishing to be bound by theory, it is believed that recombination layer (242) can be considered as a common electrode between two semi-cells (e.g., one including electrode (220), optionally hole blocking layer (230), photoactive layer (240), and recombination layer (242), and the other including recombination layer (242), photoactive layer (244), optionally hole carrier layer (250), and electrode (260)) in photovoltaic cells (200). In some embodiments, recombination layer (242) can include an electrically conductive grid (e.g., mesh) material, such as those described above. An electrically conductive grid material can provide a selective contact of the same polarity (either p-type or n-type) to the semi-cells and provide a highly conductive but transparent layer to transport electrons to a load.

In some embodiments, a one-layer recombination layer (242) can be prepared by applying a blend of an n-type semiconductor material and a p-type semiconductor material on a photoactive layer. For example, an n-type semiconductor and a p-type semiconductor can be first dispersed and/or dissolved in a solvent together to form a dispersion or solution, which can then be coated on a photoactive layer to form a recombination layer.

In some embodiments, a two-layer recombination layer can be prepared by applying a layer of an n-type semiconductor material and a layer of a p-type semiconductor material separately. For example, when titanium oxide nanoparticles are used as an n-type semiconductor material, a layer of titanium oxide nanoparticles can be formed by (1) dispersing a precursor (e.g., a titanium salt) in a solvent (e.g., an anhydrous alcohol) to form a dispersion, (2) coating the dispersion on a photoactive layer, (3) hydrolyzing the dispersion to form a titanium oxide layer, and (4) drying the titanium oxide layer. As another example, when a polymer (e.g., PEDOT) is used as a p-type semiconductor, a polymer layer can be formed by first dissolving the polymer in a solvent (e.g., an anhydrous alcohol) to form a solution and then coating the solution on a photoactive layer.

Other components in tandem cell (200), optionally including a substrate and/or passivation layer, can be formed of the same materials, or have the same characteristics, as those in photovoltaic cell (100) described above.

In some embodiments, multiple photovoltaic cells can be electrically connected to form a photovoltaic system. As an example, FIG. 3 is a schematic of a photovoltaic system (300) having a module (310) containing a plurality of photovoltaic cells (320). The photovoltaic cells (320) are electrically connected in series, and system (300) is electrically connected to a load (330). As another example, FIG. 4 is a schematic of a photovoltaic system (400) having a module (410) that contains a plurality of photovoltaic cells (420). The photovoltaic cells (420) are electrically connected in parallel, and system (400) is electrically connected to a load (430). In some embodiments, some photovoltaic cells in a photovoltaic system can be disposed on one or some of common substrates. Preferably, in some embodiments, some photovoltaic cells in a photovoltaic system are electrically connected in series, and some of the photovoltaic cells in the photovoltaic system are electrically connected in parallel.

The photovoltaic cell of the present invention can be used in combination with one or more of another type of photovoltaic cells. Examples of such photovoltaic cells include dye sensitized photovoltaic cells, perovskite photoactive cells, inorganic photoactive cells with a photoactive material formed of amorphous silicon, crystal silicon, polycrystal silicon, microcrystal silicon, cadmium selenide, cadmium telluride, copper indium selenide and/or copper indium gallium selenide.

Definition of Terms

The term “transparent” means at least around 60% of incident light transmittal at the thickness used in a photovoltaic cell and at a wavelength or a range of wavelengths used during operation of photovoltaic cells.

Preferably, it is over 70%, more preferably, over 75%, most preferably it is over 80%.

According to the present invention, the term “oligomer” has a meaning of material which has a number average degree n of polymerization of at least 2 and at the most 100.

The term “polymer” means a material having a number average degree of polymerization n of at least 101 or more.

The number average degree of polymerization (Pn) can be determined from the number average molecular weight (Mn) measured by gel permeation chromatography (GPC) and the molecular weight of a monomer.

According to the present invention, the term “electron withdrawing capability” means an ability to reduce electron density in a system.

The term “optical density” is defined as absorbance.

And absorbance can be defined by following formula;

A_{λ}=−log₁₀(l/l₀)

wherein A_{λ} represents absorbance and l is the intensity of light at a specified wavelength λ that has passed through a sample (a photovoltaic cell), l₀ is the intensity of light before it enters the sample.

The term “peak optical density” means the peak optical density value of a photovoltaic cell, when applying the light having 400 nm to 1100 nm wavelength range to the photovoltaic cell.

The term “Max optical density” is defined as the max optical density value of a photovoltaic cell, when applying the light having 400 nm to 1100 nm wavelength range to the photovoltaic cell.

Each feature disclosed in this specification, unless stated otherwise, may be replaced by alternative features serving the same, equivalent, or similar purpose. Thus, unless stated otherwise, each feature disclosed is but one example of a generic series of equivalent or similar features.

The invention is described in more detail in reference to the following examples, which are only illustrative and do not limit the scope of the invention.

### EXAMPLES

### Example 1

### Synthesis of 1,4-Bis(2-bromo-4,4′bis(2-ethylhexyl)dithieno[3,2-b:2′,3′-dIsilole])-2,3,5,6-tetrafluorobenzene

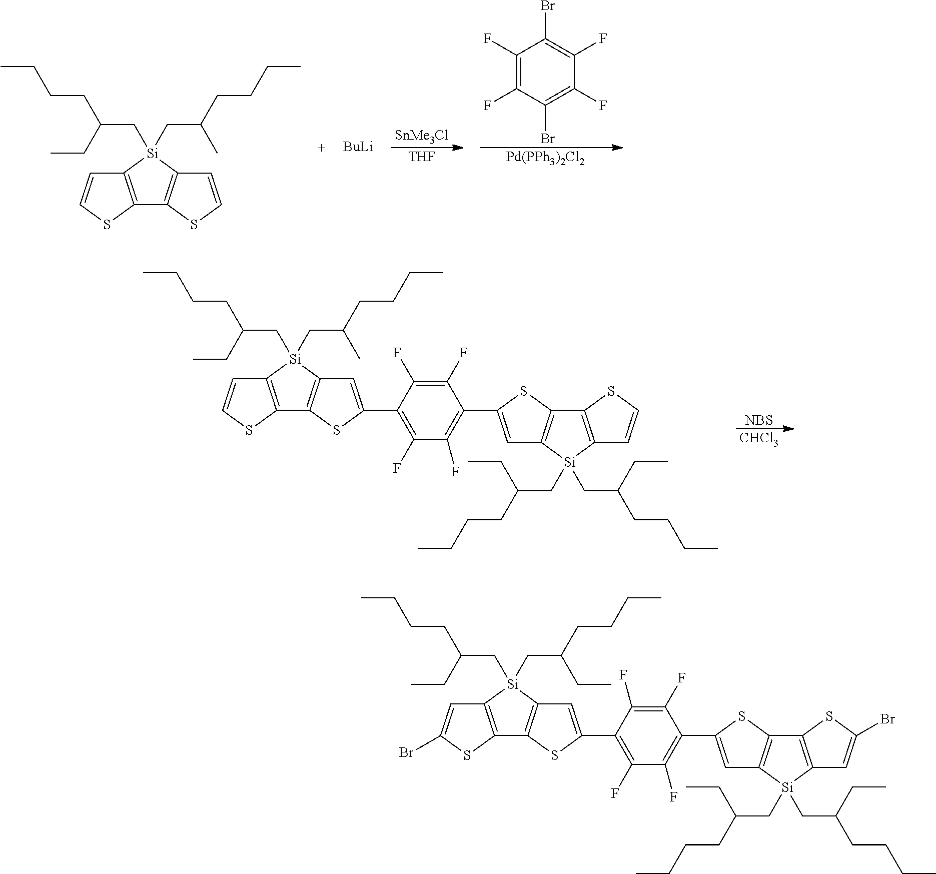

4,4′-bis(2-ethylhexyl)dithieno[3,2-b:2′,3′-d]silole (1.68 g, 4.0 mmol) was dissolved in 50 ml of dry THF (tetrahydrofuran). After the solution was cooled to −78° C., N-Butyl lithium (BuLi) (1.40 ml, 4.0 mmol) was added into the solution. After reaction mixture was stirred at −78° C. for 30 minutes, SnMe₃Cl (4.0 ml, 4.0 mmol) was added into the reaction flask by syringe. The reaction mixture was then allowed to warm to room temperature. 1,4-Dibromo-2,3,5,6-tetrafluorobenzene (0.61 g, 2.0 mmol) and bis(triphenylphosphine)palladium(II)chloride (0.14 g, 0.20 mmol) were dissolved in 5 ml of THF. The resultant solution was then added into the above solution by syringe. The reaction mixture was refluxed then overnight. After the reaction was cooled down, it was quenched by water, and extracted by dichloromethane. The crude product was concentrated by rotary evaporation, and purified by column chromatography to give 1,4-bis(4,4′-bis(2-ethylhexyl)dithieno[3,2-b:2′3′-d]silone)-2,3,5,6-tetrafluorobenzene as yellow oil (1.4 g, 72%).

1,4-bis(2-bromo-4,4′-bis(2-ethylhexyl)dithieno[3,2-b:2′3′-d]silone)-2,3,5,6-tetrafluorobenzene (0.98 g, 1.0 mmol) obtained above and N-Bromosuccinimide (NBS) (0.36 g, 2.0 mmol) were dissolved in 30 ml of chloroform. The solution was refluxed for 1 hour. After the reaction mixture was cooled to room temperature, water was added to quench the reaction. The organic layer was extracted by chloroform to afford a crude product. The crude product was purified by column chromatography to give 1,4-bis(2-bromo-4,4′-bis(2-ethylhexyl)dithieno[3,2-b:2′3′-d]silone)-2,3,5,6-tetrafluorobenzene as a yellow solid (1.08 g, 95%).

### Example 2

### Synthesis of 2,5-bis(5-trimethylstannyl-3-tetradecyl-2-thienyl)-thiazoo[5,4-cl]thiazole

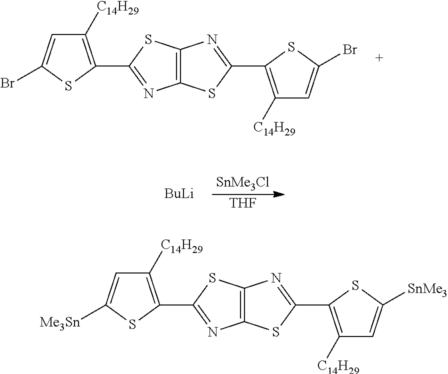

A 100 ml Schlenk flask was evacuated and refilled with Ar three times. 35 ml of dry THF was added to the flask. The flask was subsequently cooled to −78 degree centigrade. N-Butyl lithium (0.64 mmol) was then added dropwise to the above solution. After the solution was stirred at −78° C. for one hour, 0.7 ml of 1.0 M solution of trimethyl tin chloride was syringed into the reaction mixture. After the solution was allowed to warm up to room temperature, 100 ml of diethyl ether was added to the solution. The solution was washed three times with 100 ml of water and then the organic layer was dried over anhydrous MgSO₄. After the solvent was removed in vacuum, 2,5-bis(5-trimethylstannyl-3-tetradecyl-2-thienyl)-thiazolo[5,4-d]thiazole was isolated in quantitative yield.

### Example 3

### Synthesis of KP179

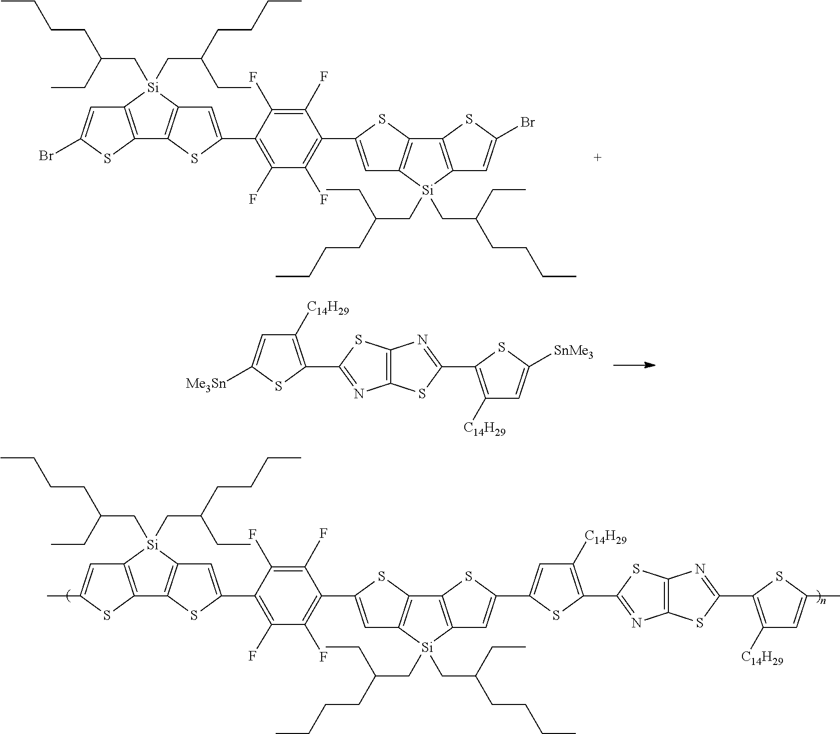

The 2,5-bis(5-trimethylstannyl-3-tetradecyl-2-thienyl)-thiazolo[5,4-d]thiazole was transferred to a 100 ml three neck round bottom flask. The following reagents were then added to the three neck flask: 7 mg (7 μmol) of Pd₂(dba)₃, 18 mg (59 μmol) of tri-o-tolyl-phosphine, 332 mg (0.29 mmol) of 1,4-bis(2-bromo-4,4′-bis(2-ethylhexyl)dithieno[3,2-b:2′,3′-d]silole)-2,3,5,6-tetrafluorobenzene, and 20 ml of dry toluene. This reaction mixture was refluxed for two days and then cooled to 80° C. An aqueous solution of sodium diethyldithiocarbamate trithydrate (1.5 g in 20 ml water) was syringed into the flask and the mixture was stirred together at 80° C. for 12 hours. After the mixture was cooled to room temperature, the organic phase was separated from the aqueous layer. The organic layer was poured into methanol (200 ml) to form a polymer precipitate. The polymer precipitate was then collected and purified by soxhlet extraction. The final extraction yielded 123 mg (Mn=31 kDa) of poly [1,4-bis(4,4′-bis(2-ethylhexyl)dithieno[3,2-b:2′,3′-d]silole)-2,3,5,6-tetrafluorobenzene-alt-2,5-bis(3-tetradecyl-2-thienyl)-thiazolo[5,4-d]thiazole].

### Example 4

### Synthesis of KP252, KP184, KP143, and KP155

KP252, KP184, KP143 and KP155 were prepared in a manner similar to that described in examples 1 to 3 using corresponding monomers.

### Example 5

### Synthesis of KP266

KP266 was prepared in a manner similar to that described in examples 1 to 3 using corresponding monomers.

### Example 6

### Fabrication of Photovoltaic Cells with KP179, KP252 and Mixed PCBM

Photovoltaic cells were prepared as follows:

An ITO coated glass substrate was cleaned by sonicating in acetone and isopropanol, respectively. The substrate was then treated with UV/ozone. A thin hole blocking layer was formed on the cleaned substrate using 0.5 wt % polyethylenimine (PEI) and 0.5 wt % glycerol diglycidyl ether (DEG) (1:1 weight ratio in butanol). The thickness of the hole blocking layer was 20 nm. The substrate thus formed was annealed at 100° C. for 2 minutes. Then, KP179, KP252, PC60BM and PC70BM (4: 3: 13.1: 4.4 weight ratio in o-dichlorobenzene (ODCB)) were dissolved in ODCB and the resulting solution was coated onto the hole blocking layer to form a photoactive layer by using a blade coating technique and its thickness was controlled to achieve the peak optical density of the photovoltaic cell of 0.553. After heating and cooling, A 2.5 nm thick of hole carrier layer consisting of MoO₃ was formed onto the photoactive layer by deposition. Then the 1^{st} photovoltaic cell was prepared by evaporation of a silver layer (80 nm) on the hole carrier layer as a top electrode.

Three other photovoltaic cells were made in the same manner as the 1^{st} photovoltaic cell described in the preceding paragraph expect for the layer thickness of the photoactive layer. By changing the layer thickness of the photoactive layer of the photovoltaic cells to achieve the peak optical density of the photovoltaic cell of 0.679, 0.751 or 0.877, three additional photovoltaic cells were fabricated.

Further, four additional photovoltaic cells were fabricated in the same manner as the photovoltaic cell described above expect for the photoactive layer.

KP179, KP252, PC60BM, PC70BM (4: 2: 11.2: 3.8 weight ratio in o-dichlorobenzene (ODCB)) and resulting ODCB solution was poured onto the hole blocking layer to form a photoactive layer and its thickness was controlled to achieve the peak optical density of the photovoltaic cells of 0.512, 0.574, 0.773 and 0.792.

The current-voltage characteristics of photovoltaic cells were measured using Keithley 2400 SMU while the photovoltaic cells were illuminated under AM 1.5 G irradiation on an Oriel Xenon solar simulator (100 mW/cm²).

FIGS. 5-a, b show the cell performance (Fill Factor and photo conversion efficiency) of the photovoltaic cells fabricated in the working example 6.

### Comparative Example 1

### Fabrication of Photovoltaic Cells with KP252 and PC60BM

Photovoltaic cells as comparative example 1 were made in the same manner as the first photovoltaic cell described in Example 6 except that the photoactive layer contained KP252 and PC60BM in 1:2 weight ratio and the layer thickness of the photoactive layer of the photoactive cells was each independently controlled to achieve the optical density of the photovoltaic cells of 0.22, 0.252, and 0.308.

And photovoltaic cells having the photoactive layer contained KP252 and PC60BM in 1:2 weight ratio and 1 wt % 1-8-diiodooctane (DIO) as a dopant were fabricated in the same manner disclosed in the Example 1. The layer thickness of the photoactive layer of the each one of photovoltaic cells was controlled to achieve the max optical density of the photovoltaic cells of 0.23, 0.28, 0.289 and 0.32.

FIGS. 6-a, b show the cell performances (Fill Factor and photo conversion efficiency) of the photovoltaic cells fabricated in the comparative example 1.

### Comparative Example 2

### Fabrication of Photovoltaic Cells with KP179 and PCBM

Photovoltaic cells as comparative example 2 were made in the same manner as the first photovoltaic cell described in Example 6 except that the photoactive layer contained KP179 and PCBM and the layer thickness of the photoactive layer of the photoactive cells was each independently controlled to achieve the peak absorption value of the photovoltaic cells of 0.609, 0.862, 1.161 and 1.384.

FIGS. 7-a, b show the cell performances (Fill Factor and photo conversion efficiency) of the photovoltaic cells fabricated in the comparative example 2.

### Comparative Example 3

### Fabrication of Photovoltaic Cells with KP179, JA19B and PC60BM

Photovoltaic cells as comparative example 3 were made in the same manner as the first photovoltaic cell described in Example 6 except that the photoactive layer contained KP179, JA19B (Konarka) and PCBM in 4:2:15 weight ratio and the layer thickness of the photoactive layer of the photoactive cells was each independently controlled to achieve the peak optical density of the photovoltaic cells of 0.421, 0.482, 0.588, 0.69, 0.767 and 0.83.

FIGS. 8-a, b show the cell performances (Fill Factor and photo conversion efficiency) of the photovoltaic cells fabricated in the comparative example 3.

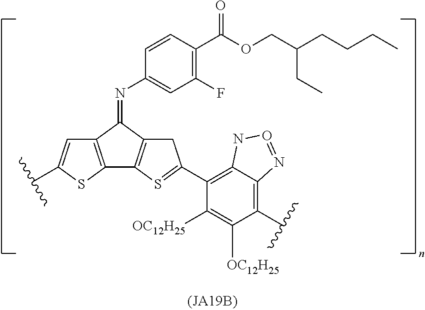

### Comparative Example 4

### Fabrication of Photovoltaic Cells with KP179, PDPPTPT and PC61BM

Photovoltaic cells as comparative example 4 were made in the same manner as the first photovoltaic cell described in Example 1 except that the photoactive layer contained KP179, PDPPTPT (from Konarka) and PC61BM in 4:2:12 weight ratio and the layer thickness of the photoactive layer of the photovoltaic cells was each independently controlled to achieve the MAX optical density of the photovoltaic cells of 0.679, 0.54, 0.888, and 1.193.

FIGS. 9-a, b show the cell performances (Fill Factor and photo conversion efficiency) of the photovoltaic cells fabricated in the comparative example 4.

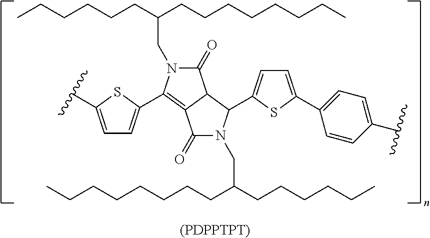

### Example 7

### Fabrication of Photovoltaic Cells with KP143, KP155 and PC60BM

Photovoltaic cells as example 7 were made in the same manner as the first photovoltaic cell described in Example 6 except that the photoactive layer contained KP143, KP155 and PC60BM in 4:2:15 weight ratio and the layer thickness of the photoactive layer of the photoactive cells was each independently controlled to achieve the peak optical density of the photovoltaic cells of 0.625, 0.629, 0.749, 0.796, 0.882, 0.949 and 0.986.

FIGS. 10-a, b show the cell performances (Fill Factor and photo conversion efficiency) of the photovoltaic cells fabricated in the example 7.

### Comparative Example 5

### Fabrication of Photovoltaic Cells with KP143 and PCBM

Photovoltaic cells as comparative example 5 were made in the same manner as the first photovoltaic cell described in Example 6 except that the photoactive layer contained KP143 and PCBM in 1:2 weight ratio and the layer thickness of the photoactive layer of the photoactive cells was each independently controlled to achieve the optical density of the photovoltaic cells of in the range of 0.6-0.7, 0.6-0.67, 0.6-0.8, 0.7-0.75, and 085-0.95.

FIGS. 11-a, b show the cell performances (Fill Factor and photo conversion efficiency) of the photovoltaic cells fabricated in the comparative example 5.

### Comparative Example 6

### Fabrication of Photovoltaic Cells with KP155, PC70BM with a Dopant

Photovoltaic cells as comparative example 6 were made in the same manner as the first photovoltaic cell described in Example 6 except that the photoactive layer contained KP155, PC70BM and DIO 1 wt %, ODT 1 wt % or phenylnaphthalene 1 w % as a dopant. In case of the photoactive layer contained KP155, PC70BM and DIO 1 wt %, the layer thickness of the photoactive layer of the photovoltaic cells was each independently controlled to achieve the MAX optical density of the photovoltaic cells of 0.282, 0.303, and 0.369. In case of the photoactive layer contained KP155, PC70BM and ODT 1 wt %, the layer thickness of the photoactive layer of the photoactive cells was each independently controlled to achieve the MAX optical density of the photovoltaic cells of 0.468, 0.204, and 0.279. About the case the photoactive layer contained KP155, PC70BM and phenyl naphthalene 1 w %, the layer thickness of the photoactive layer of the photovoltaic cells was each independently controlled to achieve the MAX optical density of the photovoltaic cells of 0.281, 0.295, and 0.305.

FIGS. 12-a, b show the cell performances (Fill Factor and photo conversion efficiency) of the photovoltaic cells fabricated in the comparative example 6.

### Comparative Example 7

### Fabrication of Photovoltaic Cells with KP143, JA19B and PC60BM

Photovoltaic cells as comparative example 7 were made in the same manner as the first photovoltaic cell described in Example 6 except that the photoactive layer contained KP143, JA19B and PC60BM in (4:2:15) weight ratio and the layer thickness of the photoactive layer of the photovoltaic cells was each independently controlled to achieve the peak optical density of the photovoltaic cells of 0.428, 0.445, 0.482, 0.507, 0.614, 0.754 and 0.823.

FIGS. 13-a, b show the cell performances (Fill Factor and photo conversion efficiency) of the photovoltaic cells fabricated in the comparative example 7.

### Example 8

### Fabrication of Photovoltaic Cells with KP179, KP184 and PCBM

Photovoltaic cells as example 8 were made in the same manner as the first photovoltaic cell described in Example 6 except that the photoactive layer contained KP179, KP184 and PCBM in 4:2:12 weight ratio and the layer thickness of the photoactive layer of the photovoltaic cells was each independently controlled to achieve the peak optical density of the photovoltaic cells of 0.713, 0.796, 0.862, and 0.907, and a max optical density of the photovoltaic cells of 0.9, 0.68 and 0.54.

FIGS. 14-a,b show the thermal test results with cell performances (Fill Factor and photo conversion efficiency) of the photoactive cells fabricated in the example 8. And in the FIG. 14-a, starting from in the order left to right, cell performance of the photovoltaic cells which were not annealed, cell performance of the photovoltaic cells annealed at 85 degree centigrade for 168 hours, cell performance of the photovoltaic cells at 85 degree centigrade for 288 hours are mentioned.

### Comparative Example 8

### Fabrication of Photovoltaic Cells with KP179 and PC60BM

Photovoltaic cells as comparative example 8 were also made in the same manner except that the photoactive layer contained KP179 and PC60BM in 1:2 weight ratio and the layer thickness of the photoactive layer of the photovoltaic cells was each independently controlled to achieve the peak optical density of the photovoltaic cells of 0.761, 1.274, 1.486, and a max optical density of the photovoltaic cells of 2.6, 1.1, 0.88.

FIGS. 15-a, b show the cell performances (Fill Factor and photo conversion efficiency) of the photoactive cells fabricated in the comparative example 7.

### Comparative Example 9

### Fabrication of Photovoltaic Cells with KP266 and PC60BM

Photovoltaic cells as comparative example 9 were also made in the same manner except that the photoactive layer contained KP266 and PC60BM in 1:2 weight ratio and the layer thickness of the photoactive layer of the photovoltaic cells was each independently controlled to achieve the max optical density of the photovoltaic cells of 0.448, 0.56, 0.749 and 0.799

FIGS. 16-a, b show the cell performances (Fill Factor and photo conversion efficiency) of the photovoltaic cells fabricated in the comparative example 9.

Here, the current-voltage characteristics of photovoltaic cells fabricated in afore mentioned examples and comparative examples were measured in a same manner described in Example 6.

### DESCRIPTION OF THE DRAWINGS

FIG. 1: shows a cross sectional view of an embodiment of a photovoltaic cell.

FIG. 2: shows a cross sectional view of an embodiment of a tandem photovoltaic cell.

FIG. 3: shows a schematic of a system containing multiple photovoltaic cells electrically connected in series.

FIG. 4: shows a schematic of a system containing multiple photovoltaic cells electrically connected in parallel.

FIGS. 5-a, b: shows cell performances of the KP179/KP252/PCBM cells

FIGS. 6-a, b: shows cell performances of the KP252/PCBM cells

FIGS. 7-a, b: shows cell performances of the KP179/PCBM cells

FIGS. 8-a, b: shows cell performances of the KP179/JA19B/PCBM cells

FIGS. 9-a, b: shows cell performances of the KP179/PDPPTPT/PCBM cells

FIGS. 10-a, b: shows cell performances of the KP143/KP155/PCBM cells

FIGS. 11-a, b: shows cell performances of the KP143/PCBM cells

FIGS. 12-a, b: shows cell performances of the KP155/PCBM cells

FIGS. 13-a, b: shows cell performances of the KP143/JA19B/PCBM cells

FIGS. 14-a, b: shows cell performances of the KP179/KP184/PCBM cells

FIGS. 15-a, b: shows cell performances of the KP179/PCBM cells

FIGS. 16-a, b: shows cell performances of the KP266/PCBM cells

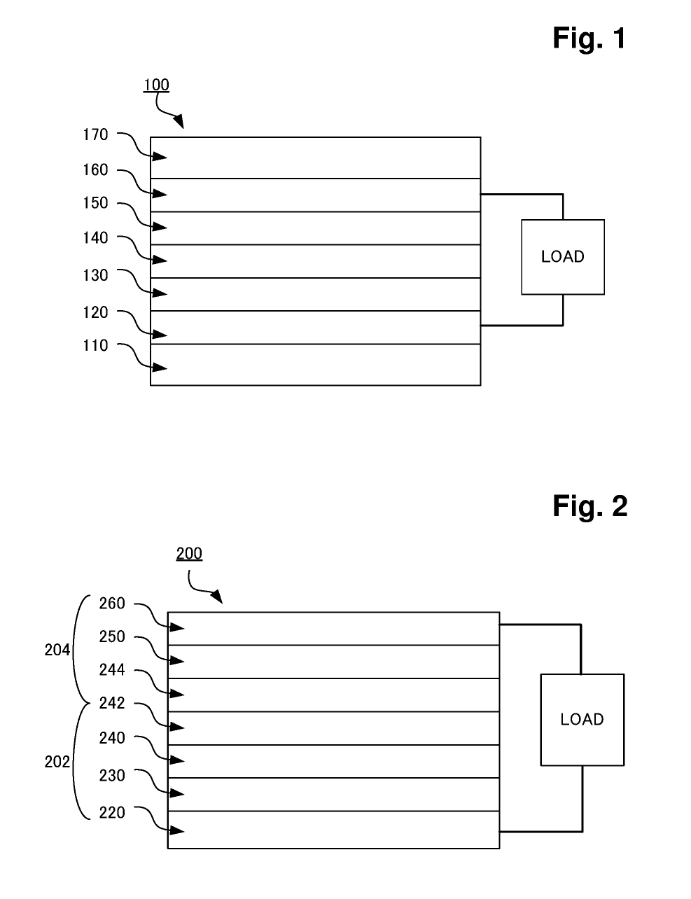

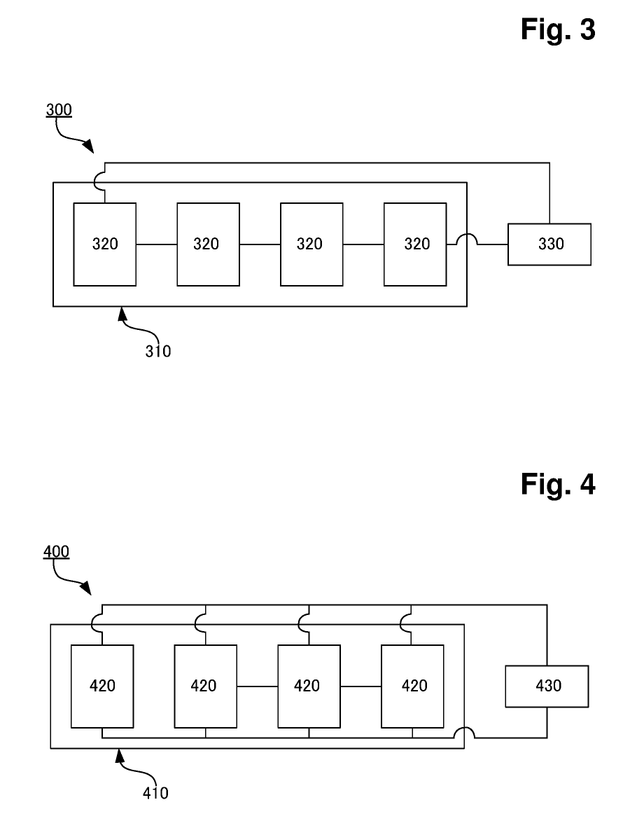

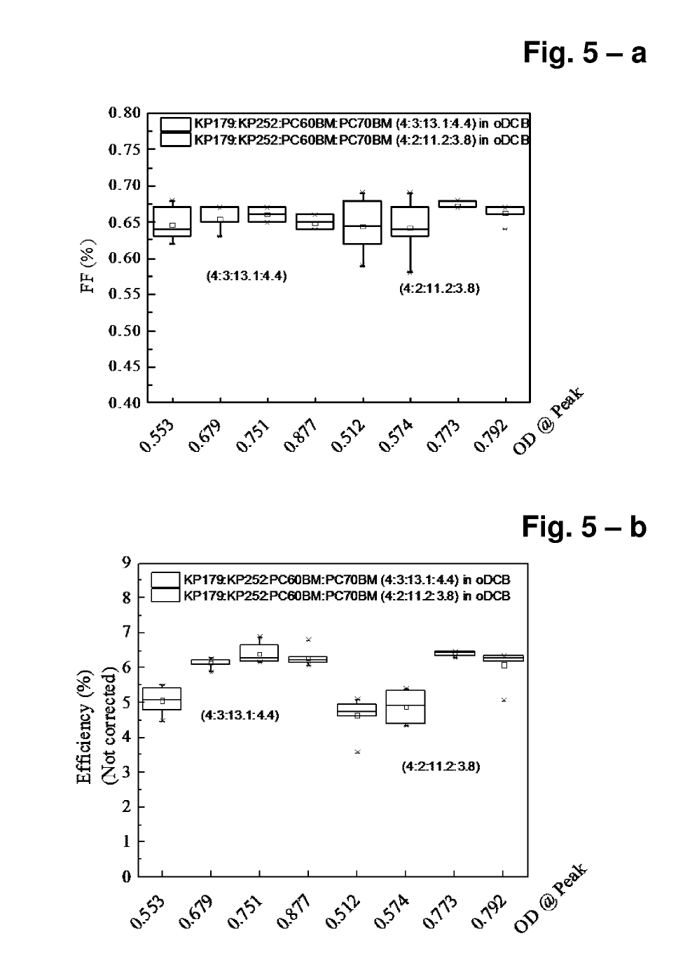

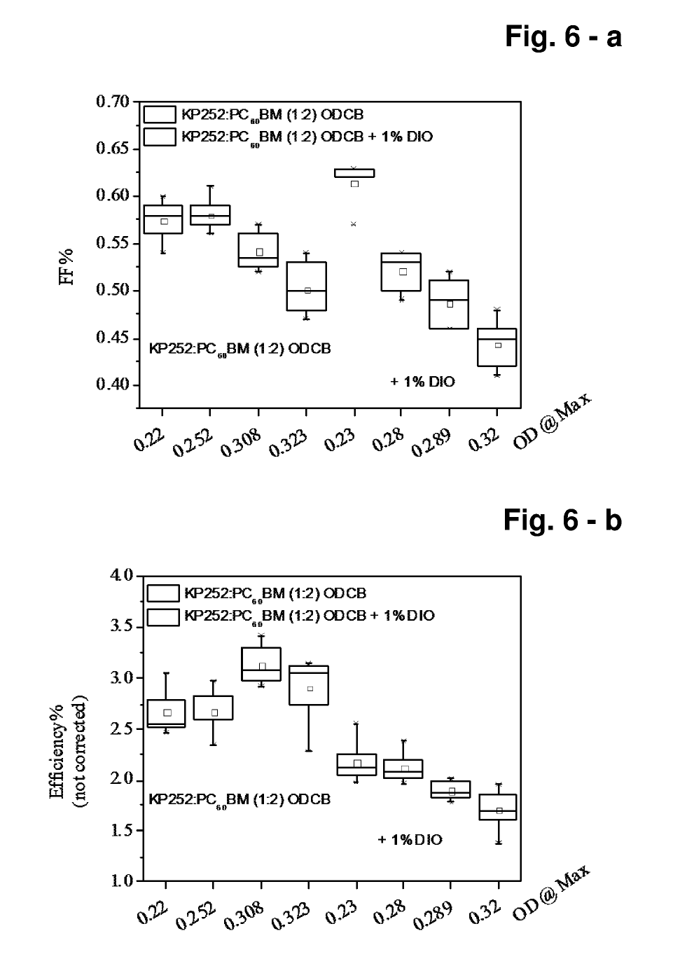

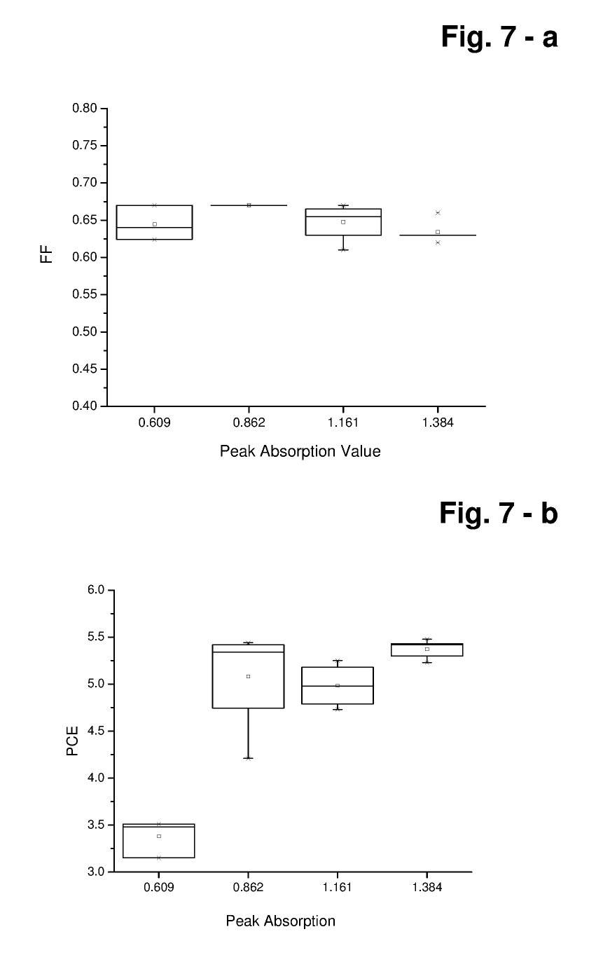

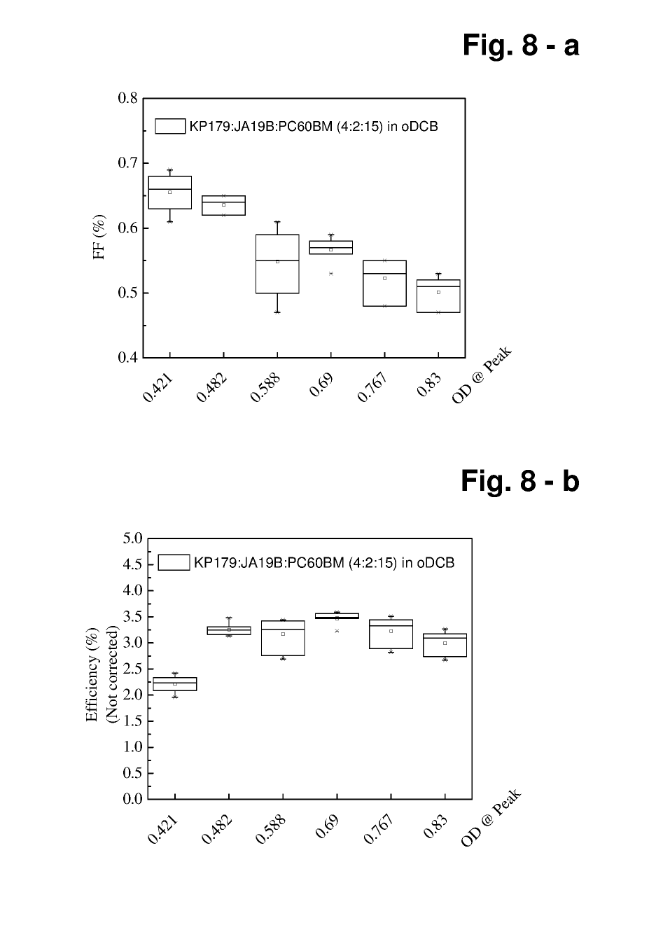

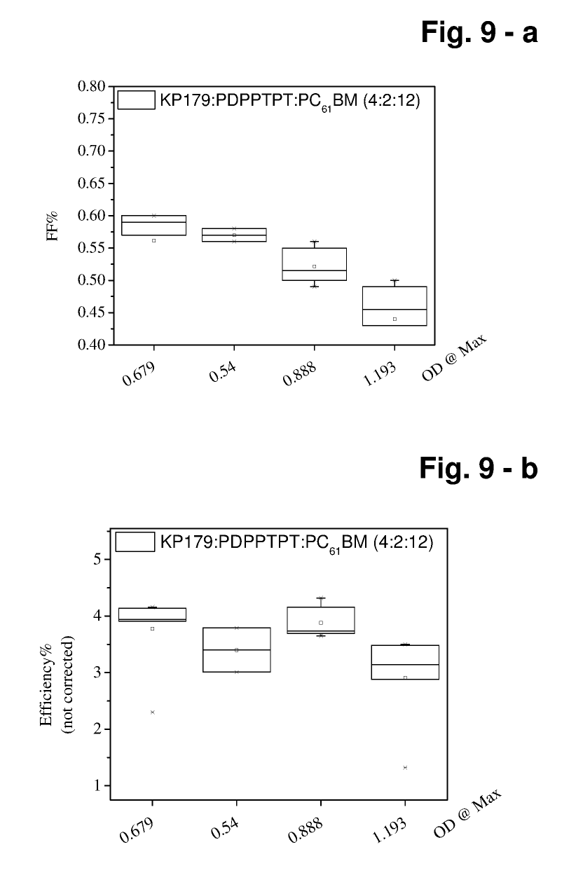

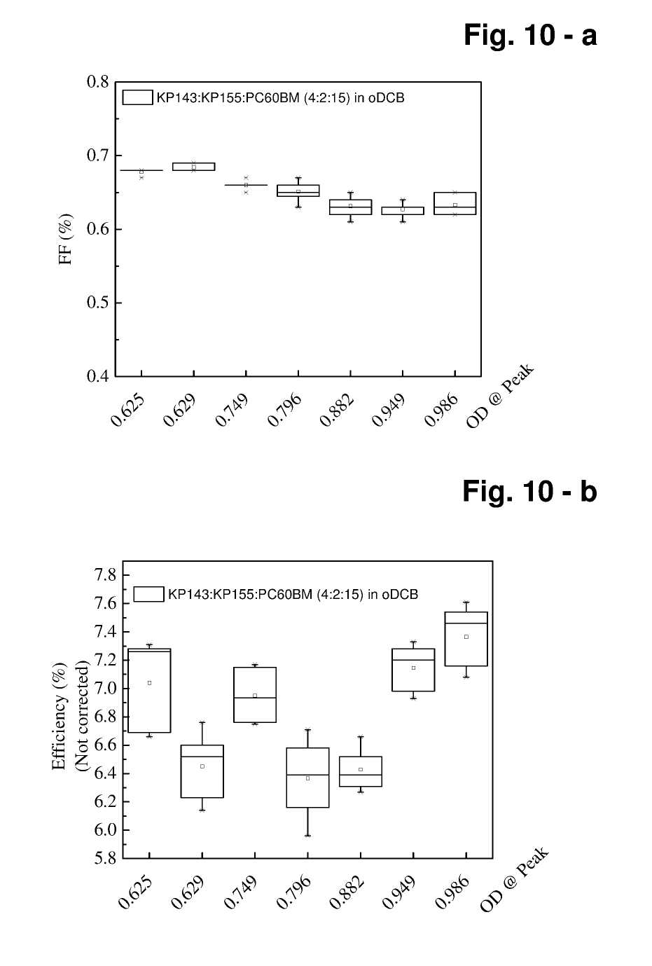

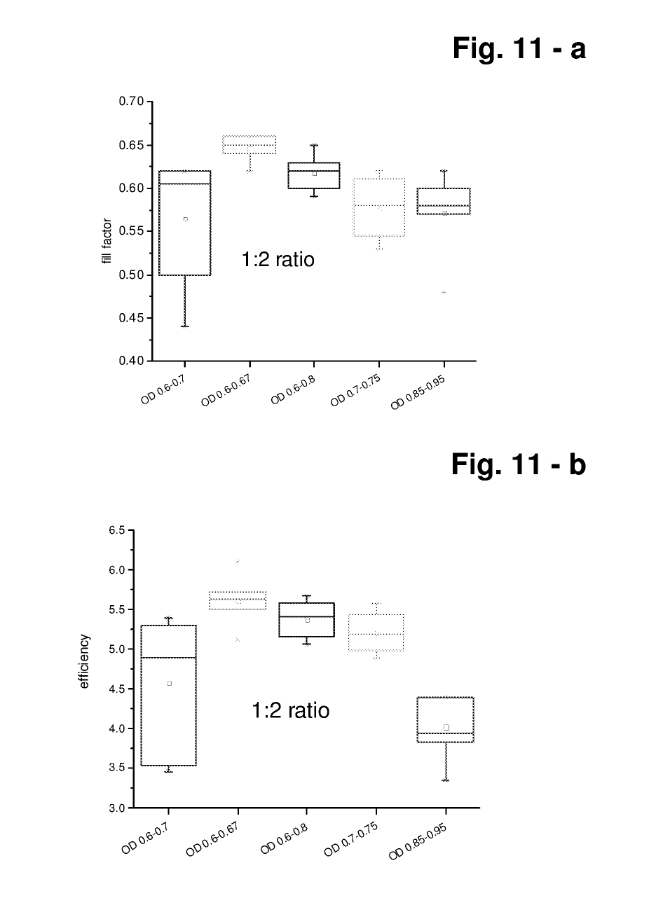

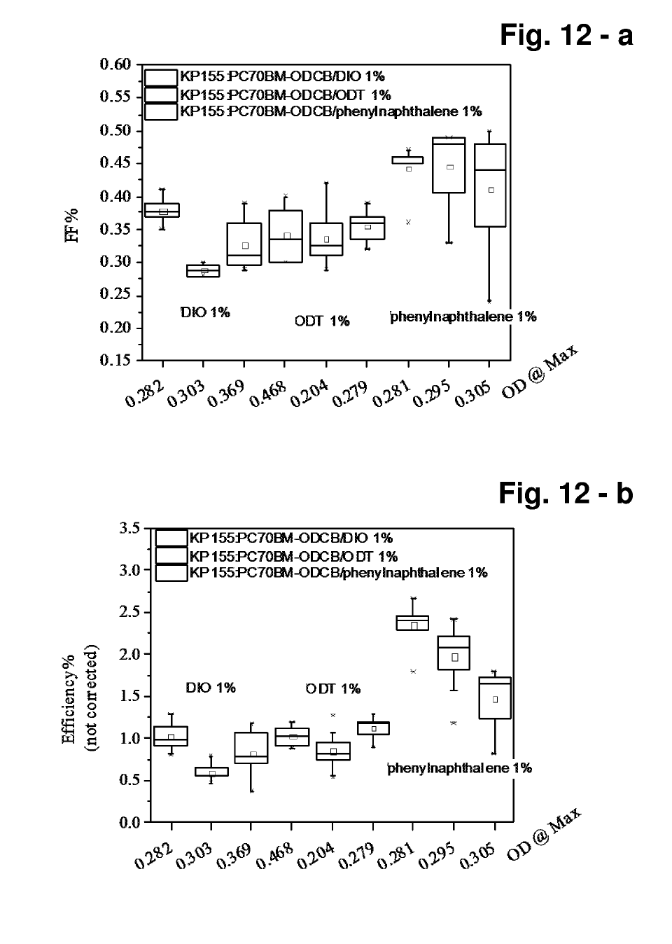

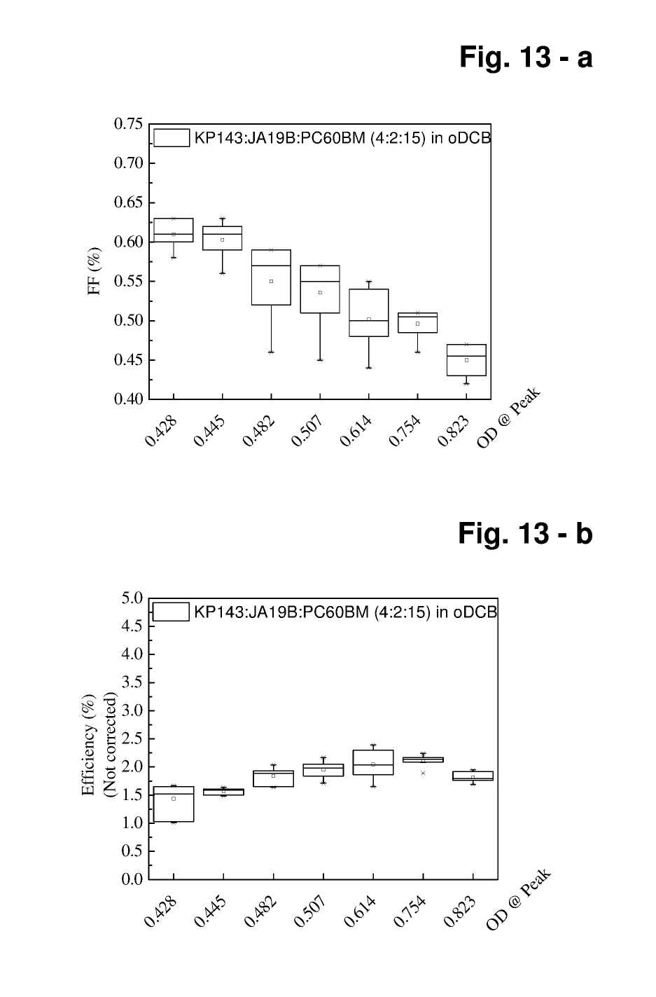

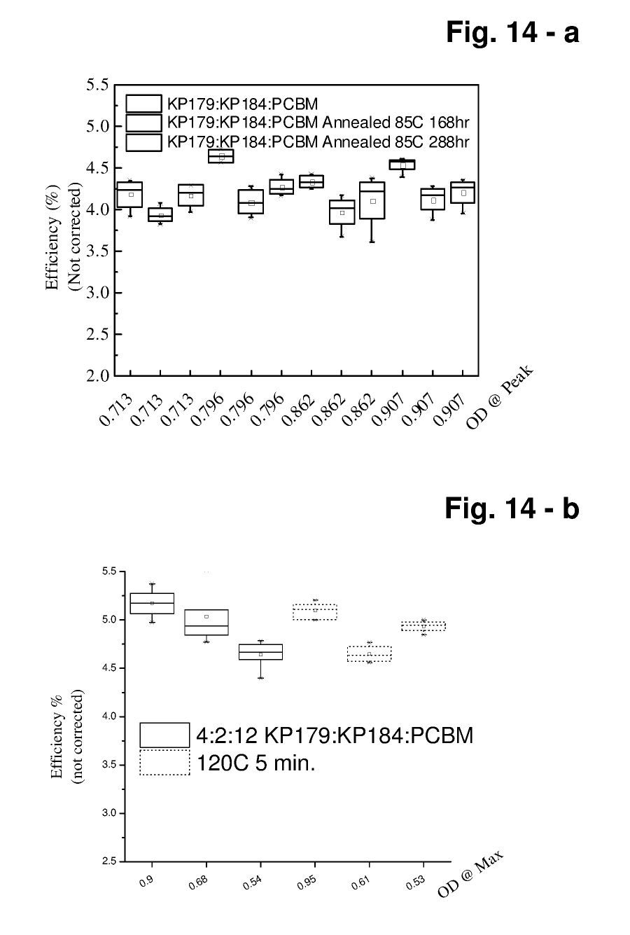

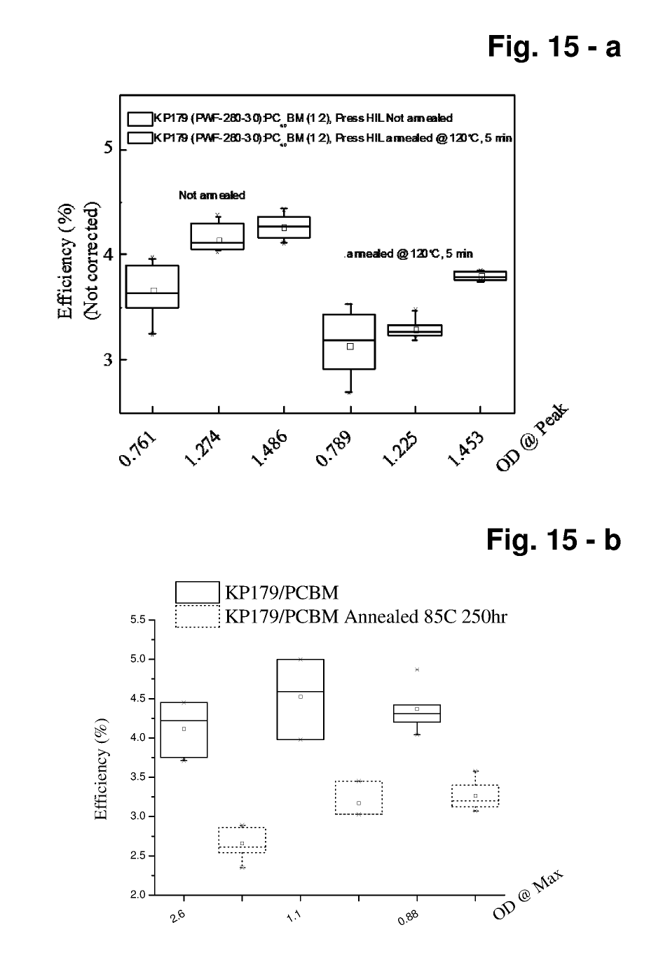

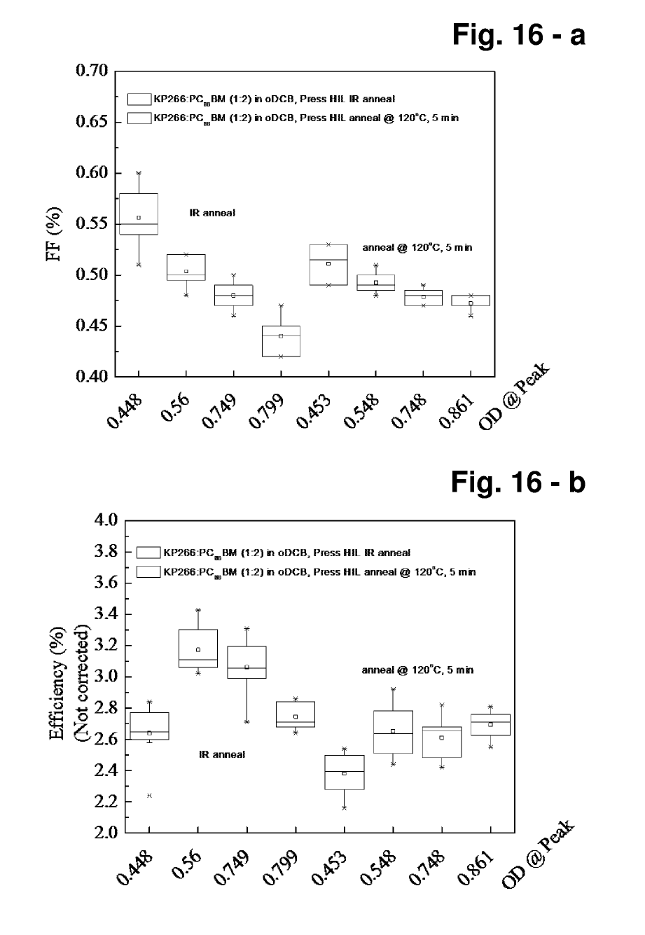

### LIST OF REFERENCE SIGNS IN FIGS

100. a photovoltaic cell

110. a substrate (optional)

120. an electrode

130. a hole blocking layer (optional)

140. a photoactive layer

150. a hole carrier layer (optional)

160. an electrode

170. a passivation layer (optional)

200. a tandem photovoltaic cell

202. a semi-cell

204. a semi-cell

220. an electrode

230. a hole blocking layer (optional)

240. a 1^{st} photoactive layer

242. a recombination layer

244. a 2^{nd} photoactive layer

250. a hole carrier layer (optional)

260. an electrode

300. a photovoltaic system

310. a module

320. a plurality of photovoltaic cells

330. a load

400. a photovoltaic system

410. a module

420. a plurality of photovoltaic cells

430. a load

1. A photovoltaic cell comprising:
a first electrode;
a second electrode; and
a photoactive layer between the first electrode and the second electrode,
wherein the photoactive layer comprises a first donor material, second donor material and acceptor material; the first donor material and the second donor material being different from each other and each of the donor materials comprising a common building block of the same chemical structure, said common building block comprising a conjugated fused ring moiety.

2. The photovoltaic cell according to claim 1, wherein the common building block constitutes an electron donating unit of the donor materials.

3. The photovoltaic cell according to claim 1, wherein the common building block is at each occurrence, selected from the group consisting of the following formulae (A1) to (A106) 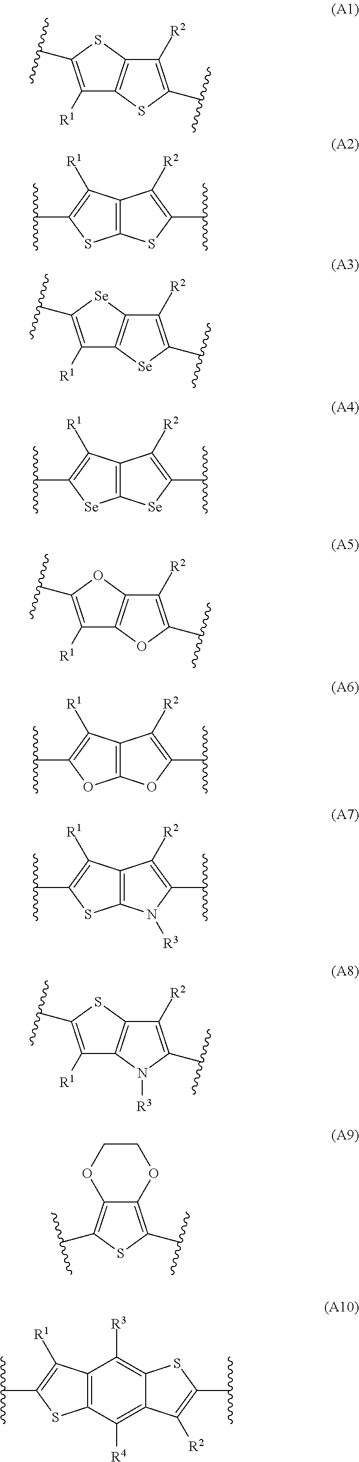 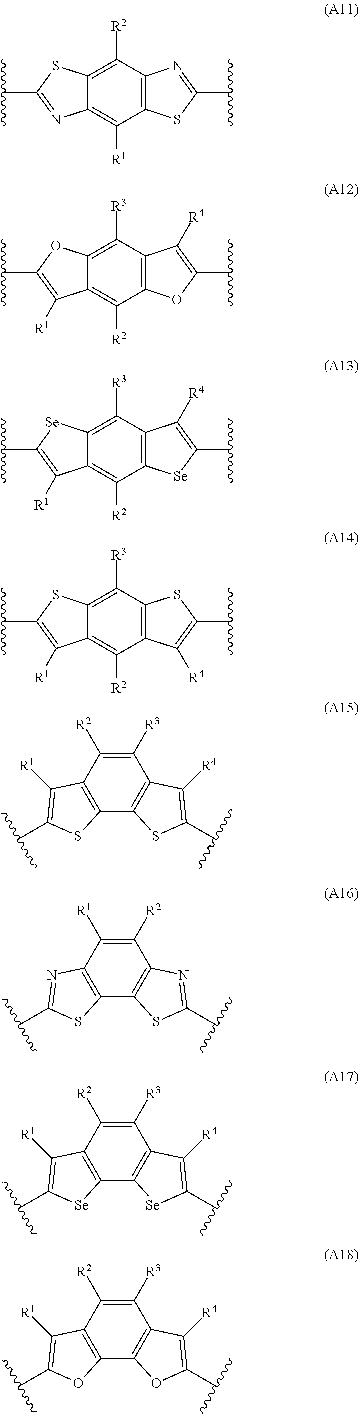 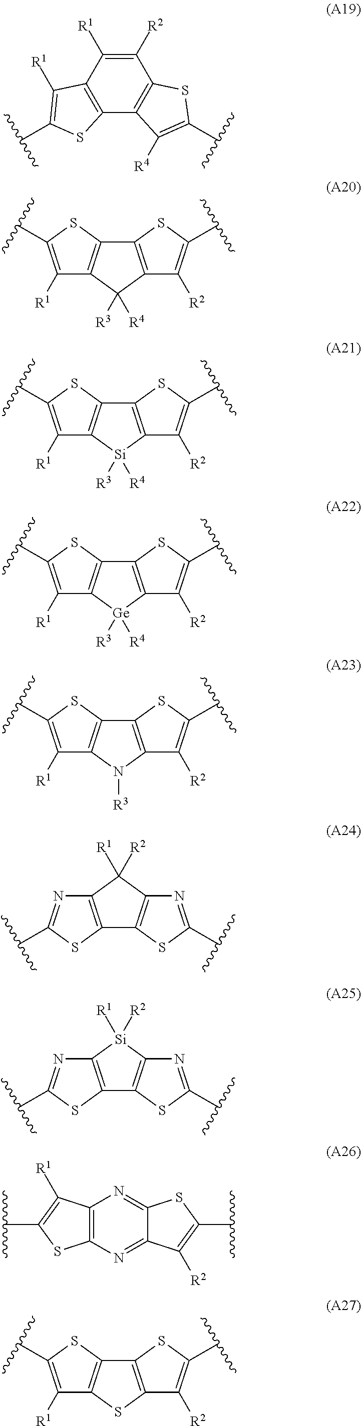 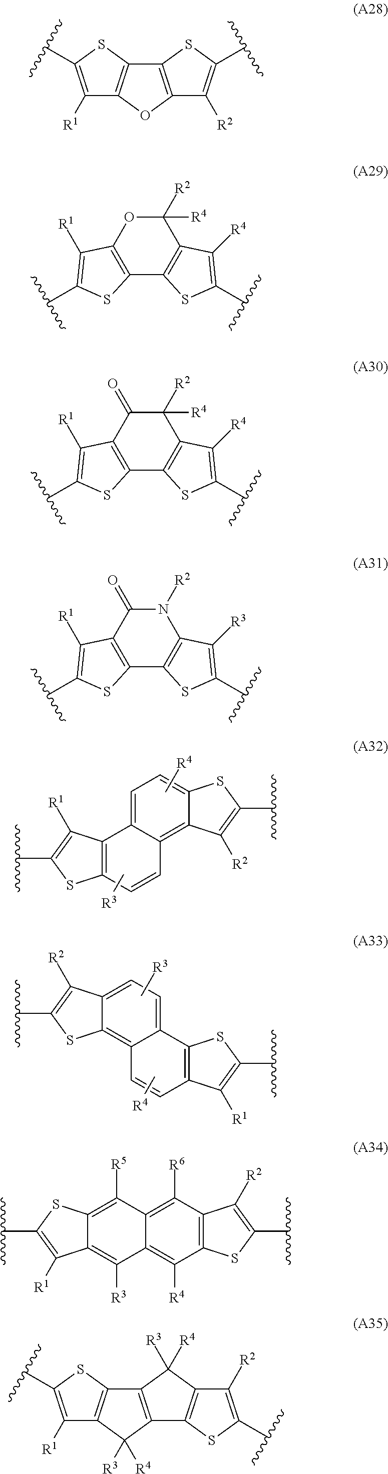 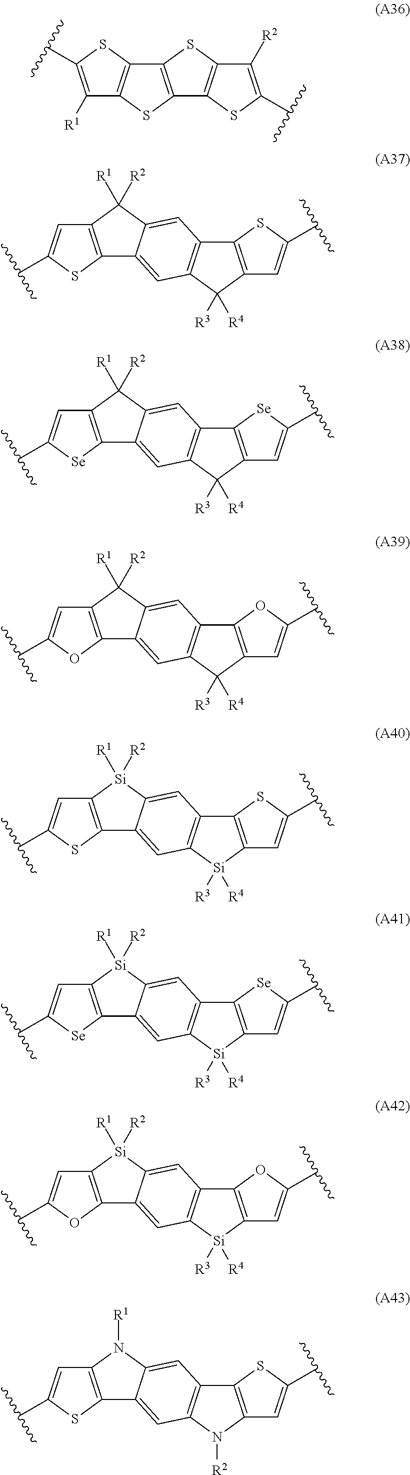 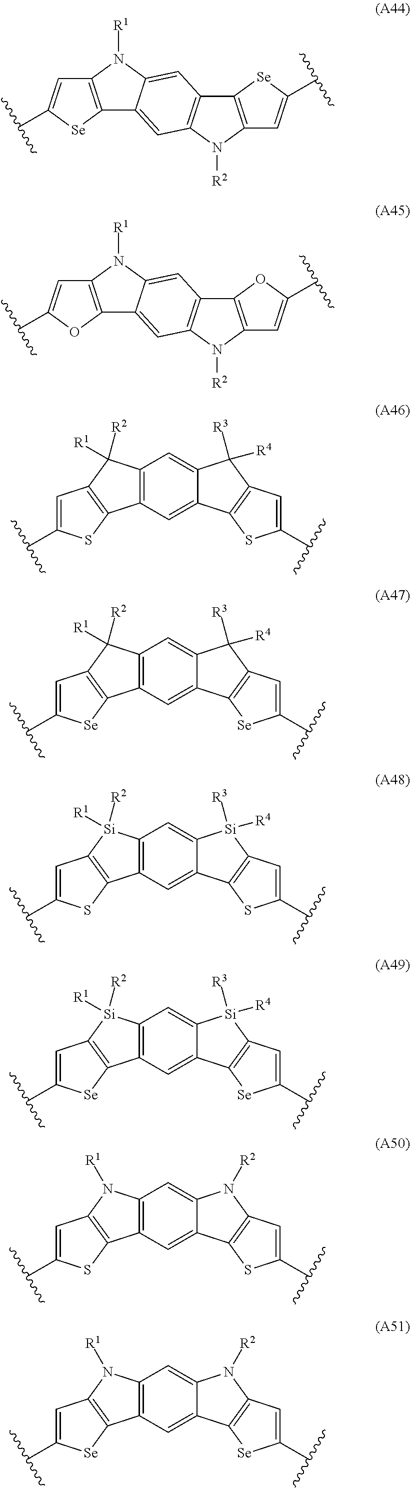 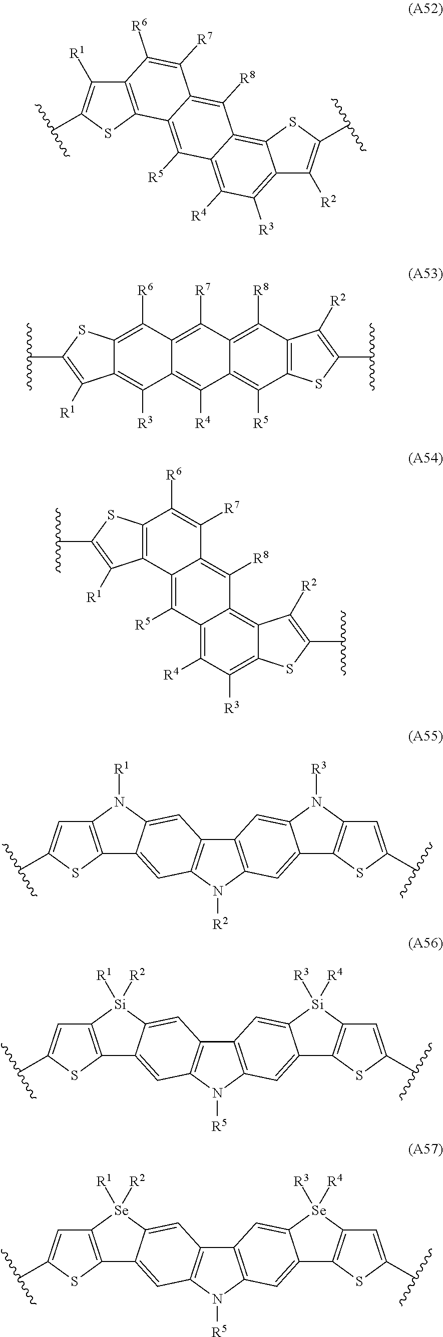 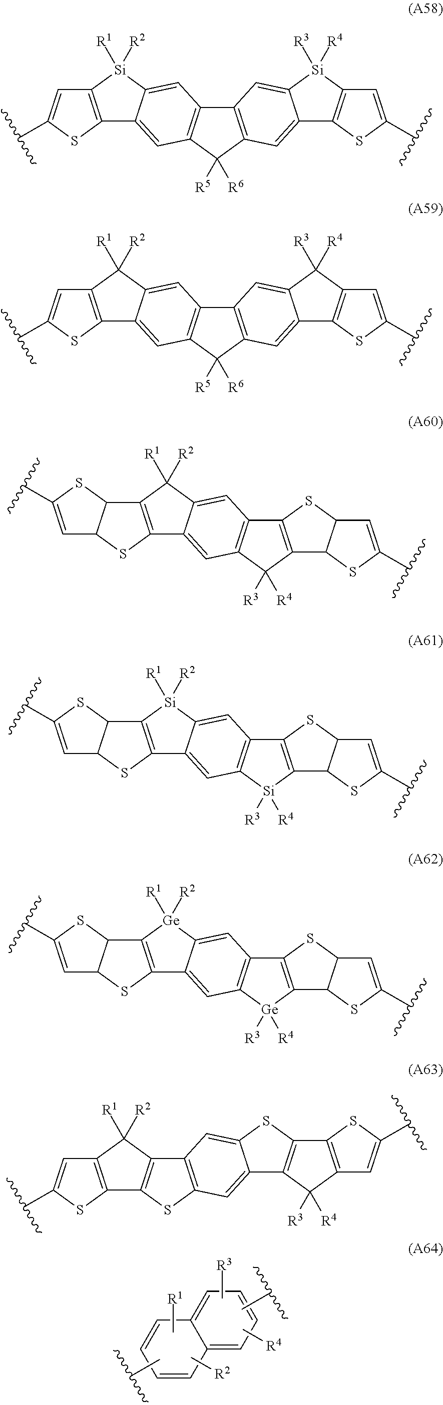 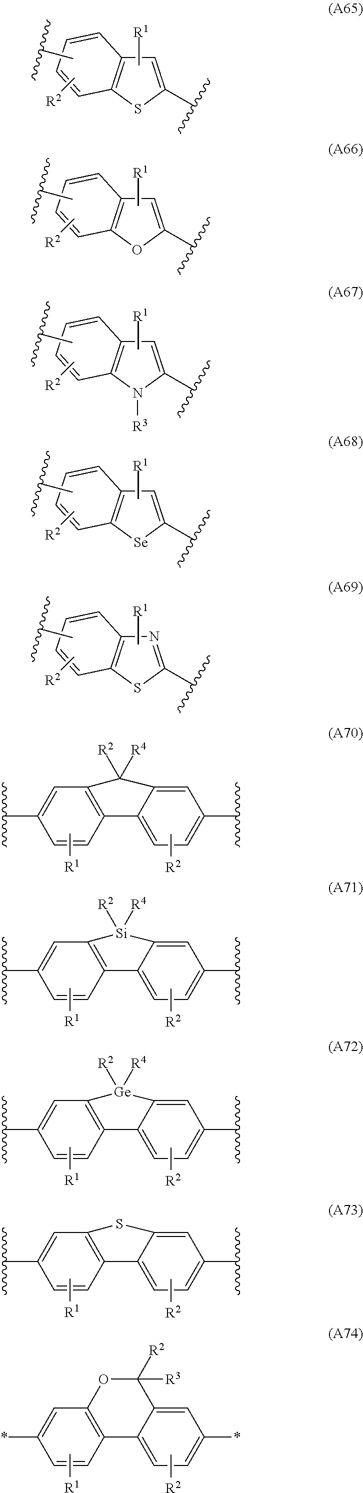 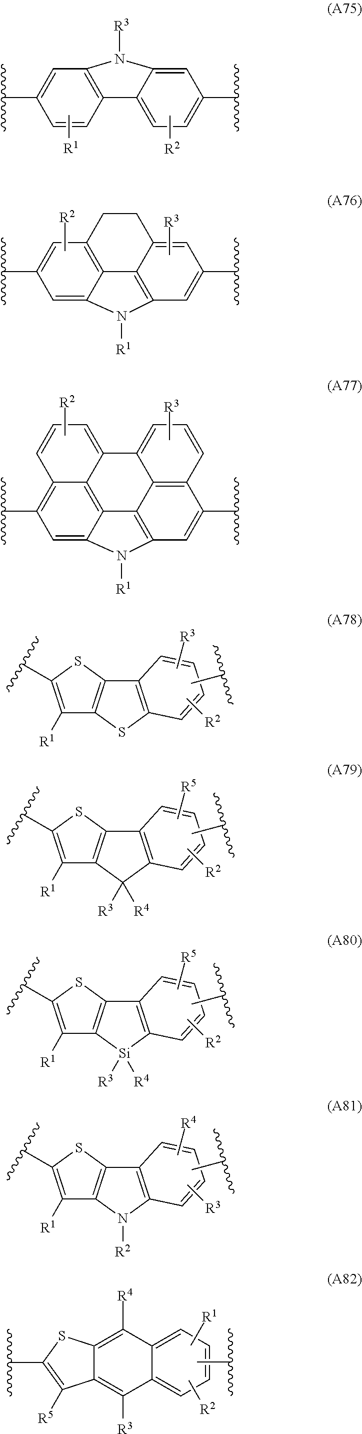 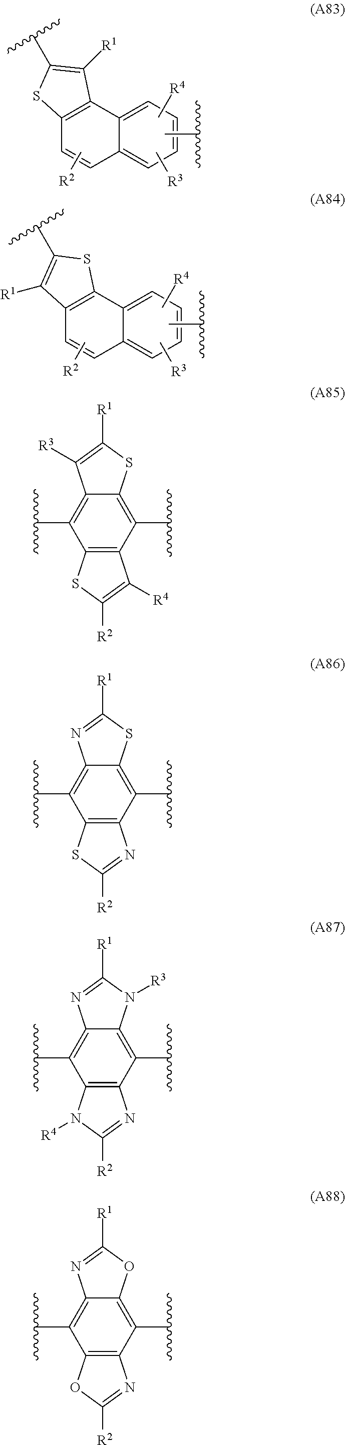 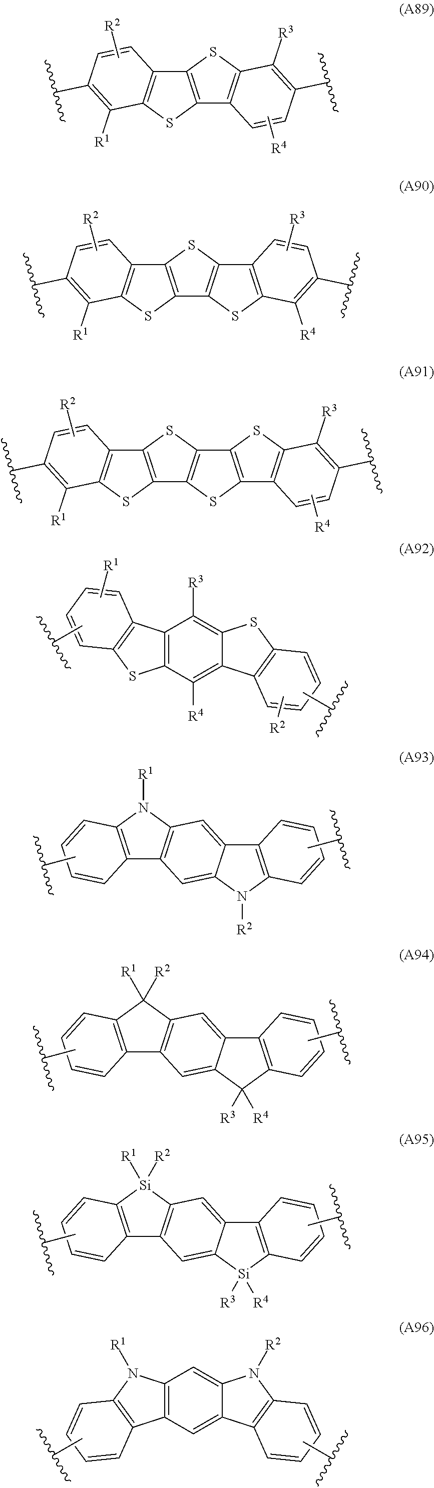 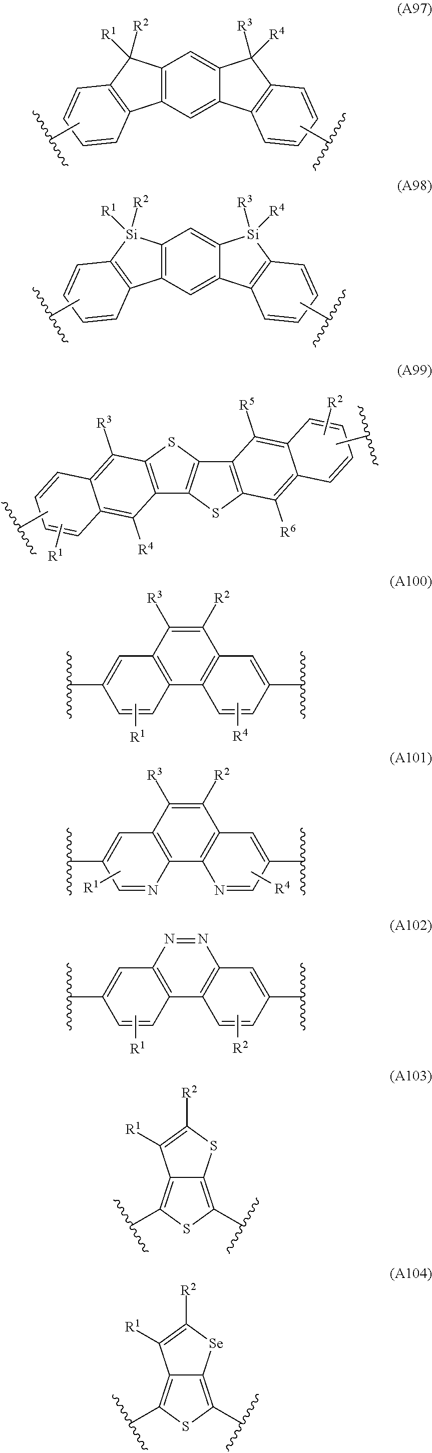 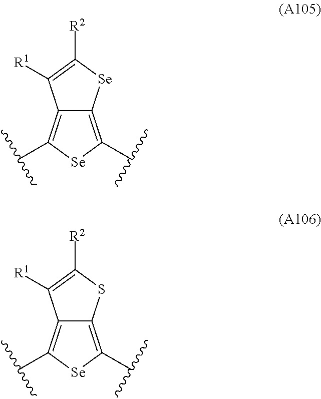
wherein the following applies to the symbols used:
R¹ is at each occurrence, identically or differently, selected from the group consisting of hydrogen, halogen, C₁-C₄₀ alkyl, C₁-C₄₀ alkoxy, aryl, heteroaryl, C₃-C₄₀ cycloalkyl, C₃-C₄₀ heterocycloalkyl, CN, OR⁹, COR⁹, COOR⁹, and CON(R⁹R¹⁰);
R² is at each occurrence, identically or differently, selected from the group consisting of hydrogen, halogen, C₁-C₄₀ alkyl, C₁-C₄₀ alkoxy, aryl, heteroaryl, C₃-C₄₀ cycloalkyl, C₃-C₄₀ heterocycloalkyl, CN, OR⁹, COR⁹, COOR⁹, and CON(R⁹R¹⁰);
R³ is at each occurrence, identically or differently, selected from the group consisting of hydrogen, halogen, C₁-C₄₀ alkyl, C₁-C₄₀ alkoxy, aryl, heteroaryl, C₃-C₄₀ cycloalkyl, C₃-C₄₀ heterocycloalkyl, CN, OR⁹, COR⁹, COOR⁹, and CON(R⁹R¹⁰);
R⁴ is at each occurrence, identically or differently, selected from the group consisting of hydrogen, halogen, C₁-C₄₀ alkyl, C₁-C₄₀ alkoxy, aryl, heteroaryl, C₃-C₄₀ cycloalkyl, C₃-C₄₀ heterocycloalkyl, CN, OR⁹, COR⁹, COOR⁹, and CON(R⁹R¹⁰);
R⁵ is at each occurrence, identically or differently, selected from the group consisting of hydrogen, halogen, C₁-C₄₀ alkyl, C₁-C₄₀ alkoxy, aryl, heteroaryl, C₃-C₄₀ cycloalkyl, C₃-C₄₀ heterocycloalkyl, CN, OR⁹, COR⁹, COOR⁹, and CON(R⁹R¹⁰);
R⁶ is at each occurrence, identically or differently, selected from the group consisting of hydrogen, halogen, C₁-C₄₀ alkyl, C₁-C₄₀ alkoxy, aryl, heteroaryl, C₃-C₄₀ cycloalkyl, C₃-C₄₀ heterocycloalkyl, CN, OR⁹, COR⁹, COOR⁹, and CON(R⁹R¹⁰);
R⁷ is at each occurrence, identically or differently, selected from the group consisting of hydrogen, halogen, C₁-C₄₀ alkyl, C₁-C₄₀ alkoxy, aryl, heteroaryl, C₃-C₄₀ cycloalkyl, C₃-C₄₀ heterocycloalkyl, CN, OR⁹, COR⁹, COOR⁹, and CON(R⁹R¹⁰);
R⁸ is at each occurrence, identically or differently, selected from the group consisting of hydrogen, halogen, C₁-C₄₀ alkyl, C₁-C₄₀ alkoxy, aryl, heteroaryl, C₃-C₄₀ cycloalkyl, C₃-C₄₀ heterocycloalkyl, CN, OR⁹, COR⁹, COOR⁹, and CON(R⁹R¹⁰);
R⁹ is at each occurrence, identically or differently, H, C₁-C₄₀ alkyl, aryl, heteroaryl, C₃-C₄₀ cycloalkyl, or C₃-C₄₀ heterocycloalkyl.
R¹⁰ is at each occurrence, identically or differently, H, C₁-C₄₀ alkyl, aryl, heteroaryl, C₃-C₄₀ cycloalkyl, or C₃-C₄₀ heterocycloalkyl.

4. The photovoltaic cell according to claim 3, wherein the common building block is at each occurrence, selected from the group consisting of formulae (A10), (A12), (A13), (A19), (A20), (A21), (A22), and (A23).

5. The photovoltaic cell according to claim 3, wherein the common conjugated fused ring moieties of the donor materials is at each occurrence, represented by formula (A10) or (A21).

6. The photovoltaic cell according to claim 1, wherein at least one of the donor materials comprises an electron withdrawing building block.

7. The photovoltaic cell according to claim 1, wherein the first donor material and the second donor material each comprise an electron withdrawing building block, and the electron withdrawing building block of the first donor material has more electron withdrawing capability than the electron withdrawing building block of the second donor material.

8. The photovoltaic cell according to claim 1, wherein the first donor material comprises an electron withdrawing building block selected from the group consisting of the following formulae (B1) to (B92) 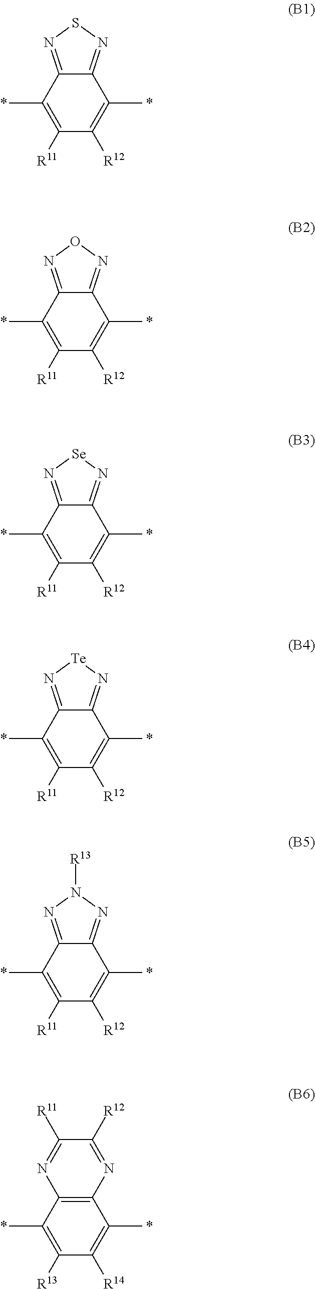 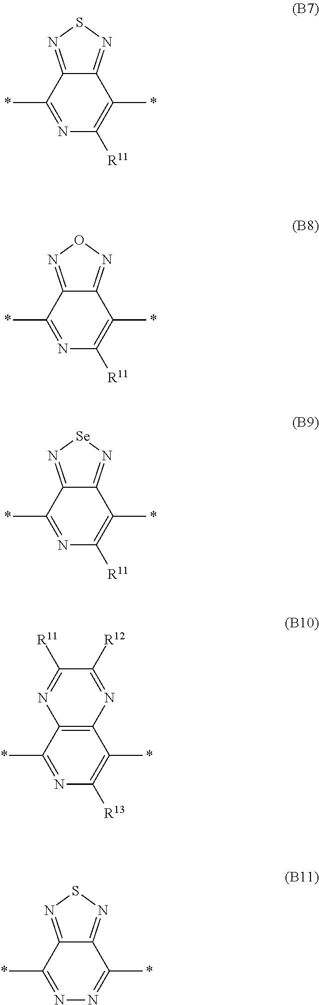 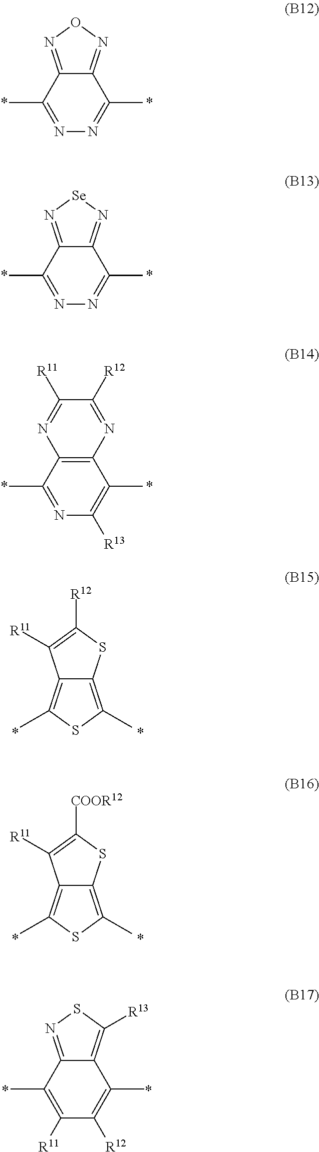 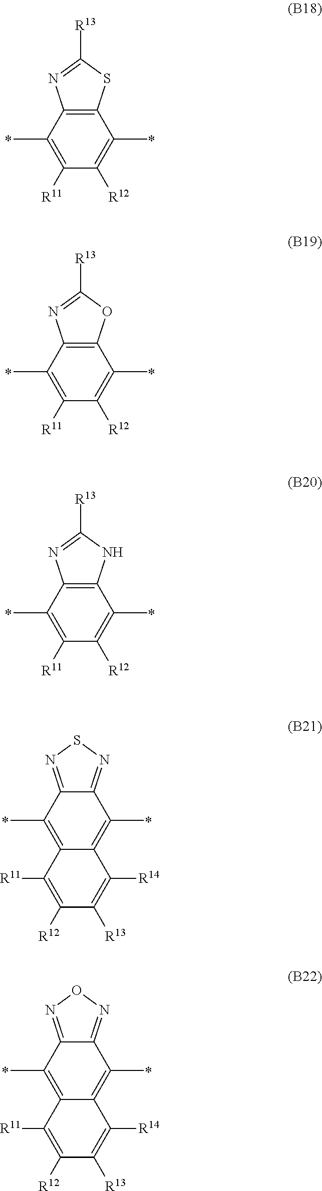 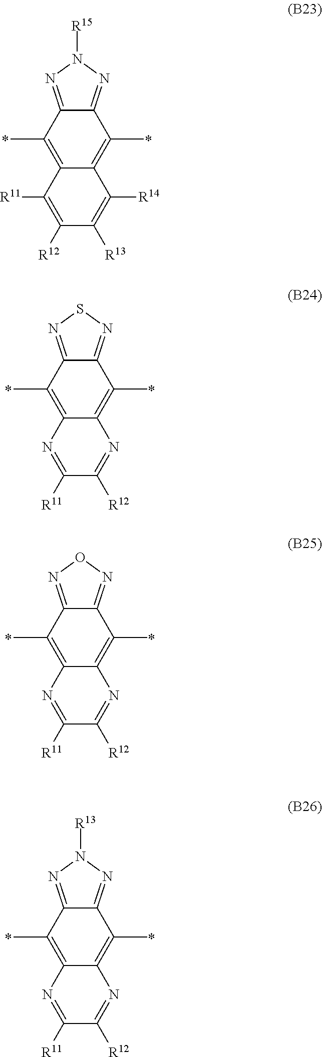 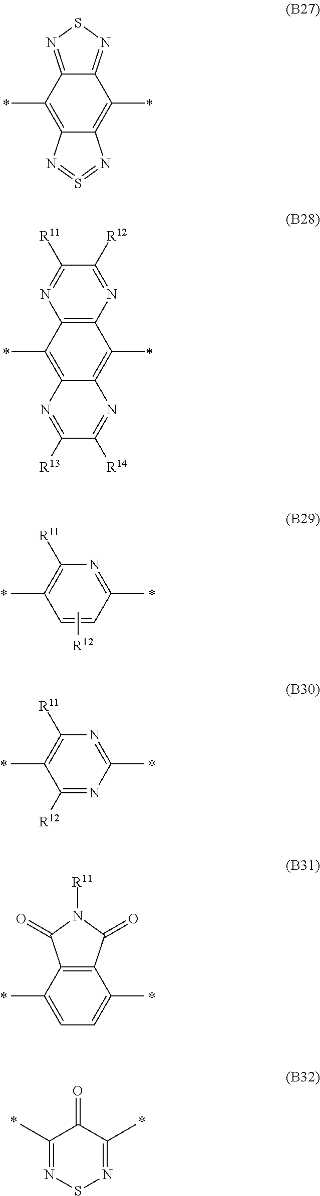 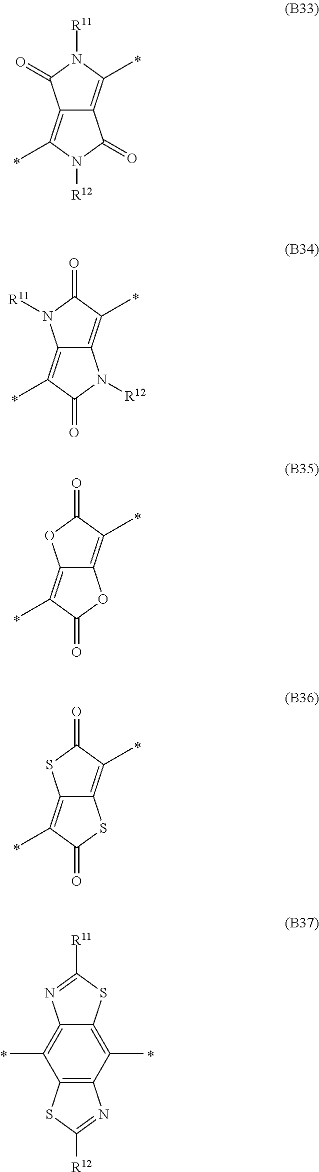 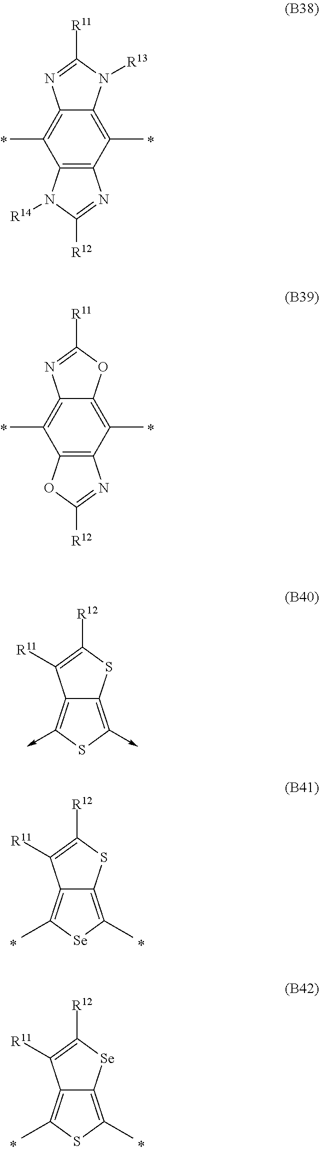 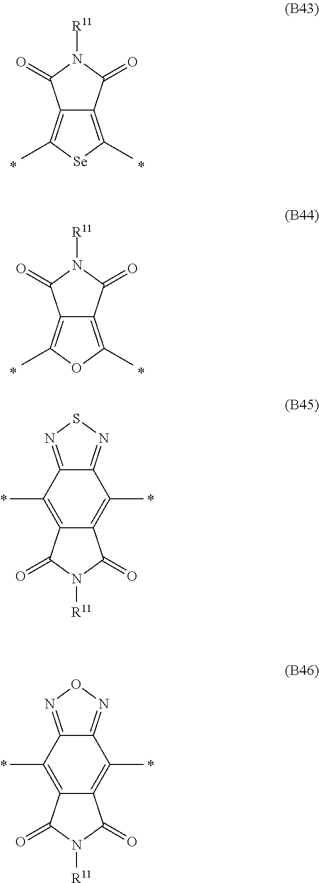 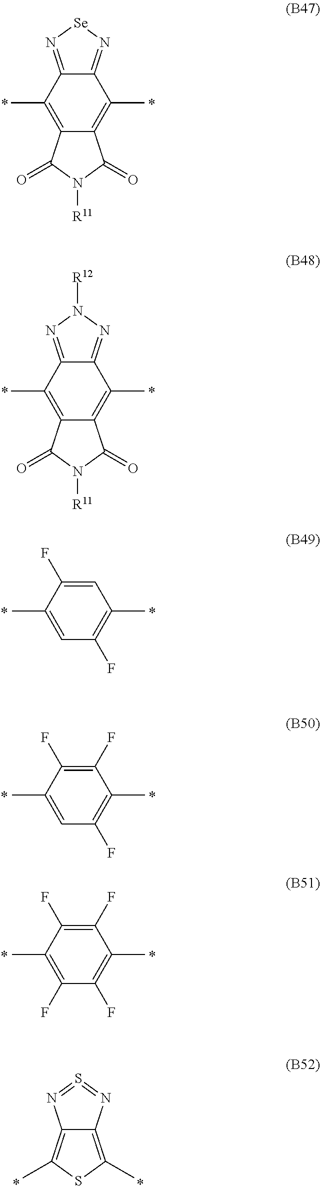 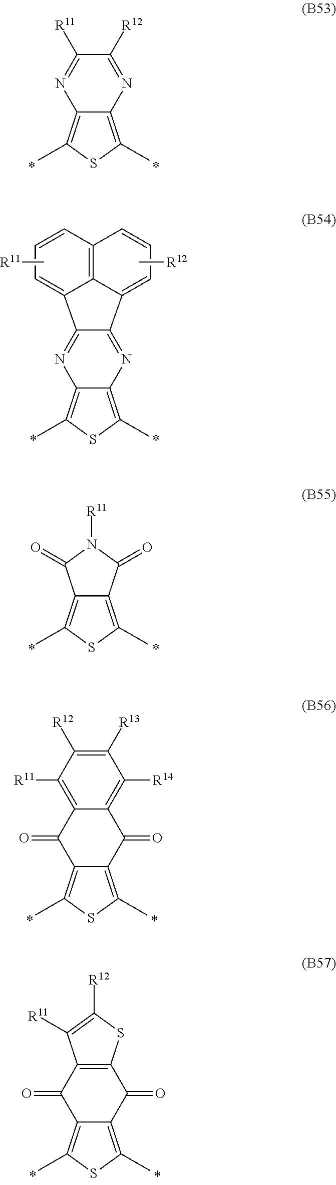 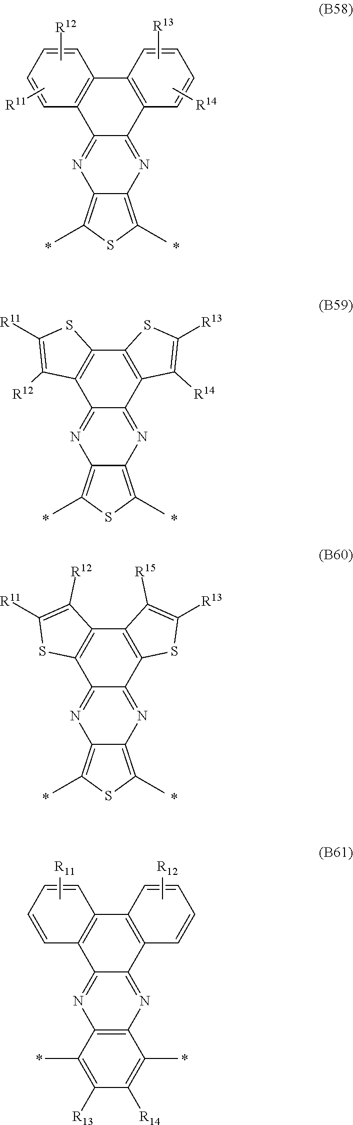 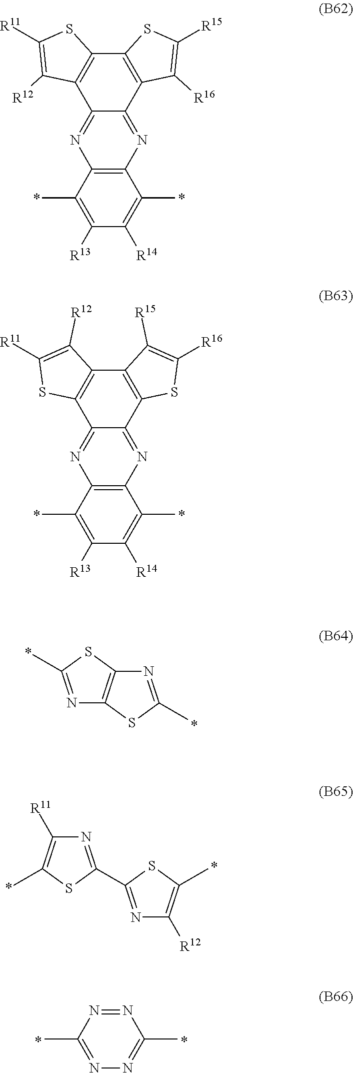 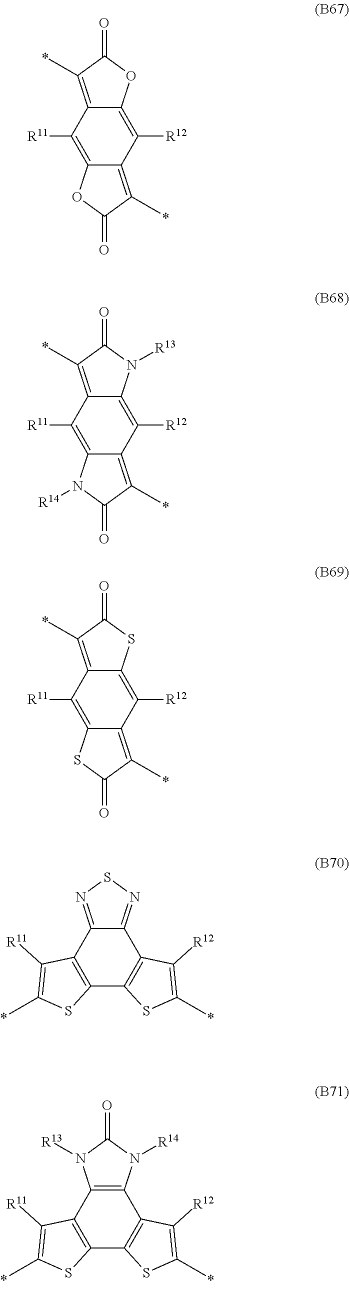 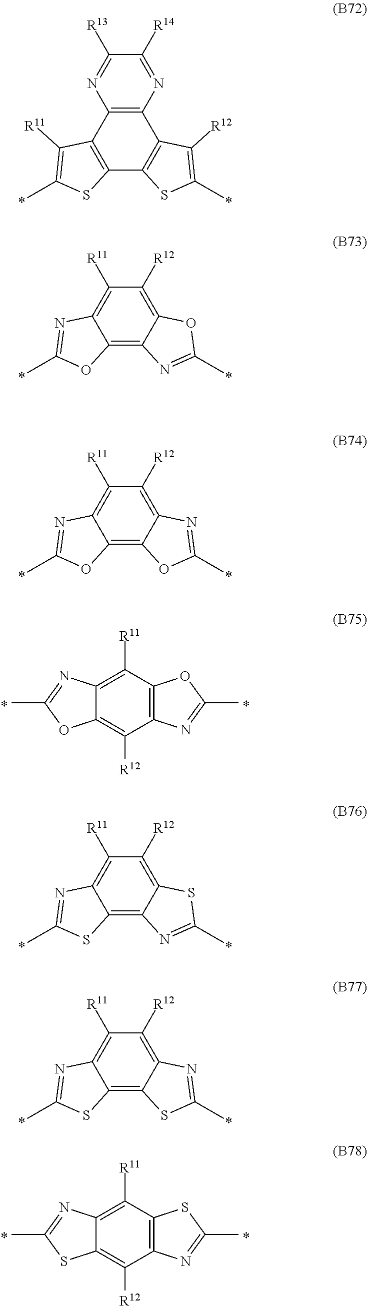 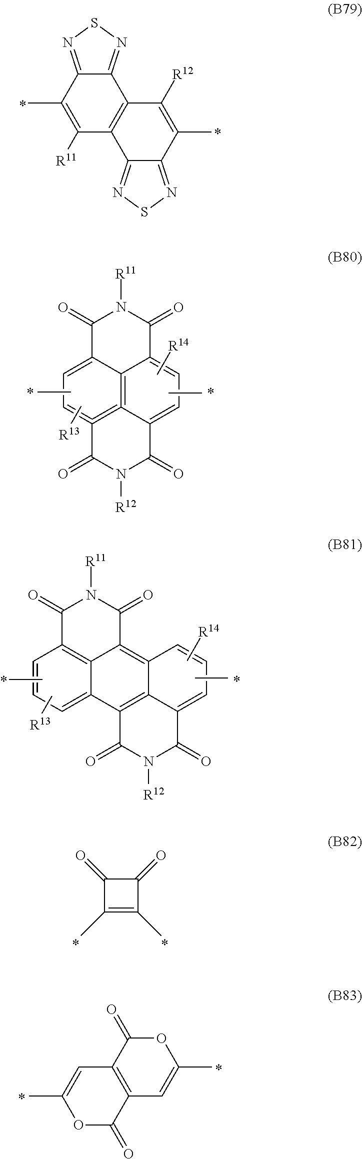 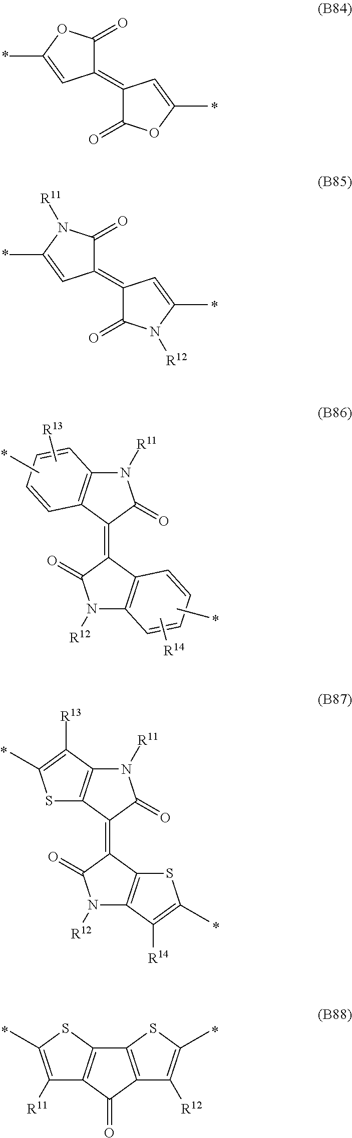 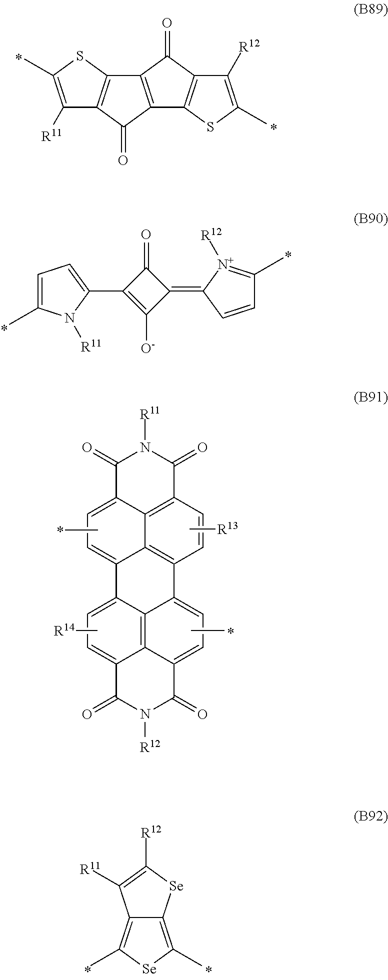
wherein the following applies to the symbols used:
R¹¹ is at each occurrence, identically or differently, selected from the group consisting of hydrogen, halogen, C₁-C₄₀ alkyl, C₁-C₄₀ alkoxy, aryl, heteroaryl, C₃-C₄₀ cycloalkyl, C₃-C₄₀ heterocycloalkyl, CN, OR¹⁷, COR¹⁷, COOR¹⁷, and CON(R¹⁷R¹⁸);
R¹² is at each occurrence, identically or differently, selected from the group consisting of hydrogen, halogen, C₁-C₄₀ alkyl, C₁-C₄₀ alkoxy, aryl, heteroaryl, C₃-C₄₀ cycloalkyl, C₃-C₄₀ heterocycloalkyl, CN, OR¹⁷, COR¹⁷, COOR¹⁷, and CON(R¹⁷R¹⁸);
R¹³ is at each occurrence, identically or differently, selected from the group consisting of hydrogen, halogen, C₁-C₄₀ alkyl, C₁-C₄₀ alkoxy, aryl, heteroaryl, C₃-C₄₀ cycloalkyl, C₃-C₄₀ heterocycloalkyl, CN, OR¹⁷, COR¹⁷, COOR¹⁷, and CON(R¹⁷R¹⁸);
R¹⁴ is at each occurrence, identically or differently, selected from the group consisting of hydrogen, halogen, C₁-C₄₀ alkyl, C₁-C₄₀ alkoxy, aryl, heteroaryl, C₃-C₄₀ cycloalkyl, C₃-C₄₀ heterocycloalkyl, CN, OR¹⁷, COR¹⁷, COOR¹⁷, and CON(R¹⁷R¹⁸);
R¹⁵ is at each occurrence, identically or differently, selected from the group consisting of hydrogen, halogen, C₁-C₄₀ alkyl, C₁-C₄₀ alkoxy, aryl, heteroaryl, C₃-C₄₀ cycloalkyl, C₃-C₄₀ heterocycloalkyl, CN, OR¹⁷, COR¹⁷, COOR¹⁷, and CON(R¹⁷R¹⁸);
R¹⁶ is at each occurrence, identically or differently, selected from the group consisting of hydrogen, halogen, C₁-C₄₀ alkyl, C₁-C₄₀ alkoxy, aryl, heteroaryl, C₃-C₄₀ cycloalkyl, C₃-C₄₀ heterocycloalkyl, CN, OR¹⁷, COR¹⁷, COOR¹⁷, and CON(R¹⁷R¹⁸);
R¹⁷ is at each occurrence, identically or differently, H, C₁-C₄₀ alkyl, aryl, heteroaryl, C₃-C₄₀ cycloalkyl, or C₃-C₄₀ heterocycloalkyl.
R¹⁸ is at each occurrence, identically or differently, H, C₁-C₄₀ alkyl, aryl, heteroaryl, C₃-C₄₀ cycloalkyl, or C₃-C₄₀ heterocycloalkyl;
and the second donor material comprises an electron withdrawing building block selected from the group consisting of the following formulae (C1) to (C92) 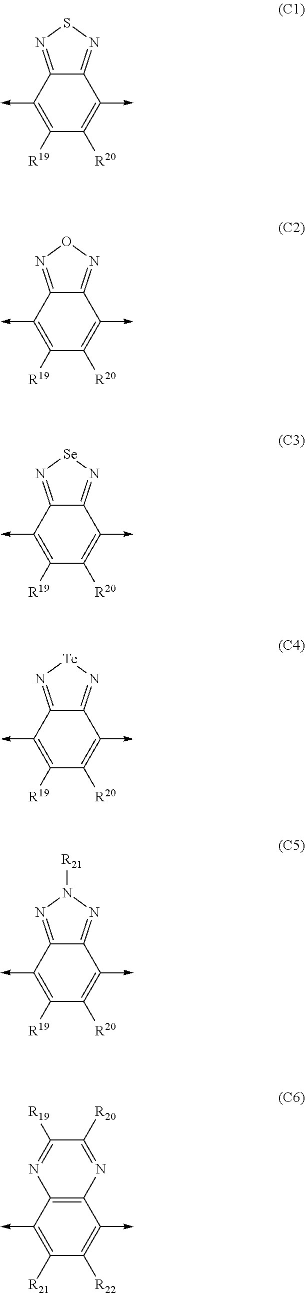 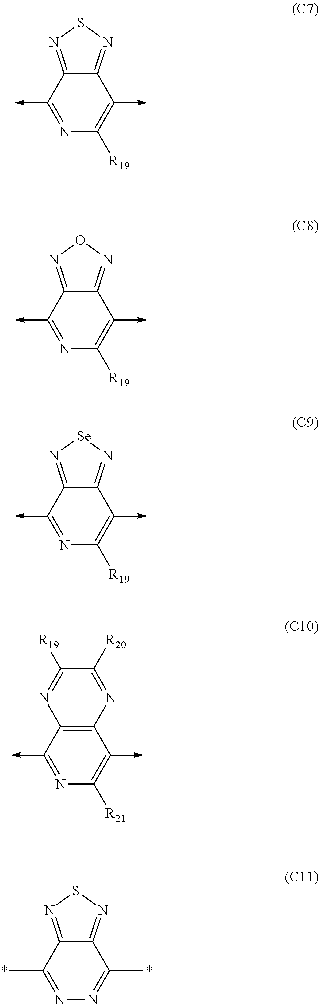 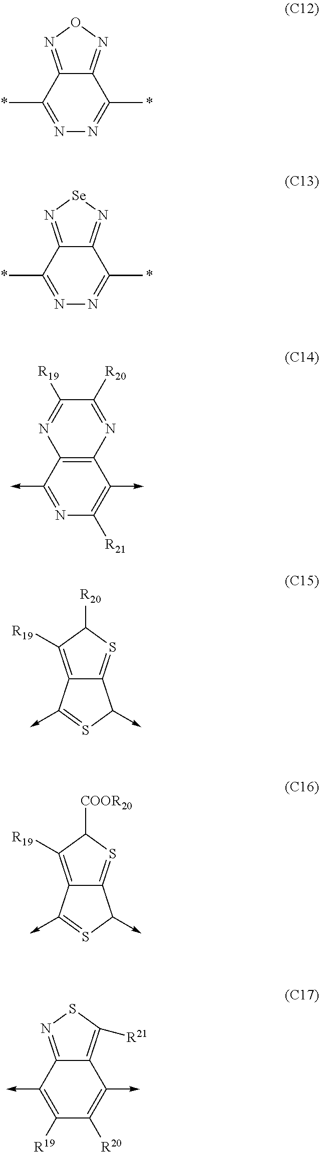 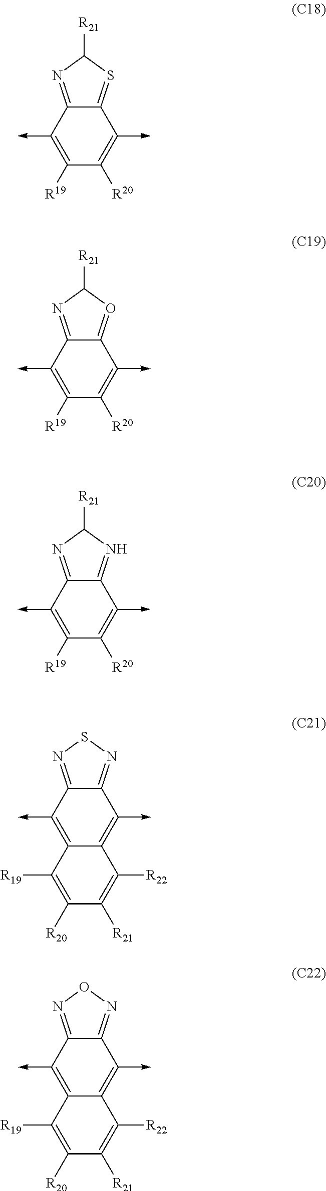 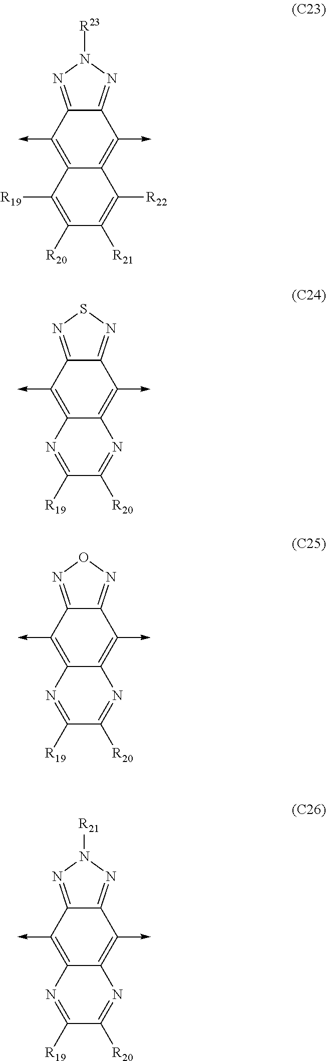 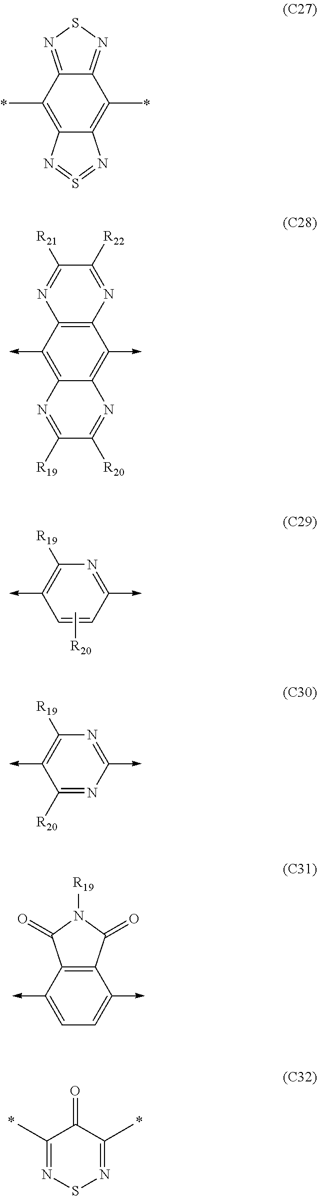 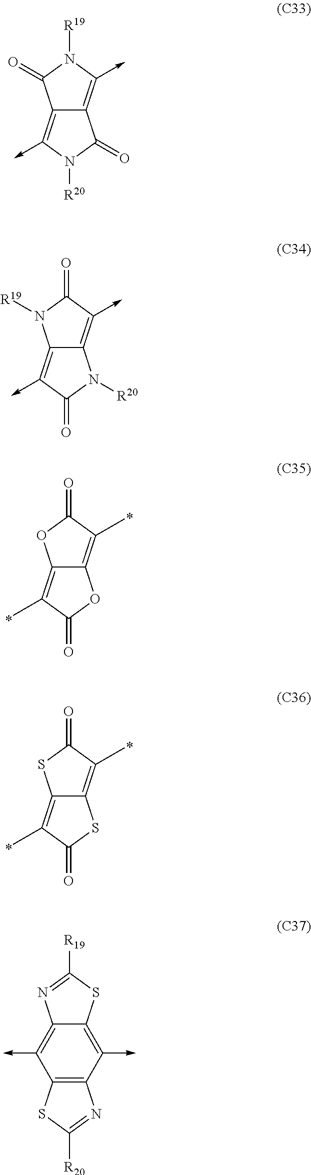 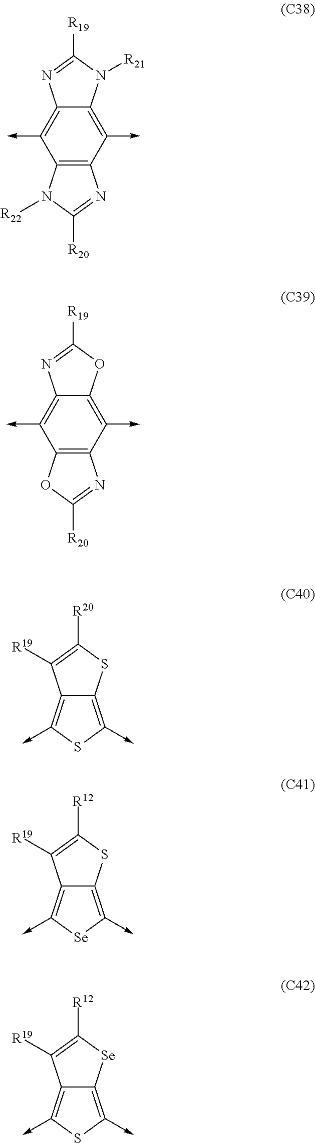 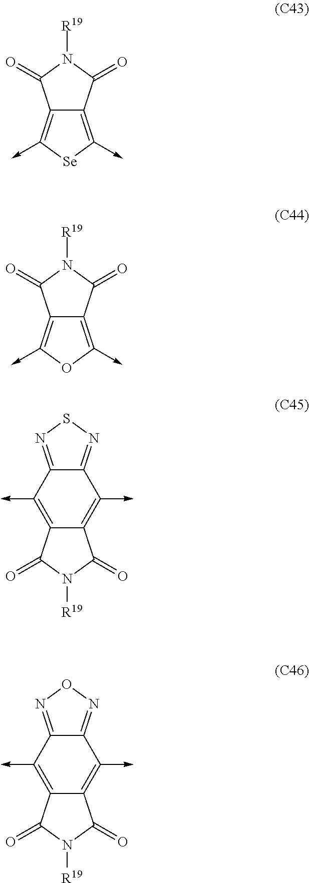 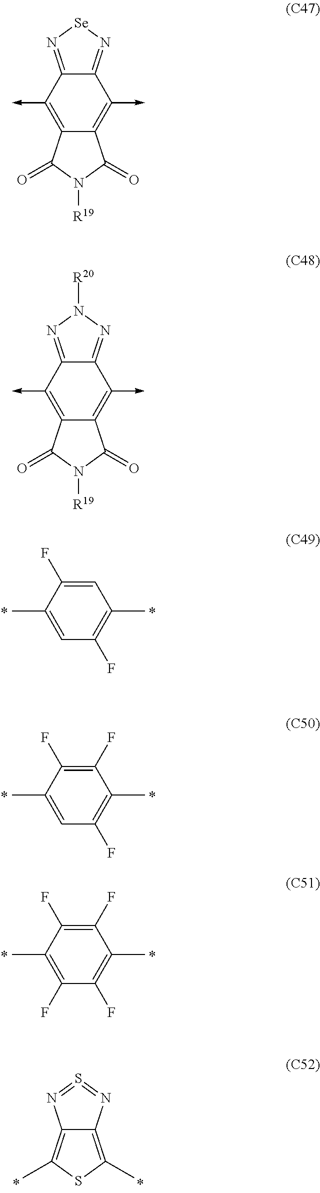 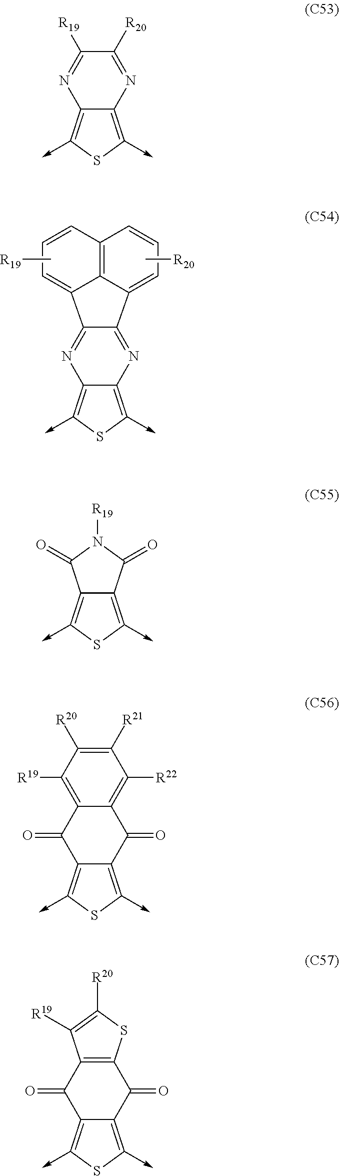 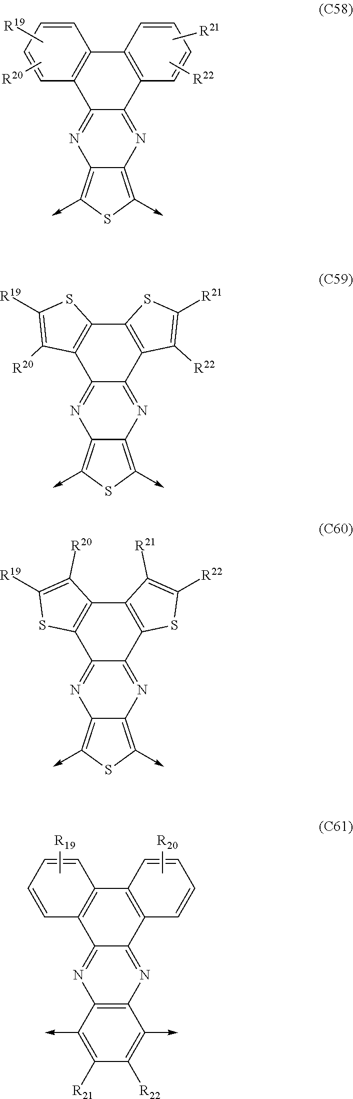 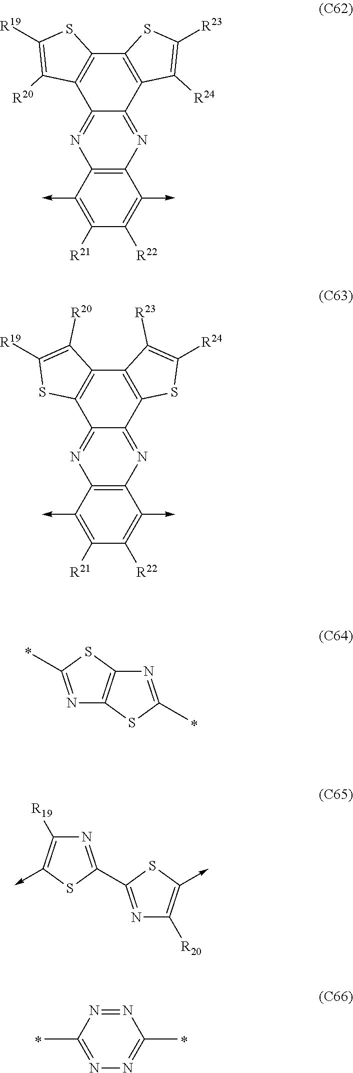 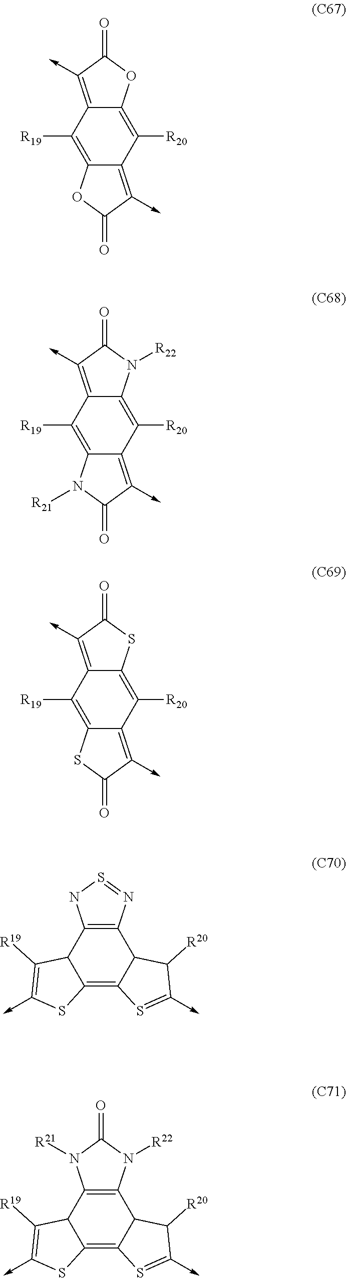 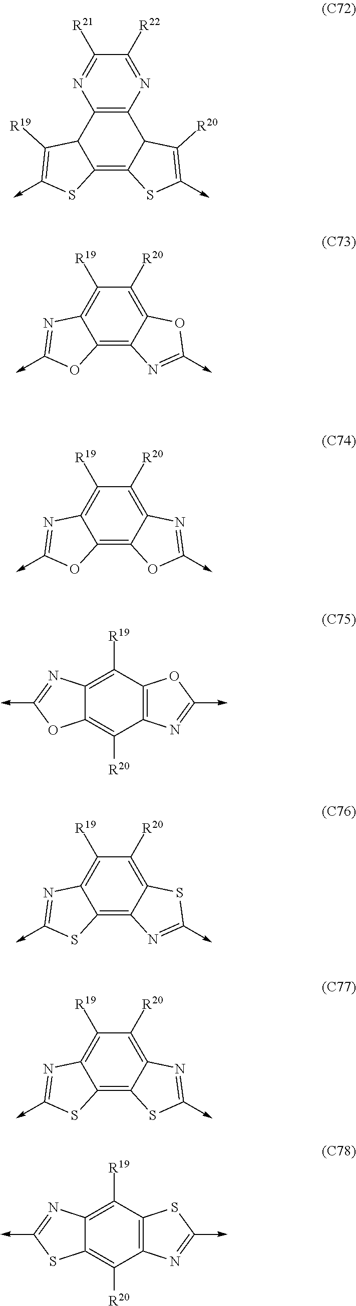 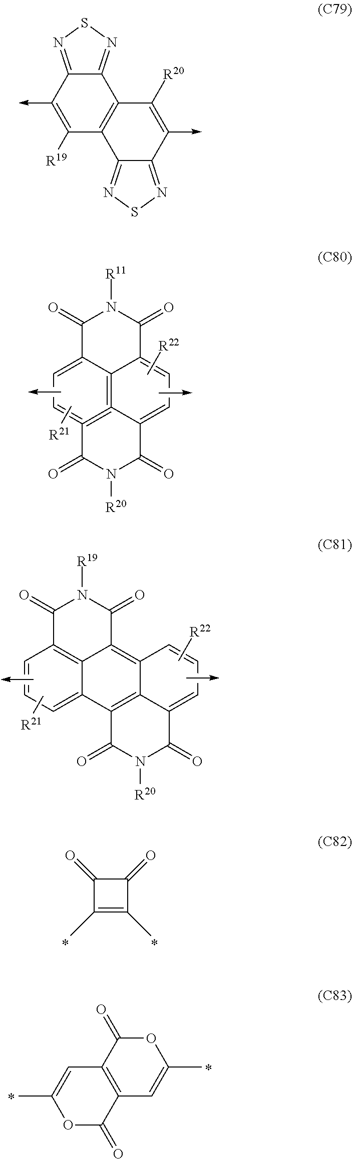 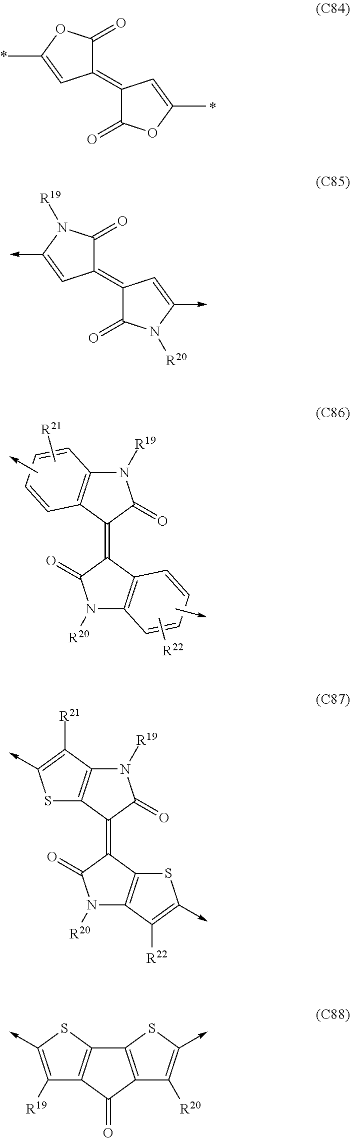 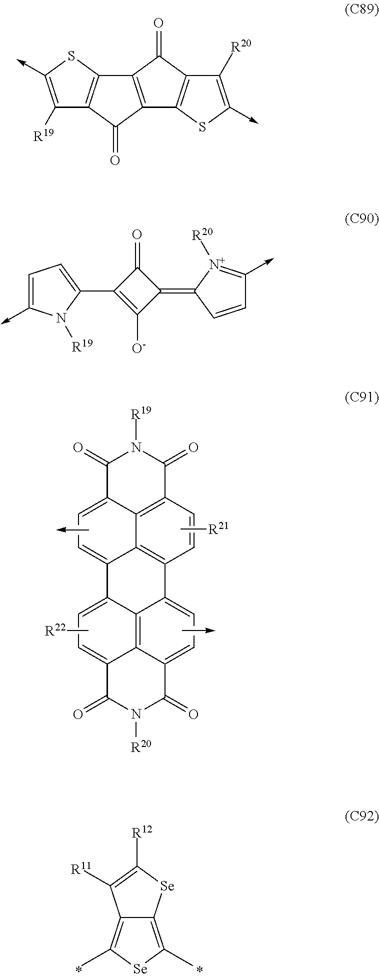
wherein the following applies to the symbols used:
R¹⁹ is at each occurrence, identically or differently, selected from the group consisting of hydrogen, halogen, C₁-C₄₀ alkyl, C₁-C₄₀ alkoxy, aryl, heteroaryl, C₃-C₄₀ cycloalkyl, C₃-C₄₀ heterocycloalkyl, CN, OR²⁵, COR²⁵, COOR²⁵, and CON(R²⁵R²⁶);
R²⁰ is at each occurrence, identically or differently, selected from the group consisting of hydrogen, halogen, C₁-C₄₀ alkyl, C₁-C₄₀ alkoxy, aryl, heteroaryl, C₃-C₄₀ cycloalkyl, C₃-C₄₀ heterocycloalkyl, CN, OR²⁵, COR²⁵, COOR²⁵, and CON(R²⁵R²⁶);
R²¹ is at each occurrence, identically or differently, selected from the group consisting of hydrogen, halogen, C₁-C₄₀ alkyl, C₁-C₄₀ alkoxy, aryl, heteroaryl, C₃-C₄₀ cycloalkyl, C₃-C₄₀ heterocycloalkyl, CN, OR²⁵, COR²⁵, COOR²⁵, and CON(R²⁵R²⁶);
R²² is at each occurrence, identically or differently, selected from the group consisting of hydrogen, halogen, C₁-C₄₀ alkyl, C₁-C₄₀ alkoxy, aryl, heteroaryl, C₃-C₄₀ cycloalkyl, C₃-C₄₀ heterocycloalkyl, CN, OR²⁵, COR²⁵, COOR²⁵, and CON(R²⁵R²⁶);
R²³ is at each occurrence, identically or differently, selected from the group consisting of hydrogen, halogen, C₁-C₄₀ alkyl, C₁-C₄₀ alkoxy, aryl, heteroaryl, C₃-C₄₀ cycloalkyl, C₃-C₄₀ heterocycloalkyl, CN, OR²⁵, COR²⁵, COOR²⁵, and CON(R²⁵R²⁶);
R²⁴ is at each occurrence, identically or differently, selected from the group consisting of hydrogen, halogen, C₁-C₄₀ alkyl, C₁-C₄₀ alkoxy, aryl, heteroaryl, C₃-C₄₀ cycloalkyl, C₃-C₄₀ heterocycloalkyl, CN, OR²⁵, COR²⁵, COOR²⁵, and CON(R²⁵R²⁶);
R²⁵ is at each occurrence, identically or differently, H, C₁-C₄₀ alkyl, aryl, heteroaryl, C₃-C₄₀ cycloalkyl, or C₃-C₄₀ heterocycloalkyl.
R²⁶ is at each occurrence, identically or differently, H, C₁-C₄₀ alkyl, aryl, heteroaryl, C₃-C₄₀ cycloalkyl, or C₃-C₄₀ heterocycloalkyl.

9. The photovoltaic cell according to claim 8, wherein the first donor material comprises an electron withdrawing building block selected from the group consisting of formulae (B15), (B16), (B45), (B46), (B47), and (B48); and the second donor material comprises an electron withdrawing building block represented by the formula (C64).

10. The photovoltaic cell according to claim 8, wherein the first donor material comprises an electron withdrawing building block selected from the group consisting of formulae (B15), (B16), and (B45); and the second donor material comprises an electron withdrawing building block represented by the formula (C64).

11. The photovoltaic cell according to claim 1, wherein at least one of the donor materials is a polymer or an oligomer.

12. The photovoltaic cell according to claim 1, wherein at least two of the donor materials are at each occurrence independently of each other selected from the group consisting of KP179, KP252, and KP184, or KP143, and KP155.

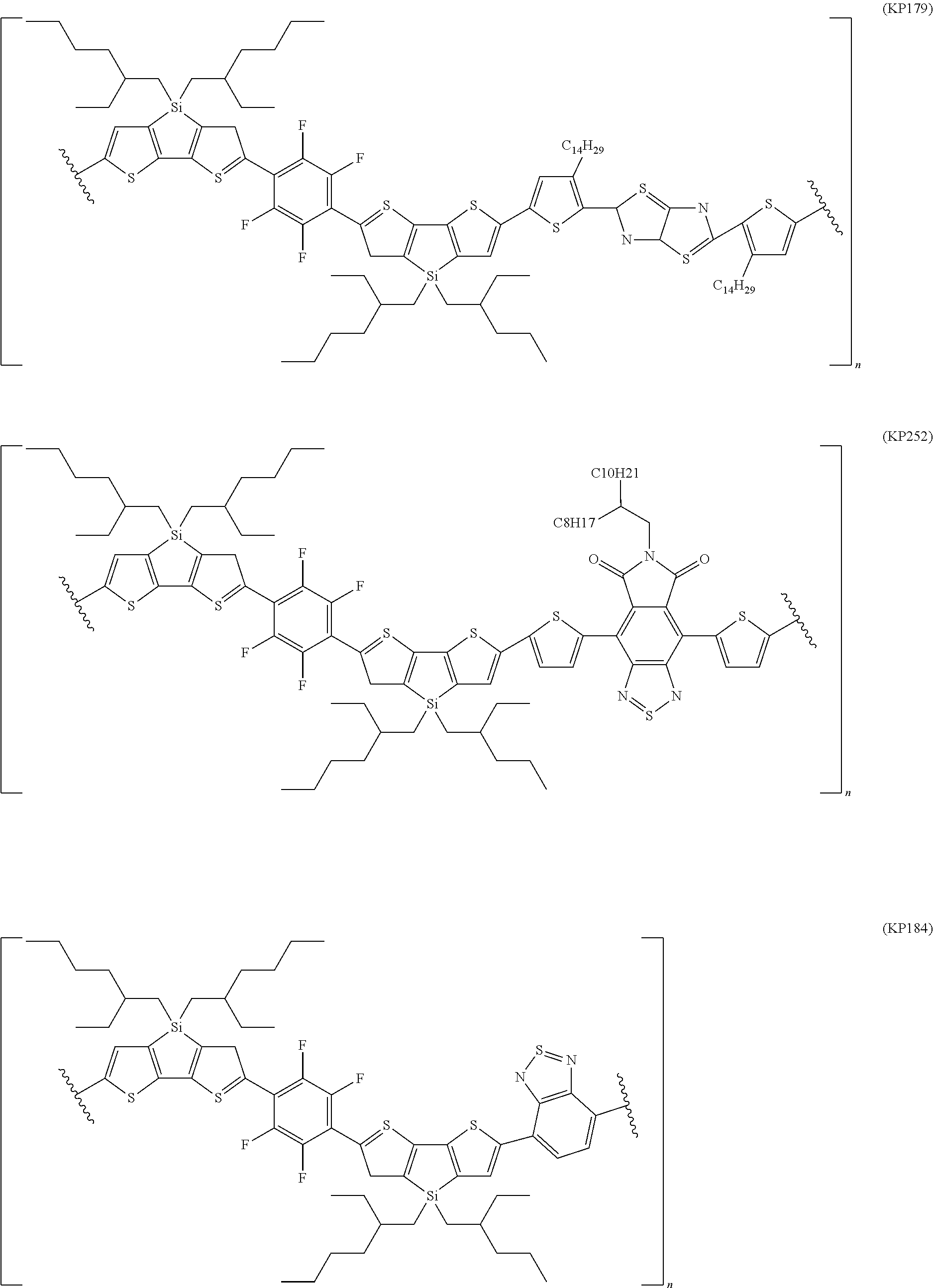

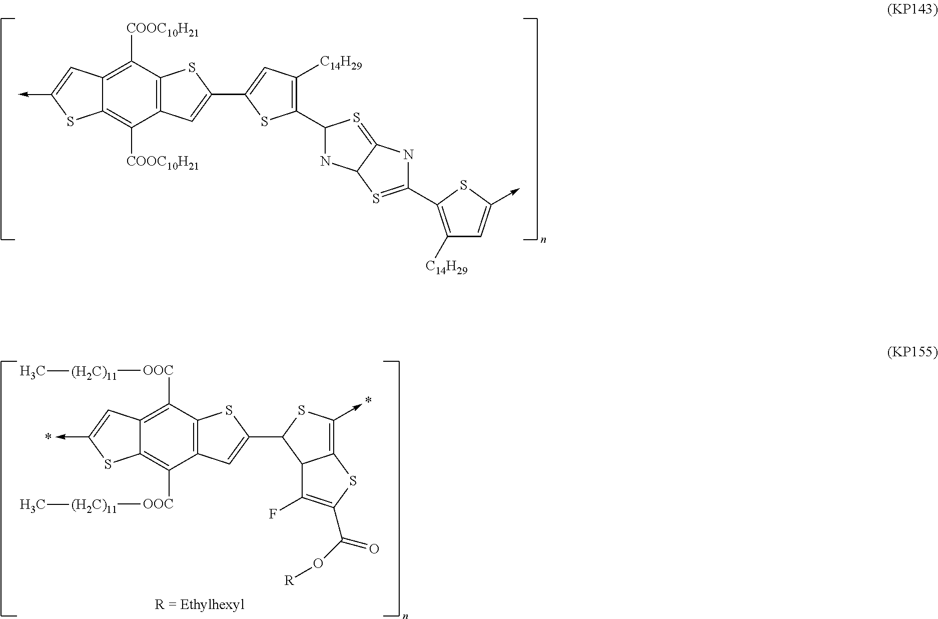

13. The photovoltaic cell according to claim 1, in which the acceptor material comprises a compound selected from the group consisting of fullerene, fullerene derivatives, perylene diimide derivatives, benzo thiazole derivatives, diketo-pyrrolo-pyrrole derivatives, bi-fluorenylidene derivatives, pentacene derivatives, quinacridone derivatives, fluoranthene imide derivatives, boron-dipyrromethene derivatives, oxadiazoles, metal phthalocyanine and sub-phthalocyanine, inorganic nanoparticles, discotic liquid crystals, carbon nanorods, inorganic nanorods, polymers containing CN groups, polymers containing CF3 groups, or a combination of any of these.

14. The photovoltaic cell according to claim 1, wherein the acceptor material comprises a substituted fullerene.

15. The photovoltaic cell according to claim 14, wherein the substituted fullerene is selected from the group consisting of PC60BM, PC61BM, PC70BM and a combination of any of these.

16. The photovoltaic cell according to claim 1, wherein the photoactive layer further comprises a dopant.

17. The photovoltaic cell according to claim 16, wherein the dopant is selected from the group consisting of diiodo octane, octadecanethiol, phenylnaphthalene and a combination of any of these.

18. Use of donor materials in a photovoltaic cell:
wherein the photovoltaic cell comprises,
a first electrode;
a second electrode; and
a photoactive layer between the first electrode and the second electrode,
wherein the photoactive layer comprises a first donor material, second donor material and acceptor material; the first donor material and the second donor material are different from each other and each of the donor materials comprises a common building block of the same chemical structure, said common building block comprising a conjugated fused ring moiety.

19. Method for preparing the photovoltaic cell according to claim 1, where the method for preparing the photovoltaic cell of the present invention comprises the steps of
(a) dissolving at least the first donor material, the second donor material and the acceptor material together in a solvent; and
(b) subsequently coating the resulting solution from step (a) over a layer underneath,
wherein the first donor material and the second donor material are different from each other and each of the donor materials comprises a common building block of the same chemical structure, said common building block comprising a conjugated fused ring moiety.

20. Method for preparing the photovoltaic cell according to claim 1, where the method comprises the steps of
(a′) dissolving at least the first donor material, the second donor material and the acceptor material each separately in a same type or different type of solvent to obtain different solutions;
(b′) mixing the resulting solutions from step (a′) to obtain a solution which contains the first donor material, the second donor material and the acceptor material; and
(c′) subsequently coating the resulting solution from step (b′) over a layer underneath,
wherein the first donor material and the second donor material are different from each other and each of the donor materials comprises a common building block of the same chemical structure, said common building block comprising a conjugated fused ring moiety.

21. The method according to claim 19,
wherein the solvent is selected from organic solvents.

22. The method according to claim 19,
wherein the solvent is selected from the group consisting of aliphatic hydrocarbons, chlorinated hydrocarbons, aromatic hydrocarbons, ketones, ethers and mixtures thereof. Additional solvents which can be used include 1,2,4-trimethylbenzene, 1,2,3,4-tetra-methyl benzene, pentylbenzene, mesitylene, cumene, cymene, cyclohexylbenzene, diethylbenzene, tetralin, decalin, 2,6-lutidine, 2-fluoro-m-xylene, 3-fluoro-o-xylene, 2-chlorobenzotrifluoride, N,N-dimethylformamide, 2-chloro-6-fluorotoluene, 2-fluoroanisole, anisole, 2,3-dimethylpyrazine, 4-fluoroanisole, 3-fluoroanisole, 3-trifluoro-methylanisole, 2-methylanisole, phenetol, 4-methylanisole, 3-methylanisole, 4-fluoro-3-methylanisole, 2-fluorobenzonitrile, 4-fluoroveratrol, 2,6-dimethylanisole, 3-fluorobenzo-nitrile, 2,5-dimethylanisole, 2,4-dimethylanisole, benzonitrile, 3,5-dimethyl-anisole, N,N-dimethylaniline, ethyl benzoate, 1-fluoro-3,5-dimethoxy-benzene, 1-methylnaphthalene, N-methylpyrrolidinone, 3-fluorobenzo-trifluoride, benzotrifluoride, dioxane, trifluoromethoxy-benzene, 4-fluorobenzotrifluoride, 3-fluoropyridine, toluene, 2-fluoro-toluene, 2-fluorobenzotrifluoride, 3-fluorotoluene, 4-isopropylbiphenyl, phenyl ether, pyridine, 4-fluorotoluene, 2,5-difluorotoluene, 1-chloro-2,4-difluorobenzene, 2-fluoropyridine, 3-chlorofluoro-benzene, 1-chloro-2,5-difluorobenzene, 4-chlorofluorobenzene, chloro-benzene, o-dichlorobenzene, 2-chlorofluorobenzene, p-xylene, m-xylene, o-xylene or mixture of o-, m-, and p-isomers and combinations of any of these.
